(19) United States
(12) Patent Application Publication
(10) Pub. No.: US 2011/0260271 A1
(43) Pub. Date: Oct. 27, 2011

(54) SEMICONDUCTOR DEVICE AND MANUFACTURING METHOD THEREOF

(75) Inventor: Shoichi FUKUI, Kanagawa (JP)

(73) Assignee: Renesas Electronics Corporation

(21) Appl. No.: 13/090,860

(22) Filed: Apr. 20, 2011

(30) Foreign Application Priority Data
Apr. 26, 2010 (JP) 2010-100808

(51) Int. Cl. H01L 29/82; H01L 21/02

(52) U.S. Cl. 257/421; 438/3; 257/E29.323; 257/E21.002

(57) ABSTRACT

Provided is a semiconductor device causing less peeling between an insulating film having on the top surface thereof a strap line and a wiring formed on the bottom surface of the insulating film, and a manufacturing method of the semiconductor device. The semiconductor device according to the invention has a semiconductor substrate, first wiring layers formed over the semiconductor substrate and having a peripheral wiring and a first wiring, a second wiring layer formed over the first wiring layers and having a second wiring, and a third wiring layer formed over the second wiring layer and having a magnetic storage element. The diffusion preventive films formed over the first wiring are each comprised of a SiCN film or an SiC film and the diffusion preventive film formed over the second wiring is comprised of SiN.

### CROSS-REFERENCE TO RELATED APPLICATIONS

The disclosure of Japanese Patent Application No. 2010-100808 filed on Apr. 26, 2010 including the specification, drawings and abstract is incorporated herein by reference in its entirety.

### BACKGROUND

The present invention relates to a semiconductor device and a manufacturing method thereof, in particular, to a semiconductor device having a magnetic storage element and a manufacturing method of the semiconductor device.

There has conventionally been proposed a semiconductor device equipped with a magnetic storage element. For example, a semiconductor device described in Japanese Patent Laid-Open No. 2007-165505 has a magnetic tunnel resistance element, a first interlayer insulating film having the magnetic tunnel resistance element, and a second interlayer insulating film having, on the top surface thereof, the first interlayer insulating film.

The semiconductor device further has a wiring layer formed in the second interlayer insulating film, a diffusion preventive film formed on the wiring layer and the second interlayer insulating film, a contact portion penetrating through the diffusion preventive film, and a strap line formed on the diffusion preventive film and coupled to the contact portion. This strap line has thereon the magnetic tunnel resistance element.

Japanese Patent Laid-Open No. 2007-165505 describes a manufacturing method of a semiconductor device having the above-described configuration.

After formation of a wiring layer in a second interlayer insulating film, a diffusion preventive film is formed on the second interlayer insulating film. An opening portion reaching the wiring layer is made in the diffusion preventive film. This opening portion is filled with W (tungsten) or the like to form a contact.

After formation of the contact, a metal film such as Ta film is formed and then a film stack having a ferromagnetic film, a tunnel insulating film, and another ferromagnetic film is formed on the metal film. Photolithography and etching are performed to process the film stack and the metal film to form a strap line on the diffusion preventive film. A magnetic tunnel resistance element is then formed on this strap line.

### SUMMARY

In the manufacturing method of a semiconductor device described in Japanese Patent Laid-Open No. 2007-165505, when the film stack and the metal film having on the top surface thereof the film stack are processed to form the strap line and the magnetic tunnel resistance element, first a photoresist is formed on the film stack, followed by patterning of the photoresist.

With the patterned photoresist as a mask and the metal film as a stopper, the film stack is dry etched. The magnetic tunnel resistance element is thus formed on the metal film. Ashing is then performed in order to remove the remaining photoresist. The metal film is then patterned to form the strap line.

The metal film which will be the strap line is exposed to a gas atmosphere of from about 100 to 300° C. upon dry etching of the film stack. In addition, the metal film is exposed to ashing plasma upon ashing treatment. These treatments oxidize or nitride the metal film, causing expansion of it. The substrate thus treated is then discharged from a plasma etching apparatus and loaded in the next apparatus. During this transport, the substrate is cooled, the metal film shrinks, and wafer warp occurs.

Since adhesion between the diffusion preventive film which is an insulating film and the wiring layer which is a metal film is low, peeling occurs between the diffusion preventive film and the wiring layer when the metal film shrinks and wafer warp occurs.

In view of the above problem, the present invention has been made. An object of the invention is to provide a semiconductor device in which peeling between an insulating film having on the top surface thereof a strap line and a wiring formed on the bottom surface of the insulating film is inhibited; and a manufacturing method of the semiconductor device.

In one aspect of the invention, there is thus provided a semiconductor device having a semiconductor substrate having: a main surface; a first wiring layer formed over the main surface of the semiconductor substrate and including a first copper wiring; a second wiring layer formed over the first wiring layer and including a second copper wiring; a third wiring layer formed over the second wiring layer and including a magnetic storage element; an insulating film brought into contact with the top surface of the first copper wiring and formed of a silicon carbide (SiC) film or a silicon carbonitride (SiCN) film; and a first silicon nitride (SiCN) film brought into contact with the top surface of the second copper wiring. A rewrite current of the magnetic storage element is caused to pass through the second copper wiring. The second copper wiring includes: a wiring body made of copper; and a stacked metal film covering therewith the bottom surface and the side surface of the wiring body. The stacked metal film is formed of: a first metal film containing at least one element selected from tantalum (Ta), titanium (Ti), ruthenium (Ru), manganese (Mn), magnesium (Mg), and tungsten (W); and a second metal film containing at least one element selected from cobalt (Co), nickel (Ni), and iron (Fe).

In another aspect of the present invention, there is also provided a semiconductor device having: a semiconductor substrate having a main surface; a first wiring layer formed over the main surface of the semiconductor substrate and including a first copper wiring; a second wiring layer formed over the first wiring layer and including a second copper wiring; and a third wiring layer formed over the second wiring layer and including a magnetic storage element. The first wiring layer is brought into contact with the top surface of the first copper wiring and includes an insulating film formed of a silicon carbide (SiC) film or a silicon carbonitride (SiCN) film. The second wiring layer includes: a first silicon nitride (SiN) film brought into contact with the top surface of the second copper wiring; and a third wiring located with a space from the second copper wiring. The third wiring layer includes: a first plug coupled to the upper portion of the third copper wiring; and a first strap line coupling the upper portion of the first plug to the bottom portion of the magnetic storage element.

In a further aspect of the invention, there is also provided a manufacturing method of a semiconductor device having the steps of: preparing a semiconductor substrate having a main surface; forming first wiring layers over the main surface; forming a second wiring layer over the first wiring layer which lies at the top of the first wiring layers; and forming, over the second wiring layer, a third wiring layer including a magnetic storage element. The step of forming the first wiring layers further has the steps of: forming a first insulating film; forming a first copper wiring in the first insulating film; and forming an insulating film contiguous to the top surface of the first copper wirings and formed of a silicon carbide (SiC) film or a silicon carbonitride (SiCN) film. The step of forming the second wiring layer further has the steps of: forming a second insulating film over the first wiring layers; forming a second copper wiring over the second insulating film; and forming, over the second copper wiring, a first silicon nitride (SiN) to be brought into contact with the top surface of the second copper wiring. The step of forming the second copper wiring further has the steps of: forming a first trench portion in the second insulating film; forming, over the side surface and the bottom surface of the first trench portion, a film stack of a first metal film containing at least one element selected from tantalum (Ta), titanium (Ti), ruthenium (Ru), manganese (Mn), magnesium (Mg), and tungsten (W) and a second metal film containing at least one element selected from cobalt (Co), nickel (Ni), and iron (Fe); and forming a wiring body formed of copper in the first trench portion having the film stack therein.

In a still further aspect of the invention, there is also provided a manufacturing method of a semiconductor device having the steps of: preparing a semiconductor substrate having a main surface; forming a first wiring layer over the main surface; forming a second wiring layer over the first wiring layer; and forming, over the second wiring layer, a third wiring layer including a magnetic storage element. The step of forming the first wiring layer further has the steps of: forming a first insulating film; forming a first copper wiring in the first insulating film; and forming an insulating film made of a silicon carbide (SiC) film or a silicon carbonitride (SiCN) film so as to bring it into contact with the top surface of the first copper wiring. The step of forming the second wiring layer further has the steps of: forming a second insulating film; forming a second copper wiring and a third copper wiring in the second insulating film; and forming a first silicon nitride (SiN) film to be brought into contact with the top surface of the second copper wiring. The step of forming the third wiring layer further has the steps of; forming a first plug to be coupled to the upper portion of the third copper wiring; and forming a first strap line coupling the upper portion of the first plug to the bottom portion of the magnetic storage element.

In the semiconductor device and the manufacturing method thereof according to the invention, peeling between an insulating film formed on the bottom surface of a strap line and a wiring layer formed on the bottom surface of this insulating film can be inhibited.

### BRIEF DESCRIPTION OF THE DRAWINGS

FIG. 1 is a plan view schematically illustrating the layout of a chip having thereon a semiconductor device of First Embodiment according to the present invention;

FIG. 2 is a schematic view illustrating an MRAM 100;

FIG. 3 is a plan view schematically illustrating the positional relationship among a bit line BL, a magnetic storage element MR, and a digit line DL;

FIG. 4 is a cross-sectional view of the MRAM 100.

FIG. 5 is an enlarged cross-sectional view of a wiring layer LL3 and a portion therearound;

FIG. 6 is a cross-sectional view taken along a line VI-VI of FIG. 5;

FIG. 7 is a cross-sectional view of a peripheral circuit 200;

FIG. 8 is a cross-sectional view showing a first manufacturing step of a wiring layer LL1 of the MRAM 100;

FIG. 9 is a cross-sectional view showing a manufacturing step following that shown in FIG. 8;

FIG. 10 is a cross-sectional view showing a manufacturing step following that shown in FIG. 9;

FIG. 11 is a cross-sectional view showing a manufacturing step following that shown in FIG. 10;

FIG. 12 is a cross-sectional view showing a manufacturing step following that shown in FIG. 11;

FIG. 13 is a cross-sectional view showing a manufacturing step following that shown in FIG. 12;

FIG. 14 is a cross-sectional view showing a manufacturing step following that shown in FIG. 13;

FIG. 15 is a cross-sectional view showing a manufacturing step following that shown in FIG. 14;

FIG. 16 is a cross-sectional view showing a manufacturing step following that shown in FIG. 15;

FIG. 17 is a cross-sectional view showing a manufacturing step following that shown in FIG. 16;

FIG. 18 is a cross-sectional view showing a manufacturing step following that shown in FIG. 17;

FIG. 19 is a cross-sectional view showing a manufacturing step following that shown in FIG. 18;

FIG. 20 is a cross-sectional view showing a manufacturing step following that shown in FIG. 19;

FIG. 21 is a cross-sectional view showing a portion of the MRAM 100 when a wiring L2 is formed and it corresponds to the cross-section shown in FIG. 5;

FIG. 22 is a cross-sectional view showing the MRAM 100 when the wiring L2 is formed and it corresponds to the cross-section shown in FIG. 6;

FIG. 23 is a cross-sectional view of the peripheral circuit 200 when the wiring L2 is formed and it corresponds to the cross-section shown in FIG. 7;

FIG. 24 is a cross-sectional view showing a manufacturing step following that shown in FIG. 21;

FIG. 25 is a cross-sectional view showing a manufacturing step following that shown in FIG. 22;

FIG. 26 is a cross-sectional view showing a manufacturing step following that shown in FIG. 23;

FIG. 27 is a cross-sectional view showing a manufacturing step following that shown in FIG. 24;

FIG. 28 is a cross-sectional view showing a manufacturing step following that shown in FIG. 25;

FIG. 29 is a cross-sectional view showing a manufacturing step following that shown in FIG. 26;

FIG. 30 is a cross-sectional view showing a manufacturing step following that shown in FIG. 27;

FIG. 31 is a cross-sectional view showing a manufacturing step following that shown in FIG. 28;

FIG. 32 is a cross-sectional view showing a manufacturing step following that shown in FIG. 29;

FIG. 33 is a cross-sectional view showing a manufacturing step following that shown in FIG. 30;

FIG. 34 is a cross-sectional view showing a manufacturing step following that shown in FIG. 31;

FIG. 35 is a cross-sectional view showing a manufacturing step following that shown in FIG. 32;

FIG. 36 is a cross-sectional view showing a manufacturing step following that shown in FIG. 33;

FIG. 37 is a cross-sectional view showing a manufacturing step following that shown in FIG. 34;

FIG. 38 is a cross-sectional view showing a manufacturing step following that shown in FIG. 35;

FIG. 39 is a cross-sectional view showing a manufacturing step following that shown in FIG. 36;

FIG. 40 is a cross-sectional view showing a manufacturing step following that shown in FIG. 37;

FIG. 41 is a cross-sectional view showing a manufacturing step following that shown in FIG. 38;

FIG. 42 is a cross-sectional view showing a manufacturing step following that shown in FIG. 39;

FIG. 43 is a cross-sectional view showing a manufacturing step following that shown in FIG. 40;

FIG. 44 is a cross-sectional view showing a manufacturing step following that shown in FIG. 41;

FIG. 45 is a cross-sectional view showing a manufacturing step following that shown in FIG. 42;

FIG. 46 is a cross-sectional view showing a manufacturing step following that shown in FIG. 43;

FIG. 47 is a cross-sectional view showing a manufacturing step following that shown in FIG. 44;

FIG. 48 is a cross-sectional view showing a manufacturing step following that shown in FIG. 45;

FIG. 49 is a cross-sectional view showing a manufacturing step following that shown in FIG. 46;

FIG. 50 is a cross-sectional view showing a manufacturing step following that shown in FIG. 47;

FIG. 51 is a cross-sectional view showing a manufacturing step following that shown in FIG. 48;

FIG. 52 is a cross-sectional view showing a manufacturing step following that shown in FIG. 49;

FIG. 53 is a cross-sectional view showing a manufacturing step following that shown in FIG. 50;

FIG. 54 is a cross-sectional view showing a manufacturing step following that shown in FIG. 51;

FIG. 55 is a cross-sectional view showing a manufacturing step following that shown in FIG. 52;

FIG. 56 is a cross-sectional view showing a manufacturing step following that shown in FIG. 53;

FIG. 57 is a cross-sectional view showing a manufacturing step following that shown in FIG. 54;

FIG. 58 is a cross-sectional view showing a manufacturing step following that shown in FIG. 55;

FIG. 59 is a cross-sectional view showing a manufacturing step following that shown in FIG. 56;

FIG. 60 is a cross-sectional view showing a manufacturing step following that shown in FIG. 57;

FIG. 61 is a cross-sectional view showing a manufacturing step following that shown in FIG. 58;

FIG. 62 is a cross-sectional view showing a manufacturing step following that shown in FIG. 59;

FIG. 63 is a cross-sectional view showing a manufacturing step following that shown in FIG. 60;

FIG. 64 is a cross-sectional view showing a manufacturing step following that shown in FIG. 61;

FIG. 65 is a cross-sectional view showing a manufacturing step following that shown in FIG. 62;

FIG. 66 is a cross-sectional view showing a manufacturing step following that shown in FIG. 63;

FIG. 67 is a cross-sectional view showing a manufacturing step following that shown in FIG. 64;

FIG. 68 is a cross-sectional view showing a manufacturing step following that shown in FIG. 65;

FIG. 69 is a cross-sectional view showing a manufacturing step following that shown in FIG. 666;

FIG. 70 is a cross-sectional view showing a manufacturing step following that shown in FIG. 67;

FIG. 71 is a cross-sectional view showing a manufacturing step following that shown in FIG. 68;

FIG. 72 is a cross-sectional view showing a manufacturing step following that shown in FIG. 69;

FIG. 73 is a cross-sectional view showing a manufacturing step following that shown in FIG. 70;

FIG. 74 is a cross-sectional view showing a manufacturing step following that shown in FIG. 71;

FIG. 75 is a cross-sectional view showing a manufacturing step following that shown in FIG. 72;

FIG. 76 is a cross-sectional view showing a manufacturing step following that shown in FIG. 73;

FIG. 77 is a cross-sectional view showing a manufacturing step following that shown in FIG. 74;

FIG. 78 is a cross-sectional view showing a manufacturing step following that shown in FIG. 75;

FIG. 79 is a cross-sectional view showing a manufacturing step following that shown in FIG. 76;

FIG. 80 is a cross-sectional view showing a manufacturing step following that shown in FIG. 77;

FIG. 81 is a cross-sectional view showing a manufacturing step following that shown in FIG. 78;

FIG. 82 is a cross-sectional view showing a manufacturing step following that shown in FIG. 79;

FIG. 83 is a cross-sectional view showing a manufacturing step following that shown in FIG. 80;

FIG. 84 is a cross-sectional view showing a manufacturing step following that shown in FIG. 81;

FIG. 85 is a cross-sectional view showing a manufacturing step following that shown in FIG. 82;

FIG. 86 is a cross-sectional view showing a manufacturing step following that shown in FIG. 83;

FIG. 87 is a cross-sectional view showing a manufacturing step following that shown in FIG. 84;

FIG. 88 is a cross-sectional view showing a manufacturing step following that shown in FIG. 85;

FIG. 89 is a cross-sectional view showing a manufacturing step following that shown in FIG. 86;

FIG. 90 is a cross-sectional view showing a manufacturing step following that shown in FIG. 87;

FIG. 91 is a cross-sectional view showing a manufacturing step following that shown in FIG. 88;

FIG. 92 is a cross-sectional view showing a manufacturing step following that shown in FIG. 89;

FIG. 93 is a graph, in the MRAMs 100 of FIG. 5 obtained by forming a strap line SL using different metals respectively, showing the number (proportion) of peelings which have occurred between the digit line DL, a peripheral wiring P2, or the like and a diffusion preventive film NF3 during the manufacturing procedure of the MRAM 100;

FIG. 94 is a graph showing the warp of a semiconductor substrate SS caused by cooling of the semiconductor substrate SS after patterning of a magnetic storage element MR when various strap lines SL are employed;

FIG. 95 is a cross-sectional view of a peripheral circuit 200 of a semiconductor device according to Second Embodiment of the present invention;

FIG. 96 is a graph showing the mutual relationship between a width of a peripheral wiring P2 and peeling which occurs between the peripheral wiring and a diffusion preventive film NF2;

FIG. 97 is a cross-sectional view showing one of the manufacturing steps of the semiconductor device according to Second Embodiment of the present invention and it is a cross-sectional view corresponding to the step of FIG. 32;

FIG. 98 is a cross-sectional view showing a manufacturing step following that shown in FIG. 97;

FIG. 99 is a cross-sectional view showing a manufacturing step following that shown in FIG. 98;

FIG. 100 is a cross-sectional view showing a manufacturing step following that shown in FIG. 99;

FIG. 101 is a cross-sectional view of a peripheral circuit 200 of a semiconductor device according to Third Embodiment of the present invention;

FIG. 102 is a cross-sectional view showing one of the manufacturing steps of the peripheral circuit 200 of the semiconductor device according to Third Embodiment of the present invention;

FIG. 103 is a cross-sectional view showing a manufacturing step following that shown in FIG. 102;

FIG. 104 is a cross-sectional view showing a manufacturing step following that shown in FIG. 103;

FIG. 105 is a cross-sectional view showing a manufacturing step following that shown in FIG. 104;

FIG. 106 is a cross-sectional view showing a manufacturing step following that shown in FIG. 105;

FIG. 107 is a cross-sectional view showing a modification example of the peripheral circuit 200;

FIG. 108 is a cross-sectional view showing one of the manufacturing steps of the peripheral circuit 200 shown in FIG. 107;

FIG. 109 is a cross-sectional view showing a manufacturing step following that shown in FIG. 108;

FIG. 110 is a cross-sectional view showing a manufacturing step following that shown in FIG. 109;

FIG. 111 is a cross-sectional view of an MRAM 100 loaded on a semiconductor device according to Fourth Embodiment of the present invention;

FIG. 112 is a cross-sectional view showing one of the manufacturing steps of the MRAM 100 according to Fourth Embodiment of the present invention;

FIG. 113 is a cross-sectional view showing a manufacturing step following that shown in FIG. 112;

FIG. 114 is a cross-sectional view showing a manufacturing step following that shown in FIG. 113;

FIG. 115 is a cross-sectional view showing a manufacturing step following that shown in FIG. 114;

FIG. 116 is a cross-sectional view showing a manufacturing step following that shown in FIG. 115;

FIG. 117 is a cross-sectional view showing a manufacturing step following that shown in FIG. 116;

FIG. 118 is a cross-sectional view showing a manufacturing step following that shown in FIG. 117;

FIG. 119 is a cross-sectional view showing a manufacturing step following that shown in FIG. 118;

FIG. 120 is a cross-sectional view showing a manufacturing step following that shown in FIG. 119; and

FIG. 121 is a cross-sectional view showing a manufacturing step following that shown in FIG. 120;

### DETAILED DESCRIPTION

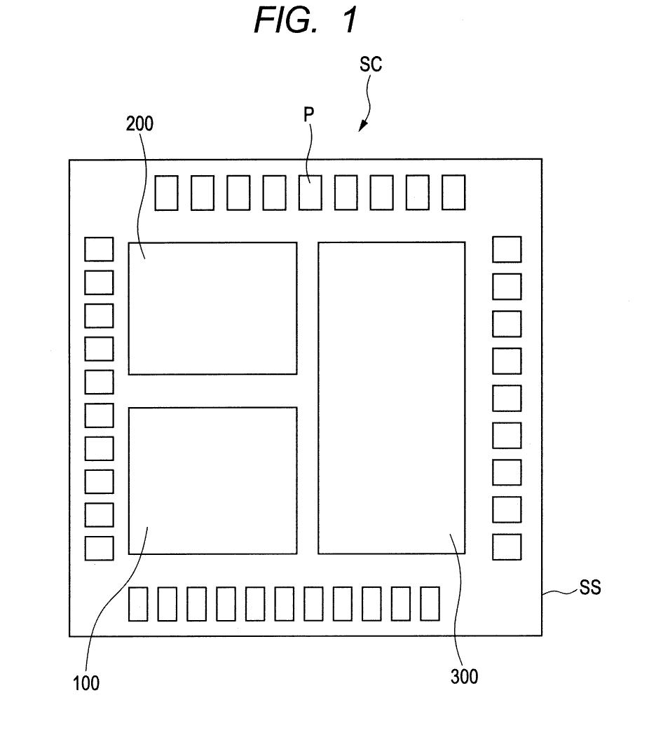

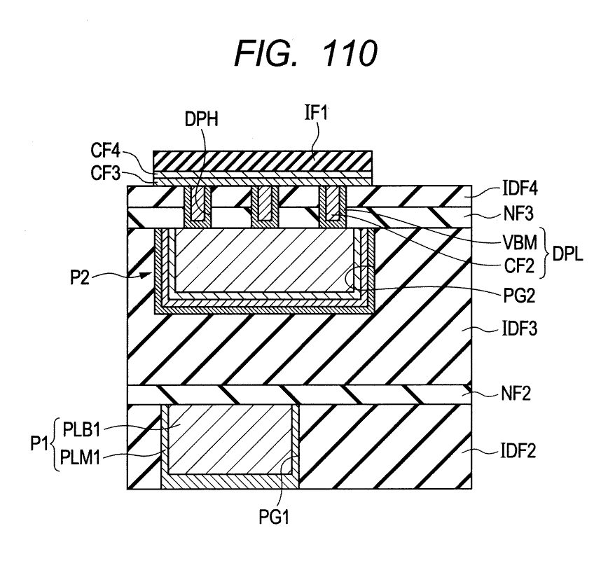

Referring to FIGS. 1 to 110, embodiments of the invention will next be described. In the embodiments described below, when a reference is made to the number, amount, or the like, the number, amount, or the like is not always limited to the specific one unless otherwise specifically indicated. In addition, in the embodiments described below, the configuring elements are not always essential in the invention unless otherwise specifically indicated. When the following description includes two or more embodiments, it is evident from the beginning that characteristic parts of these embodiments may be used in combination as needed unless otherwise specifically indicated.

### First Embodiment

FIG. 1 is a plan view schematically illustrating the layout of a chip having thereon a semiconductor device of First Embodiment according to the present invention. As illustrated in FIG. 1, a semiconductor chip (semiconductor device) SC is equipped with a semiconductor substrate SS, an MRAM 100 formed over the main surface of the semiconductor substrate SS, a peripheral circuit 200, a CPU 300, and a plurality of pad portions P formed at the periphery of the semiconductor substrate SS. The CPU 300 is a unit that performs a variety of arithmetic processing.

The MRAM 100 is a memory capable of storing data, reading out the stored data, and rewriting the data. The MRAM 100 is a non-volatile semiconductor storage device. The peripheral circuit 200 includes a power circuit, clock circuit, reset circuit, and the like.

The pad portion P is an input/output terminal portion for coupling the semiconductor chip SC to an external circuit.

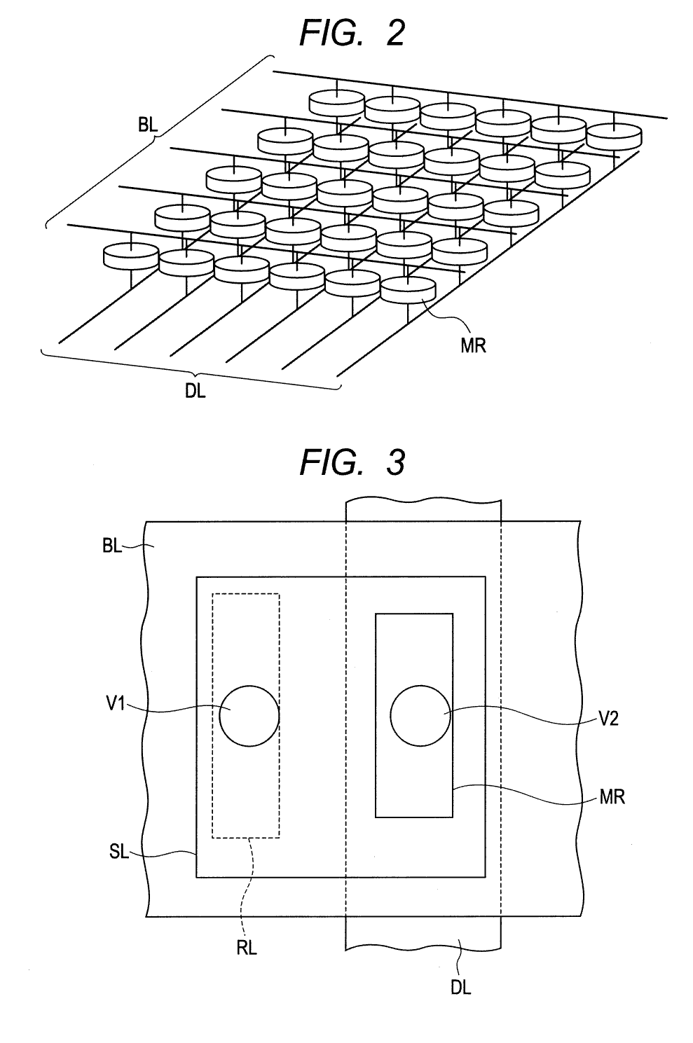

FIG. 2 is a schematic view of the MRAM 100. As illustrated in FIG. 2, the MRAM 100 has a plurality of magnetic storage elements MR, a plurality of digit lines DL extending in one direction, and a plurality of bit lines BL placed above these digit lines DL and extending in a direction intersecting with the digit lines DL.

In a planar view, the bit line BL and the digit line DL have, at the intersection thereof, the magnetic storage element MR.

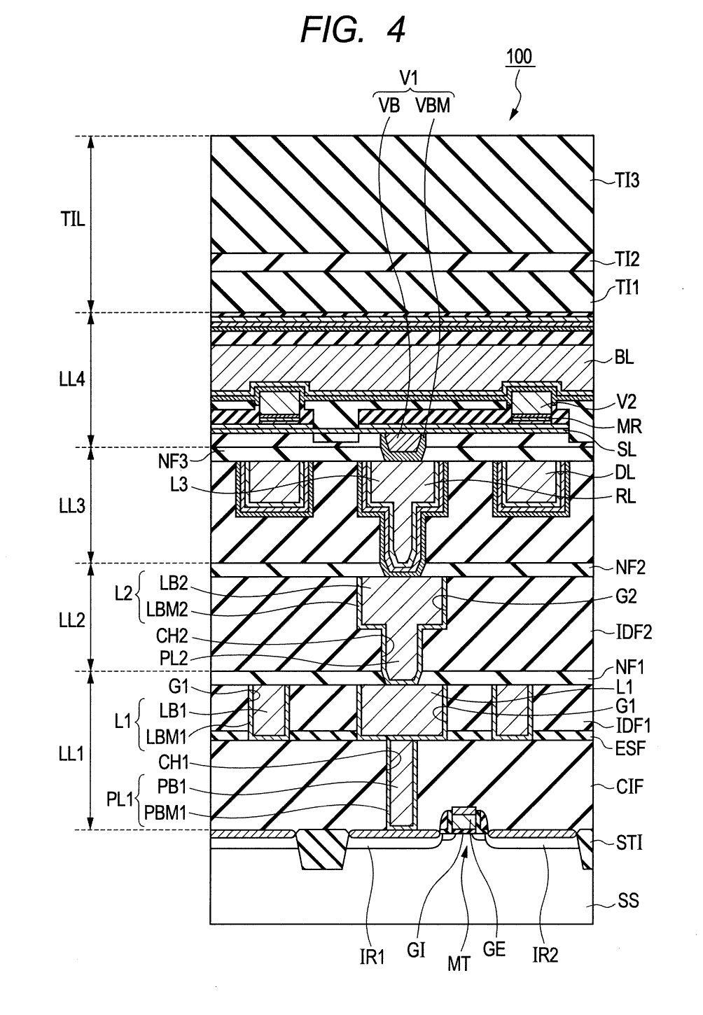

FIG. 3 is a plan view schematically illustrating the positional relationship among the bit line BL, the magnetic storage element MR, and the digit line DL. FIG. 4 is a cross-sectional view of the MRAM 100.

In these FIGS. 3 and 4, the bit line BL and the digit line DL have therebetween the magnetic storage element MR and the magnetic storage element MR is, at an upper end portion thereof, coupled to the bit line BL via a via plug V2. The magnetic storage element MR is formed on the top surface of a strap line SL and the strap line SL is coupled to a read-out wiring RL via a via plug V1.

In the magnetic storage element MR, a fixed layer made of a ferromagnetic layer whose magnetization direction is fixed and a free layer made of a ferromagnetic layer whose magnetization direction changes depending on a magnetic field applied from outside are placed via a tunnel insulating film so as to face to each other.

In this magnetic storage element MR, electrical resistance between the fixed layer and the free layer changes depending on the magnetization direction of the free layer.

For example, when the fixed layer and the free layer are the same in the magnetization direction, the magnetic storage element MR has a reduced electrical resistance. When the fixed layer and the free layer are different in the magnetization direction, the magnetic storage element MR has an increased electrical resistance. Accordingly, the magnetic storage element MR is functioned as a memory by associating the electrical resistance with a digital value “0” or “1”.

As illustrated in FIG. 4, the MRAM 100 is equipped with the semiconductor substrate SS having a main surface, a wiring layer (first wiring layer) LL1 formed over the main surface of this semiconductor substrate SS and including a wiring (first wiring) L1, a wiring layer (first wiring) LL2 formed over the top surface of the wiring layer LL1 and including a wiring (first wiring) L2, a wiring layer (second wiring layer) LL3 formed over the wiring layer LL2 and including a wiring L3 (second wiring), and a wiring layer LL4 formed over the wiring layer LL3 and including the magnetic storage element MR. The MRAM 100 is equipped further with an upper insulating layer TIL formed over the wiring layer LL4. Incidentally, the wiring layer LL2 and the wiring layer LL3 have substantially the same film thickness.

The semiconductor substrate SS has, over the main surface thereof, a plurality of element isolation regions STI. The wiring layer LL1 includes an MOS transistor MT formed over the main surface of the semiconductor substrate SS, a plug PL1 coupled to the MOS transistor MT, and the wiring L1 coupled to the upper end portion of the plug PL1. The wiring layer LL1 further includes a contact interlayer insulating film CIF covering therewith the MOS transistor MT, an etching stopper film ESF formed on the top surface of the contact interlayer insulating film CIF, an interlayer insulating film IDF1 formed on the top surface of the etching stopper film ESF, and a diffusion preventive film NF1 formed on the top surface of the interlayer insulating film IDF1.

The MOS transistor MT is formed over an active region partitioned with the element isolation regions STI. The MOS transistor MT is equipped with a gate insulating film GI made of a silicon oxide film or the like, a gate electrode GE formed over the gate insulating film GI, an impurity diffusion layer IR1, and an impurity diffusion layer IR2.

The gate electrode GE is made of a polysilicon film or the like and the gate electrode GE has, on the side surfaces thereof, sidewalls made of a silicon oxide film or the like.

The impurity diffusion layer IR1 is formed in a region of the main surface of the semiconductor substrate SS and adjacent to the gate electrode GE, while the impurity diffusion layer IR2 is formed in a region on the side opposite to the impurity diffusion layer IR1 relative to the gate electrode GE.

The contact interlayer insulating film CIF covers therewith the MOS transistor MT. The contact interlayer insulating film CIF is made of an ozone TEOS (tetra-ethyl-ortho-silicate) film or the like. The plug PL1 penetrates through the contact interlayer insulating film CIF. The contact interlayer insulating film CIF has therein a contact hole CH1 penetrating through the contact interlayer insulating film CIF and reaching the impurity diffusion layer IR1. The plug PL1 includes a contact barrier metal PBM1 formed on the inner peripheral surface of the contact hole CH1 and a plug body portion PB1 formed over the contact barrier metal PBM1 and filled in the contact hole CH1.

The contact barrier metal PBM1 is made of, for example, a titanium film or a titanium nitride film. The plug body portion PB1 is made of, for example, tungsten (W).

The etching stopper film ESF is formed on the top surface of the contact interlayer insulating film CIF and the etching stopper film ESF is made of a silicon carbonitride film (SiCN film) or a silicon carbide film (SiC film). The interlayer insulating film IDF1 is formed on the top surface of the etching stopper film ESF and this interlayer insulating film IDF1 is made of, for example, a TEOS oxide film.

The etching stopper film ESF and the interlayer insulating film IDF1 have therein a plurality of wirings L1 and the upper portion of the plug PL1 is coupled to one of the wirings L1.

The etching stopper film ESF and the interlayer insulating film IDF1 have therein a trench portion G1. The wiring L1 includes a barrier metal LBM1 formed on the inner peripheral surface of the trench portion G1 and a wiring body portion LB1 formed on the barrier metal LBM1 and filled in the trench portion G1. The barrier metal LBM1 is made of, for example, a titanium/titanium nitride film but alternatively, it may be made of a metal material containing at least one element selected from tantalum (Ta), titanium (Ti), ruthenium (Ru), manganese (Mn), magnesium (Mg), and tungsten (W). The wiring body portion LB1 is made of copper (embracing a metal material composed mainly of copper). The barrier metal LBM1 suppresses diffusion of copper, which configures the wiring body portion LB1 of the wiring L1, to silicon configuring the semiconductor substrate SS upon heat treatment. This makes it possible to prevent variations in threshold value, poor withstand voltage, and the like of the MOS transistor MT and prevent deterioration of the properties of the MOS transistor MT.

The diffusion preventive film NF1 is formed on the top surface of the interlayer insulating film IDF1 and the top surface of the wiring L1. The diffusion preventive film NF1 is made of a silicon carbonitride film (SiCN film) or a silicon carbide film (SiC film).

The etching stopper film ESF, similar to the barrier metal LBM1, prevents copper atoms configuring the wiring L1 from diffusing in the contact interlayer insulating film CIF and the semiconductor substrate SS.

The wiring layer LL1 thus formed has, on the top surface thereof, the wiring layer LL2. The wiring layer LL2 includes an interlayer insulating film IDF2 formed on the top surface of the diffusion preventive film NF1, a plug PL2 and a wiring L2 formed in the interlayer insulating film IDF2, and a diffusion preventive film NF2 covering therewith the top surfaces of the interlayer insulating film IDF2 and the wiring L2. The diffusion preventive film NF2 is made of a silicon carbonitride film (SiCN film) or a silicon carbide film (SiC film), while the interlayer insulating film IDF2 is made of, for example, a TEOS film, a silicon oxide film, an SiOC film, an HSQ film, an MSQ film, or an SiOF film.

The plug PL2 reaches the bottom surface of the wiring L2 and the wiring L2 is coupled to the upper end portion of the plug PL2. The plug PL2 and the wiring L2 are formed in a contact hole CH2 formed in the interlayer insulating film IDF2 and a trench portion G2 communicated with the contact hole CH2.

The plug PL2 and the wiring L2 are formed of a barrier metal LBM2 formed on the inner peripheral surfaces of the contact hole CH2 and the trench portion G2 and a wiring body portion LB2 formed on the barrier metal LBM2 and filled in the trench portion G2 and the contact hole CH2.

The barrier LBM2 is made of a metal material similar to that of the barrier metal LBM1 and the wiring body portion LB2 is, similar to the wiring body portion LB1, made of copper (embracing a metal material composed mainly of copper). The diffusion preventive film NF2 covers therewith the top surface of the wiring L2 and the diffusion preventive film NF2 is, similar to the diffusion preventive film NF1, made of a silicon carbonitride film (SiCN film) or a silicon carbide film (SiC film).

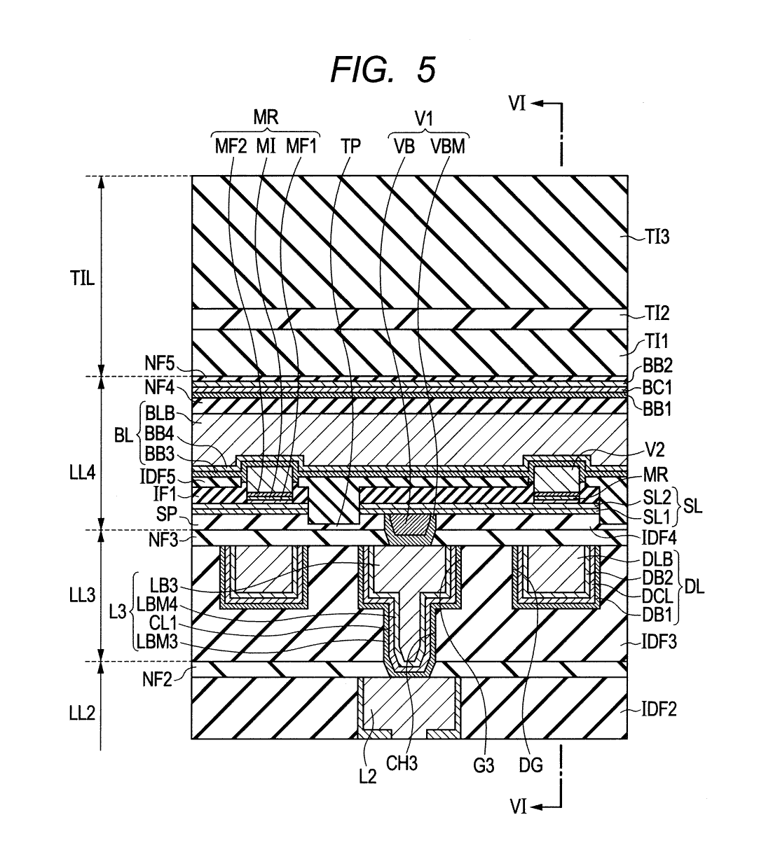

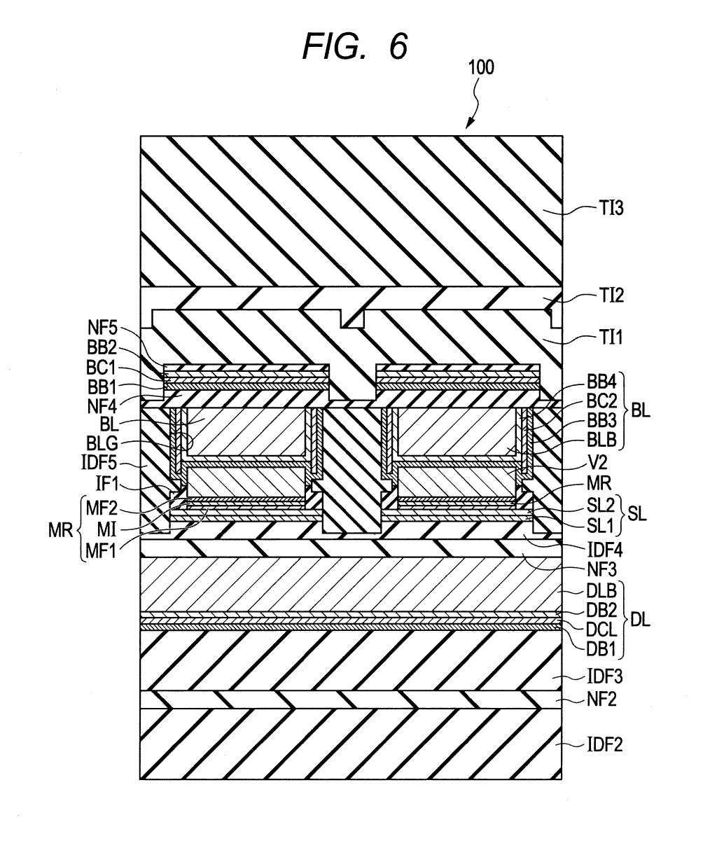

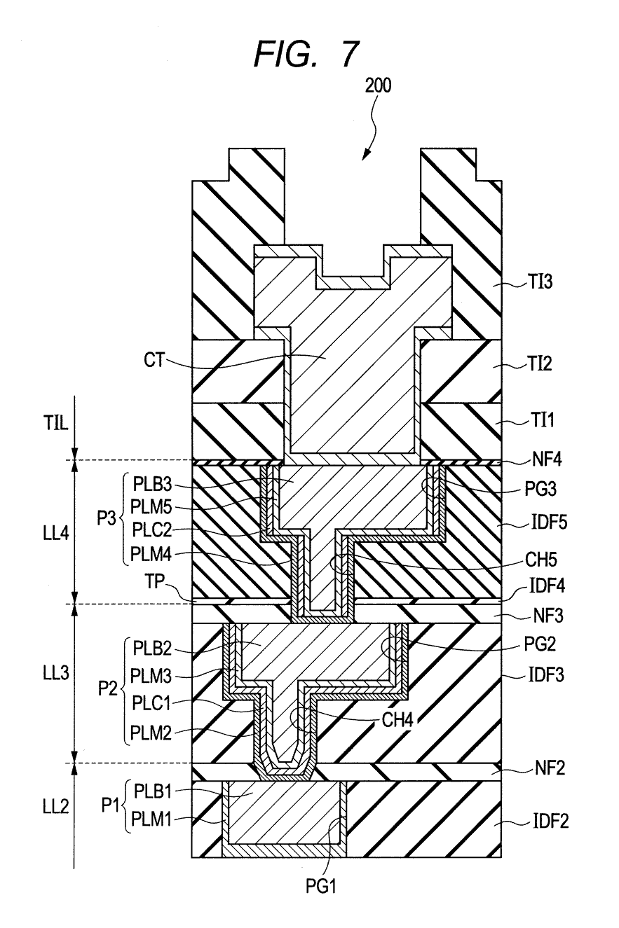

The wiring layer LL2 has, on the top surface thereof, the wiring layer LL3. The wiring layer LL3 has therein the digit line (second wiring) DL. FIG. 5 is an enlarged cross-sectional view of the wiring layer LL3 and a portion therearound. FIG. 6 is a cross-sectional view taken along a line VI-VI of FIG. 5. FIG. 7 is a cross-sectional view of the peripheral circuit 200.

In FIG. 5, the wiring layer LL3 includes an interlayer insulating film IDF3 formed on the top surface of the diffusion preventive film NF2, the wiring L3 penetrating through the interlayer insulating film IDF3 and the diffusion preventive film NF2, the digit line DL formed in the interlayer insulating film IDF3, and a diffusion preventive film NF3 formed on the top surface of the interlayer insulating film IDF3 so as to be contact with the top surfaces of the wiring L3 and the digit line DL. The interlayer insulating film IDF3 is formed of the same material as that of the interlayer insulating film IDF2.

The digit line DL is supplied with an electric current when the data written in the magnetic storage element MR is rewritten. An electric current is also supplied to the bit line BL which will be described later. The electric current passing through the digit line DL causes a magnetic field, while the electric current passing through the bit line BL also causes another magnetic field. With the magnetic field comprised of these two magnetic fields, the data written in the magnetic storage element MR is rewritten.

The digit line DL is formed in a trench portion DG formed in the interlayer insulating film IDF3. The digit line DL includes a stacked metal film (covering metal film) covering the bottom surface and inner side surface of the trench portion DG and a wiring body portion DLB formed on the stacked metal film and filled in the trench portion DG.

The stacked metal film includes a barrier metal (first metal film) DB1 covering therewith the bottom surface and inner side surface of the trench portion DG, a clad layer (second metal film) DCL formed on the barrier metal DB1, and a barrier metal DB2 formed on the clad layer DCL.

The barrier metal DB1 and the barrier metal DB2 are each made of a metal material containing at least one element selected from, for example, tantalum (Ta), titanium (Ti), ruthenium (Ru), manganese (Mn), magnesium (Mg), and tungsten (W). More concretely, titanium, titanium nitride, or the like is used.

The clad layer DCL is made of a high magnetic permeability material and it is made of a metal material containing at least one element selected from cobalt (Co), nickel (Ni), and iron (Fe). More specifically, it is preferred to use, for the clad layer DCL, an alloy such as NiFe (nickel iron), NiFeMo, CoNbZr (cobalt niobium zirconium), CoFeNb, CoFeSiB, CoNbRu, CoNbZrMoCr, or CoZrCrMo, or an amorphous alloy. The wiring body portion DLB is made of copper (embracing a metal material composed mainly of copper).

The wiring L3 is formed in a trench portion G3 and a contact hole CH3 penetrating through the interlayer insulating film IDF3 and the diffusion preventive film NF2 and the wiring L3 is coupled to the upper end portion of the wiring L2. The wiring L3 includes a stacked metal film formed on the inner peripheral surfaces of the trench portion G3 and the contact hole CH3 and a wiring body portion LB3 formed on the top surface of the stacked metal film and filled in the trench portion G3 and the contact hole CH3.

The stacked metal film (covering metal film) has a barrier metal LBM3 formed on the inner peripheral surfaces of the trench portion G3 and the contact hole CH3, a clad layer CL1 formed on the barrier metal LBM3, and a barrier metal LBM4 formed on the clad layer CL1. The barrier metal (first metal film) LBM3 and the barrier metal LBM4 are each made of a metal material containing at least one element selected from, for example, tantalum (Ta), titanium (Ti), ruthenium (Ru), manganese (Mn), magnesium (Mg), and tungsten (W). More specifically, titanium or titanium nitride is employed.

The clad layer (second metal film) CL1 is made of preferably a soft magnetic body having a high magnetic permeability and a very low remnant magnetization. It is preferred to use, for the clad layer CL1, a metal material containing at least one element selected from cobalt (Co), nickel (Ni), and iron (Fe). More specifically, an alloy such as NiFe (nickel iron), NiFeMo, CoNbZr (cobalt niobium zirconium), CoFeNb, CoFeSiB, CoNbRu, CoNbZrMoCr, or CoZrCrMo, or an amorphous alloy is preferred. The wiring body portion LB3 is made of copper (embracing a metal material composed mainly of copper).

In FIG. 4, the wiring L3, the wiring L2, the wiring L1, and the plug PL1 are coupled to each other and they are coupled to the impurity diffusion layer IR1 of the MOS transistor MT. These wiring L3, wiring L2, wiring L1, and plug PL1 function as a read-out wiring RL. The diffusion preventive film NF3 extends from the top surface of the digit line DL to the top surface of the wiring L3 and the top surfaces of the digit line DL and the wiring L3 are covered with the diffusion preventive film NF3.

Even in the peripheral circuit 200, as illustrated in FIG. 7, the wiring layer LL2 has the interlayer insulating film IDF2, a peripheral wiring P1 formed in the interlayer insulating film IDF2, and the diffusion preventive film NF2 covering therewith the top surfaces of the peripheral wiring P1 and the interlayer insulating film IDF2. The interlayer insulating film IDF2 has therein a trench portion PG1 and this trench portion PG1 has therein the peripheral wiring P1.

The peripheral wiring P1 includes a barrier metal PLM1 formed on the side surface and the bottom surface of the trench portion PG1 and a wiring body portion PLB1 formed on the barrier metal PLM1. The barrier metal PLM1 is made of the same metal material as that of the barrier metal LBM2 illustrated in FIG. 4 and the wiring body portion PLB1 is made of the same metal material as that of the wiring body portion LB2.

Even in the peripheral circuit 200, the wiring layer LL3 has the interlayer insulating film IDF3 on the diffusion preventive film NF2 and the interlayer insulating film IDF3 has, on the top surface thereof, the diffusion preventive film NF3.

A peripheral wiring (fourth wiring) P2 penetrates through the interlayer insulating film IDF3 and the diffusion preventive film NF2 and the peripheral wiring P2 is coupled to an upper end portion of the peripheral wiring P1.

The peripheral wiring P2 is formed in a contact hole CH4 formed in the diffusion preventive film NF2 and the interlayer insulating film IDF3 and also in a trench portion PG2 associated with this contact hole CH4.

The peripheral wiring P2 has a stacked metal film (covering metal film) formed on the bottom surface and the side surface of the contact hole CH4 and the trench portion PG2 and a wiring body portion PLB2 formed on the top surface of this stacked metal film.

The stacked metal film includes a barrier metal PLM2, a clad layer PLC1 formed on the barrier metal PLM2, and a barrier metal PLM3 formed on the clad layer PLC1.

The barrier metal PLM2 is made of the same metal material as that of the barrier metal LBM3 illustrated in FIG. 5. The clad layer PLC1 is made of the same metal material as that of the clad layer CL1 illustrated in FIG. 5. The barrier metal PLM3 is made of the same metal material as that of the barrier metal LBM4 illustrated in FIG. 5. The wiring body portion PLB2 is also made of the same metal material as that of the wiring body portion LB3 illustrated in FIG. 5.

As illustrated in FIGS. 5 and 7, the diffusion preventive film NF3 is brought into contact with the top surfaces of the peripheral wiring P2, the digit line DL, and the wiring L3. The wiring body portion PLB2, the wiring body portion LB3, and the wiring body portion DLB are each made of copper (embracing a metal material composed mainly of copper) and the diffusion preventive film NF3 is made of a silicon nitride (SiN) film, more specifically, an LT (low temperature)-SiN film. The LT (low temperature)-SiN film has higher hardness than a silicon carbonitride film (SiCN film) or a silicon carbide film (SiC film) so that peeling of the diffusion preventive film NF3 from the wiring body portion PLB2, the wiring body portion LB3, and the wiring body portion DLB is inhibited.

In FIG. 5, the wiring layer LL4 of the MRAM 100 includes an interlayer insulating film (first interlayer insulating film) IDF4 formed on the diffusion preventive film NF3, a via plug (first plug) V1 penetrating through the diffusion preventive film NF3 and the interlayer insulating film IDF4 and coupled to the upper portion of the wiring (third wiring) L3, and a strap line SL coupled to the upper portion of the via plug V1 and formed on the top surface of the interlayer insulating film IDF4.

The interlayer insulating film IDF4 has a plurality of thick film portions SP provided with a space in an extending direction of the bit line BL and thin film portions TP provided between the thick film portions SP. The thick film portion SP extends from a portion of the top surface of the diffusion preventive film NF3 located on the digit line DL to a portion of it located on the wiring L3. The interlayer insulating film IDF4 has, on the top surface of the thick film portion SP, the strap line SL.

The strap line SL is a stacked metal film having a first metal film SL1 formed on the thick film portion SP of the interlayer insulating film IDF4 and a second metal film SL2 formed on the first metal film SL1. The first metal film SL1 is made of a titanium (Ti) film, while the second metal film SL2 is made of a titanium nitride (TiN) film.

The interlayer insulating film IDF4 and the diffusion preventive film NF3 has a via hole extending from the top surface of the interlayer insulating film IDF4 to the top surface of the wiring L3.

The via plug V1 includes a barrier metal VBM and a via body VB composed of a metal material such as tungsten or copper, each in the via hole. The via plug V1 is, at the top surface thereof, brought into contact with the first metal film SL1. The barrier metal VBM is made of, for example, a titanium/titanium nitride film. It may alternatively be made of a metal material containing at least one element selected from tantalum (Ta), titanium (Ti), ruthenium (Ru), manganese (Mn), magnesium (Mg), and tungsten (W).

The strap line SL has, on the second metal film SL2 thereof, a magnetic storage element MR. The magnetic storage element MR is equipped with a fixed magnetization layer MF1 formed on the second metal film SL2, a tunnel insulating film M1 formed on the top surface of this fixed magnetization layer MF1, and a free magnetization layer MF2 formed on the top surface of the tunnel insulating film M1.

The fixed magnetization layer MF1 is a layer whose magnetization direction is fixed and the magnetized direction of it does not change, depending on an external magnetic field.

The tunnel insulating film MI separates the fixed magnetization layer MF1 from the free magnetization layer MF2 and the tunnel insulating film MI is made of, for example, a metal oxide film such as aluminum oxide film or magnesium oxide film.

The free magnetization layer MF2 is a layer whose magnetization direction can change, depending on an external magnetic field and it is made of a ferromagnetic film.

The fixed magnetization layer MF1 and the free magnetization layer MF2 are each made of a ferromagnetic material composed mainly of, for example, nickel, iron, and/or cobalt. These ferromagnetic materials may be introduced with an additive such as boron, nitrogen, silicon, or molybdenum in order to improve their magnetic properties and heat stability. As the fixed magnetization layer and the free magnetization layer, materials called “half metal” such as NiMnSb, Co₂Mn(Ge,Si), Co₂Fe(Al,Si), and (Zn,Mn)Fe₂O₄ may be used. Half metals can produce a markedly large magnetic effect because of an energy gap present in one of spin bands, which results in a large signal output. As an example of the combination of the fixed magnetization layer and the free magnetization layer, a stack structure of a platinum manganese alloy film and a cobalt iron alloy film may be used as the fixed magnetization layer and a nickel iron alloy film may be used as the free magnetization layer.

The magnetic storage element MR has, on the free magnetization layer MF2 thereof, a via plug V2 and this via plug V2 is, at the upper end portion thereof, coupled to the bit line BL which will be described later.

The strap line SL has, on the top surface thereof, an insulating film IF1. The insulating film IF1 is formed of a silicon nitride (SiN) film. The insulating film IF1 covers therewith the top surface of the strap line SL and at the same time, covers the side surface of the magnetic storage element MR and a portion of the side surface of the via plug V2.

The insulating film IF1 is, as described above, made of a silicon nitride (SiN) film and formed of the same insulating film as that of the diffusion preventive film NF3. On the other hand, the diffusion preventive films NF2 and NF1 lying below the digit line DL are formed of a silicon carbonitride film (SiCN film) or a silicon carbide film (SiC film).

The silicon nitride (SiN) film can be formed at a temperature lower than that of the silicon carbonitride (SiCN) film. The diffusion preventive film NF3, the insulating film IF1, or the like lying over the digit line DL can therefore be formed at a low temperature, making it possible to prevent occurrence of hillocks (protrusions) in the digit line DL. The insulating film IF1 has thereon an interlayer insulating film IDF5. The interlayer insulating film IDF5 is made of, for example, a silicon oxide film.

As illustrated in FIG. 6, the interlayer insulating film IDF5 has therein a trench portion BLG in an extending direction of the bit line BL and this trench portion BLG has therein the bit line BL. Incidentally, the upper end portion of the via plug V2 protrudes into this trench portion BLG.

The bit line BL includes a barrier metal BB3, a barrier metal BB4 formed on the barrier metal BB3, a clad layer BC2, and a bit line body portion BLB. The barrier metal BB3 covers therewith the bottom surface and side surface of the trench portion BLG and the barrier metal BB3 is formed of the same metal material as that of the barrier metal DB1 or the like. For example, the barrier metal BB3 is formed of a metal material such as tantalum (Ta) or tantalum nitride (TaN). Alternatively, it may be made of a metal material containing at least one element selected from tantalum (Ta), titanium (Ti), ruthenium (Ru), manganese (Mn), magnesium (Mg), and tungsten (W).

The clad layer BC2 is formed on the inner side surface of the barrier metal BB3. The clad layer BC2 is formed of the same metal material as that of the clad layer DCL. For example, the clad layer BC2 is formed of NiFe or the like. Incidentally, in the cross-sectional view of FIG. 5, the clad layer BC2 is located in front and back of the sheet so that it is not illustrated in FIG. 5.

In FIG. 6, the barrier metal BB4 is formed on the side surface of the clad layer BC2 and the bottom surface of the barrier metal BB3 and the barrier metal BB4 is formed of the same metal material as that of the barrier metal DB2. For example, the barrier metal BB4 is formed of tantalum (Ta) or tantalum nitride (TaN). Alternatively, it may be made of a metal material containing at least one element selected from tantalum (Ta), titanium (Ti), ruthenium (Ru), manganese (Mn), magnesium (Mg), and tungsten (W).

The bit line body portion BLB is formed on the barrier metal BB4 and is filled in the trench portion BLG. The bit line body portion BLB is formed of copper (embracing a metal composed mainly of copper).

The interlayer insulating film IDF5 has, on the top surface thereof, a diffusion preventive film NF4 and this diffusion preventive film NF4 is brought into contact with the top surface of the bit line body portion BLB and the top surfaces of the barrier metal BB4, the clad layer BC2, and the barrier metal BB3. The diffusion preventive film NF4 is formed of a silicon nitride (SiN) film similar to the diffusion preventive film NF3 and the insulating film IF1.

The diffusion preventive film NF4 has thick film portions and thin film portions. The thin film portions are each placed between two adjacent thick film portions and thinner than the thick film portions. The thick film portion of the diffusion preventive film NF4 is located on the top surface of the bit line BL, while the thin film portion of the diffusion preventive film NF4 is located on the top surface of the interlayer insulating film IDF5 between the top surfaces of the bit lines BL. The diffusion preventive film NF4 has, on the thick film portion thereof, a stacked metal film (covering metal film) obtained by successively stacking a barrier metal BB1, a clad layer BC1, and a barrier metal BB2 one after another.

The barrier metal BB1 and the barrier metal BB2 are made of the same metal material as that of the barrier metal BB3 and the barrier metal BB4. For example, they may be formed of tantalum (Ta) or tantalum nitride (TaN). Alternatively, they may each be made of a metal material containing at least one element selected from tantalum (Ta), titanium (Ti), ruthenium (Ru), manganese (Mn), magnesium (Mg), and tungsten (W). The clad layer BC1 is also formed of the same metal material as that of the clad layer BC2 or the clad layer DCL.

Thus, the wiring layer LL4 of the MRAM 100 is formed of a plurality of layers located between the interlayer insulating film IDF4 and the barrier metal BB2 and the wiring layer LL4 has therein the via plug V1, the strap line SL, the magnetic storage element MR, and the bit line BL.

In FIG. 7, the wiring layer LL4 of the peripheral circuit 200 includes the diffusion preventive film NF3 located on the top surface of the interlayer insulating film IDF3 and brought into contact with the top surface of the peripheral wiring P2, the thin film portion TP of the interlayer insulating film IDF4 formed on this diffusion preventive film NF3, the interlayer insulating film IDF5 formed on the thin film portion TP, and the diffusion preventive film NF4 formed on the top surface of the interlayer insulating film IDF5. The wiring layer LL4 includes a peripheral wiring P3 penetrating through the diffusion preventive film NF3, the interlayer insulating film IDF4, and the interlayer insulating film IDF5.

The peripheral wiring P3 is coupled to the upper end portion of the peripheral wiring P2 and the peripheral wiring P3 is formed in a contact hole CH5 and a trench portion PG3 formed in the diffusion preventive film NF3, the interlayer insulating film IDF4, and the interlayer insulating film IDF5.

The peripheral wiring P3 has a barrier metal PLM4 formed on the inner side surface and bottom surface of the contact hole CH5 and the trench portion PG3, a clad layer PLC2 formed on the side surface of the barrier metal PLM4, a barrier metal PLM5 formed on the bottom surface of the barrier metal PLM4 and the side surface of the clad layer PLC2, and a wiring body portion PLB3.

The barrier metal PLM4 is made of the same metal material as that of the barrier metal BB3 illustrated in FIG. 6 and the clad layer PLC2 is formed of the same metal material as that of the clad layer BC2 illustrated in FIG. 6. The barrier metal PLM5 is made of the same metal material as that of the barrier metal BB4.

The wiring body portion PLB3 is made of the same metal material as that of the bit line body portion BLB illustrated in FIG. 6, more specifically, it is made of copper (metal material composed mainly of copper). The diffusion preventive film NF4 is made of a silicon nitride (SiN) film.

The wiring layer LL4 having such a configuration has, on the top surface thereof, an upper insulating layer TIL. As illustrated in FIGS. 5 to 7, the upper insulating layer TIL includes an upper-layer insulating film TI1 formed on the diffusion preventive film NF5, an upper-layer insulating film TI2 formed on the upper-layer insulating film TI1, and an upper-layer insulating film TI3 formed on the top surface of the upper-layer insulating film TI2.

The upper-layer insulating film TI1 is made of a silicon nitride (SiN) film and the upper-layer insulating film TI2 and the upper-layer insulating film TI3 are each made of a silicon oxide film. In FIG. 7, in the peripheral circuit 200, an outer contact CT penetrating through the upper-layer insulating films TI1, TI2, and TI3 is formed.

The writing and reading-out operations of the MRAM 100 having such a configuration will next be described.

In FIG. 5, when data written in the magnetic storage element MR of the MRAM 100 is rewritten, an electric current is caused to pass through the bit line BL and the digit line DL. Due to the electric current passing through the bit line BL, a magnetic field appears. Similarly, due to the electric current passing through the digit line DL, another magnetic field appears. Depending on the synthetic magnetic field of them, the magnetization direction of the free magnetization layer of the magnetic storage element MR changes. This completes the rewriting of the data in the magnetic storage element MR.

As illustrated in FIG. 6, at the time of rewriting, the bit line BL has, on the side surface of the bit line body portion BLB, the clad layer BC2 and the bit line BL has, thereover, the clad layer BC1.

Thus, the clad layers surrounding therewith the bit line body portion BLB are placed to cover the top surface and the side surface of the bit line body portion BLB and are also placed to open toward the magnetic storage element MR.

The clad layers are each made of a high magnetic permeability material so that a magnetic flux generated when an electric current passes through the bit line BL runs in the clad layers preferentially. As a result, dissipation of the magnetic flux to the outside of the clad layers is inhibited, leading to concentration of the magnetic flux in the magnetic storage element MR.

Similarly, as illustrated in FIG. 5, the side surface and the bottom surface of the wiring body portion DLB of the digit line DL is covered with the clad layer DCL. The clad layer DCL opens toward the magnetic storage element MR located over the digit line DL. The magnetic reflux generated when an electric current passes through this digit line DL is therefore emitted concentratedly to the magnetic storage element MR.

As a result, a synthetic magnetic field produced by the passage of an electric current through the bit line BL and the digit line DL is enhanced. Even if a current amount supplied to the digit line DL and the bit line BL is suppressed, the magnetization direction of the free magnetization layer of the magnetic storage element MR can be changed, making it possible to suppress the power consumption of the MRAM 100.

When the data written in the magnetic storage element MR are read out, a predetermined voltage is applied to the gate electrode GE of the MOS transistor MT illustrated in FIG. 4 and the MOS transistor MT is turned ON.

Then, a predetermined voltage is applied to the bit line BL and the impurity diffusion layer IR2, by which an electric current passes through the bit line BL, the magnetic storage element MR, the strap line SL, the via plug V1, the read-out wiring RL (the wirings L1 to L3 and the plug PL1), the impurity diffusion layer IR1, and the impurity diffusion layer IR2. Since the resistance of the magnetic storage element MR varies depending on the magnetization direction of the free magnetization layer in the magnetic storage element MR, it is possible to read out the data written in the selected magnetic storage element MR by detecting the resistance of the magnetic storage element MR from the current amount passing between the impurity diffusion layer IR2 and the bit line BL.

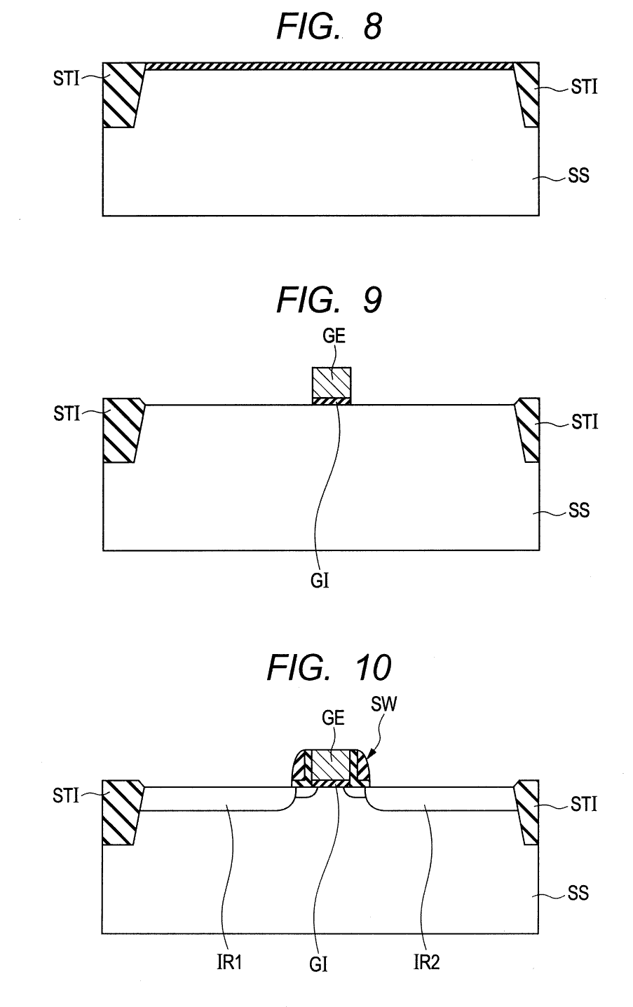

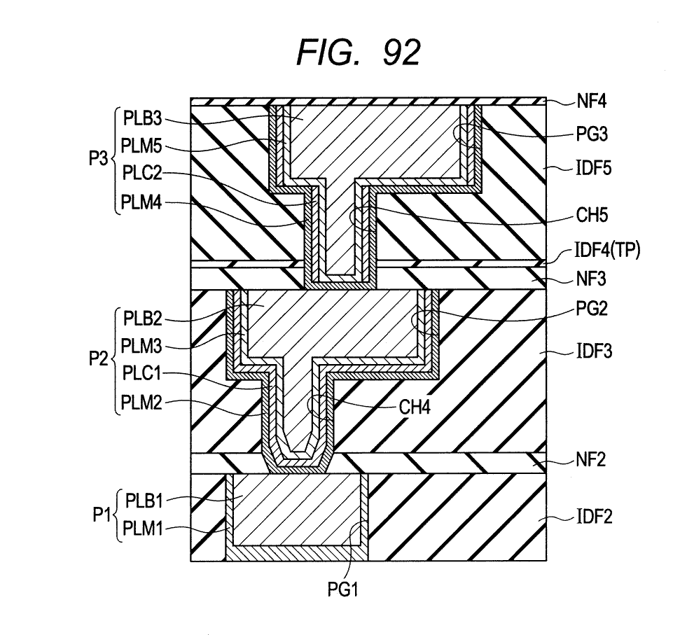

A manufacturing method of the MRAM 100 and the peripheral circuit 200 having such configurations will next be described referring to FIGS. 8 to 92.

Incidentally, the manufacturing steps of the wiring layer LL1 of the MRAM 100 will be described referring to FIGS. 8 to 20 and then the manufacturing steps of from the wiring layer LL1 to the upper insulating layer TIL of the MRAM 100 and the peripheral circuit 200 will next be described referring to FIGS. 21 to 92.

FIG. 8 is a cross-sectional view showing a first manufacturing step of the wiring layer LL1 of the MRAM 100. As illustrated in FIG. 8, a semiconductor substrate SS having a main surface is prepared. Then, an element isolation region STI is formed on the main surface of the semiconductor substrate SS to form an active region on the main surface. After formation of the element isolation region STI, an impurity is introduced into the active region by ion implantation or the like to form a well region or a channel region which is not illustrated in this drawing. After formation of the well region or the channel region, the main surface of the semiconductor substrate SS is subjected to thermal oxidation treatment or the like to form a silicon oxide film on the main surface.

As illustrated in FIG. 9, a polysilicon film is then deposited on the silicon oxide film formed on the main surface of the semiconductor substrate SS by using CVD (chemical vapor deposition) or the like, followed by patterning of the polysilicon film. As a result, a gate insulating film GI remains on the main surface of the semiconductor substrate SS and at the same time, a gate electrode GE is formed on this gate insulating film GI.

As illustrated in FIG. 10, with the gate electrode GE as a mask, an impurity of a predetermined conductivity type is then introduced into the active region of the main surface of the semiconductor substrate SS. A silicon oxide film and a silicon nitride film are deposited successively to cover therewith the gate electrode GE by using CVD. The resulting silicon oxide film and silicon nitride film are anisotropically etched to form a sidewall SW on the side surface of the gate electrode GE.

After formation of the sidewall SW, with the gate electrode GE and the sidewall SW as a mask, an impurity is introduced into the active region. Due to twice introduction of the impurity, an impurity diffusion layer IR1 and an impurity diffusion layer IR2 are formed. Incidentally, after introduction of the impurity, the semiconductor substrate SS is subjected to heat treatment for diffusing the impurity.

As illustrated in FIG. 11, after formation of each impurity region, a cobalt silicide film is formed on the top surface of the gate electrode GE and on the impurity diffusion layer IR1 and the impurity diffusion layer IR2. In such a manner, a MOS transistor MT is formed on the main surface of the semiconductor substrate SS.

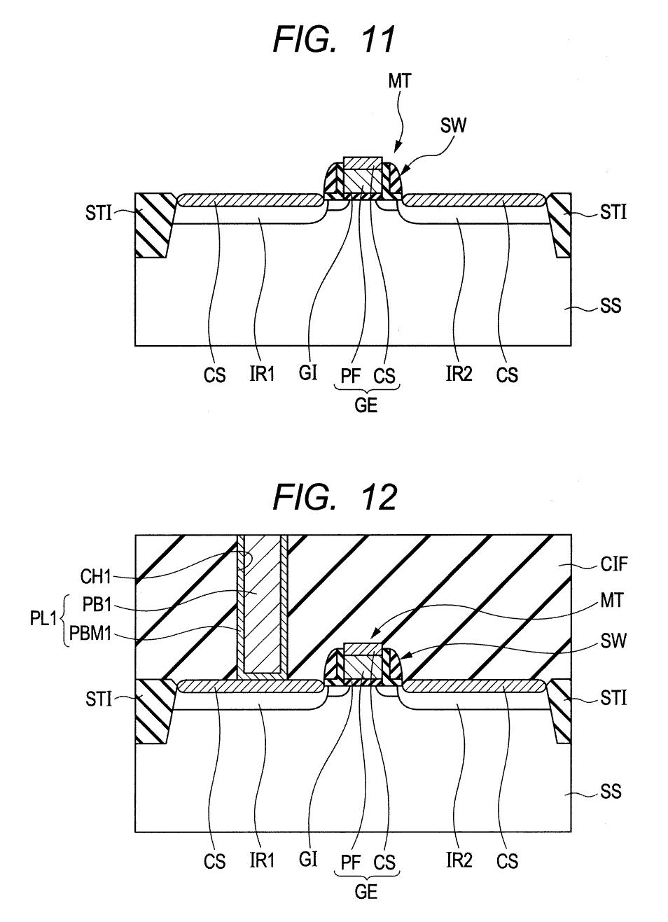

As illustrated in FIG. 12, after formation of the MOS transistor MT, a contact interlayer insulating film CIF is formed so as to cover therewith the MOS transistor MT.

The contact interlayer insulating film CIF is made of a film stack of an ozone TEOS film formed through thermal CVD with ozone and TEOS as raw materials and a plasma TEOS film formed through plasma CVD with TEOS as a raw material.

The contact interlayer insulating film CIF is subjected to photolithography and etching to form a contact hole CH1 in the contact interlayer insulating film CIF. After formation of the contact hole CH1, a barrier metal is formed on the inner peripheral surface of the contact hole CH1 and on the cobalt silicide film exposed from the contact hole CH1 by using sputtering or the like. As the barrier metal, a titanium/titanium nitride film or the like is employed. After formation of the barrier metal, tungsten is filled. After filling with a metal material such as tungsten, CMP (chemical mechanical polishing) is performed to remove the metal material such as tungsten and the barrier metal remaining on the contact interlayer insulating film CIF.

As a result, formation of a plug PL1 including a contact barrier metal PBM1 and a plug body portion PB1 is completed.

After formation of the plug PL1, the surface of the contact interlayer insulating film CIF is subjected to plasma treatment. More specifically, a chamber is supplied with an ammonia gas or an ammonia gas and a nitrogen gas and then, the semiconductor substrate SS is loaded in the chamber. Then, the gas in the chamber is converted into plasma by setting the temperature in the chamber at about 400° C. With the gas converted into plasma, the surface of the contact interlayer insulating film CIF is subjected to plasma treatment.

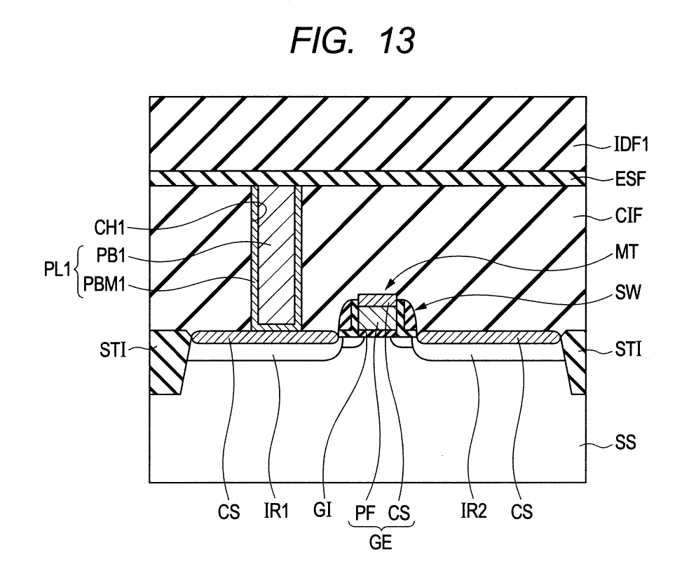

As illustrated in FIG. 13, an etching stopper film ESF is formed on the top surfaces of the contact interlayer insulating film CIF and the plug PL1 by using CVD or the like. As the etching stopper film ESF, a silicon carbonitride film (SiCN film) or a silicon carbide film (SiC film) is employed. Incidentally, the etching stopper film ESF is formed at a temperature of, for example, about 450° C.

Due to the plasma treatment of the top surface of the contact interlayer insulating film CIF, the adhesion between the etching stopper film ESF and the contact interlayer insulating film CIF is improved.

Then, an interlayer insulating film IDF1 is formed on the top surface of the etching stopper film ESF by using CVD or the like. As the interlayer insulating film IDF1, a silicon oxide film or a low dielectric constant film having a lower dielectric constant than a silicon oxide film is employed. For example, a TEOS film, a silicon oxide film, an SiOF film, or the like is employed.

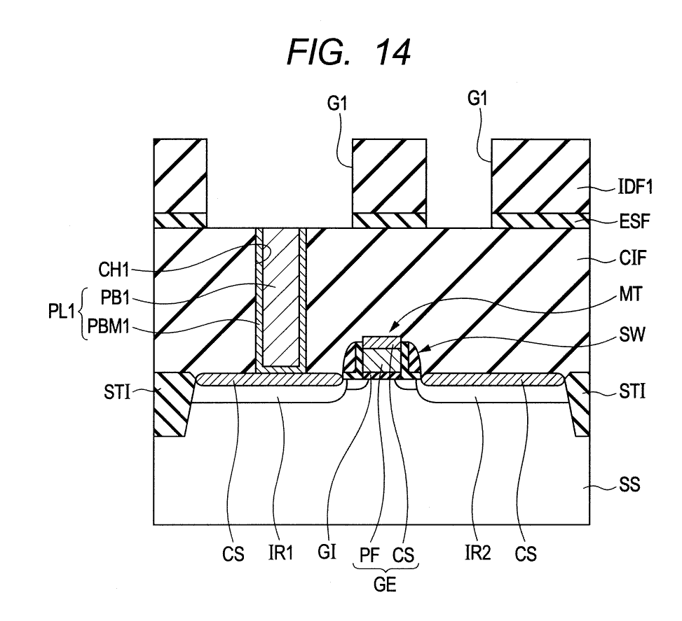

Then, as illustrated in FIG. 14, the interlayer insulating film IDF1 and the etching stopper film ESF are patterned through photolithography and etching to form a trench portion G1.

Then, as illustrated in FIG. 15, a barrier metal BM0 is formed on the inner peripheral surface of the trench portion G1 and on the upper end portion of the plug PL exposed from the trench portion G1 by using sputtering or the like. The barrier metal BM0 is formed of, for example, tantalum (Ta), titanium (Ti), ruthenium (Ru), tungsten (W), or manganese (Mn), a nitride or silicon nitride thereof, or a film stack thereof. In other words, the barrier metal BM0 is made of either one of a metal material film comprised of a metal material selected from tantalum, titanium, ruthenium, or manganese or a compound film of the metal material and any element selected from Si, N, O, and C. A conductive film CF0 made of copper or the like is deposited on the barrier metal BM0 by using electroplating or the like. The conductive film CF0 is filled in the trench portion G1.

The conductive film CF0 is made of, for example, copper (Cu) or a copper alloy (an alloy between copper (Cu) and aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), In (indium), a lanthanoid metal, or an actinoid metal).

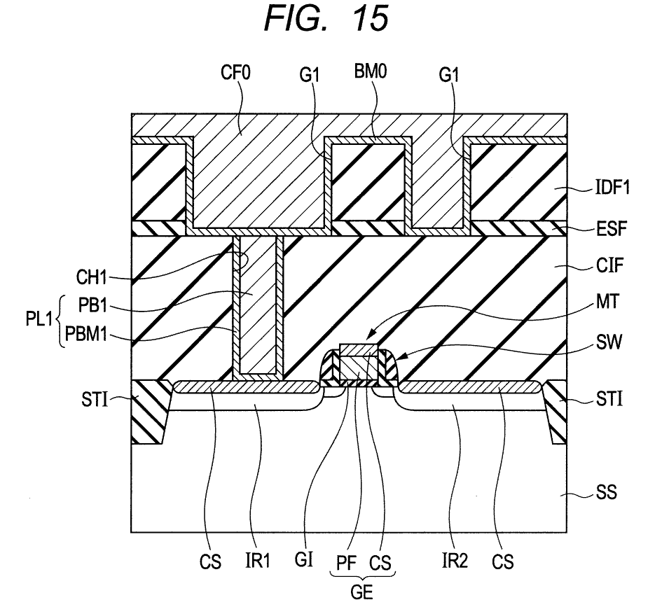

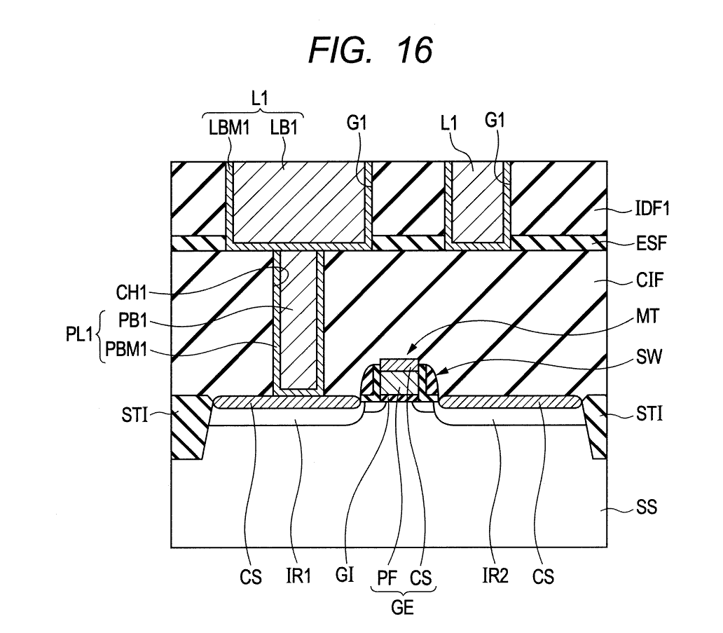

Then, as illustrated in FIG. 16, the conductive film CF0 and the barrier metal BM0 on the interlayer insulating film IDF1 are removed by using CMP or the like. As a result, the formation of the wiring L1 including the wiring body portion LB1 and the barrier metal LBM1 is completed.

The interlayer insulating film IDF1 having therein the wiring L1 is then subjected to plasma treatment similar to that given to the top surface of the contact interlayer insulating film CIF.

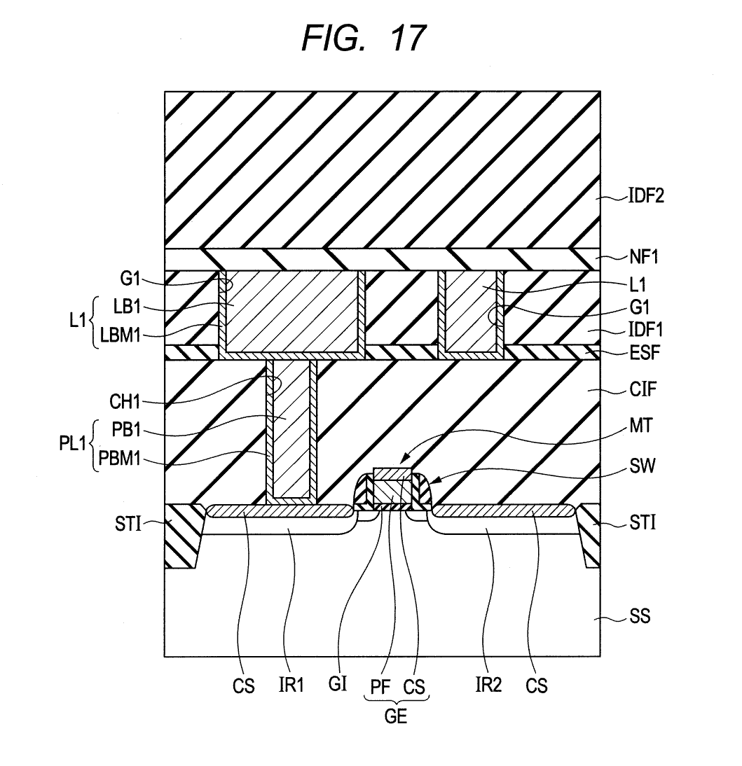

Then, as illustrated in FIG. 17, a diffusion preventive film NF1 is deposited on the top surfaces of the interlayer insulating film IDF1 and the wiring L1 by using CVD. As the diffusion preventive film NF1, a silicon carbonitride film (SiCN film) or a silicon carbide film (SiC film) is employed. Plasma treatment is given to the top surface of the interlayer insulating film IDF1 to improve the adhesion between each of the wiring L1 and the interlayer insulating film IDF1 and the diffusion preventive film NF1. Incidentally, the formation temperature of the diffusion preventive film NF1 is set at, for example, about 450° C. An interlayer insulating film IDF2 is then deposited on the top surface of the diffusion preventive film NF1 by using CVD or the like. The interlayer insulating film IDF2 is made of, for example, a TEOS film, a silicon oxide film, an SiOC film, an HSQ film, an MSQ film, or an SiOF film.

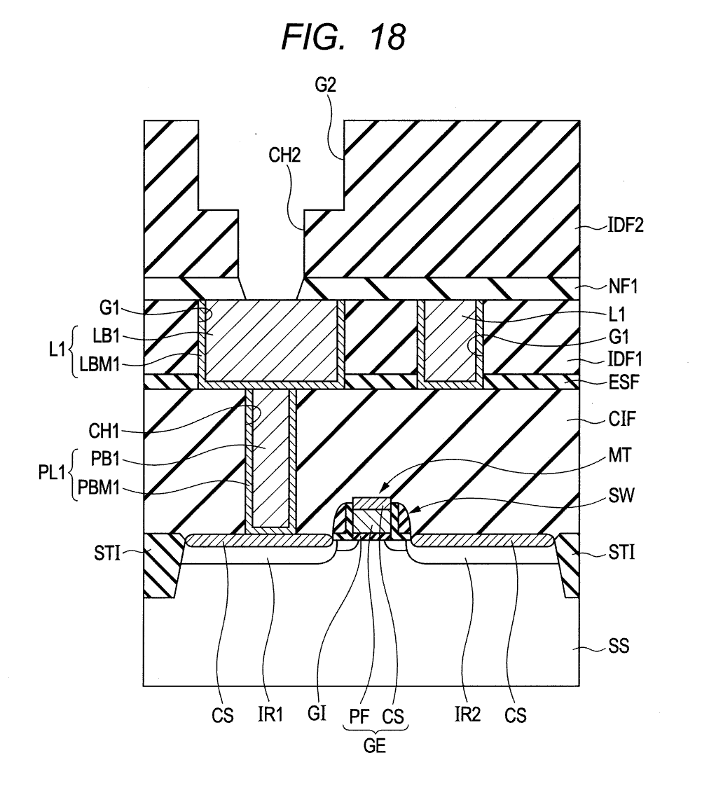

Then, as illustrated in FIG. 18, the interlayer insulating film IDF2 and the diffusion preventive film NF1 are patterned through photolithography and etching to form a contact hole CH2 and a trench portion G2. Incidentally, a portion of the top surface of the wiring L1 is exposed from the contact hole CH2.

Then, as illustrated in FIG. 19, a barrier metal BM1 is formed by sputtering on the surfaces of the contact hole CH2 and the trench portion G2. A conductive film CF1 is then formed by electroplating or the like and the conductive film CF1 is filled in the contact hole CH2 and the trench portion G2.

Incidentally, as the barrier metal BM1, a proper metal material is selected from the metal materials that can be employed for the barrier metal BM0 illustrated in FIG. 15. As the conductive film CF1, a proper metal material is also selected from the metal materials that can be employed for the conductive film CF0 illustrated in FIG. 15.

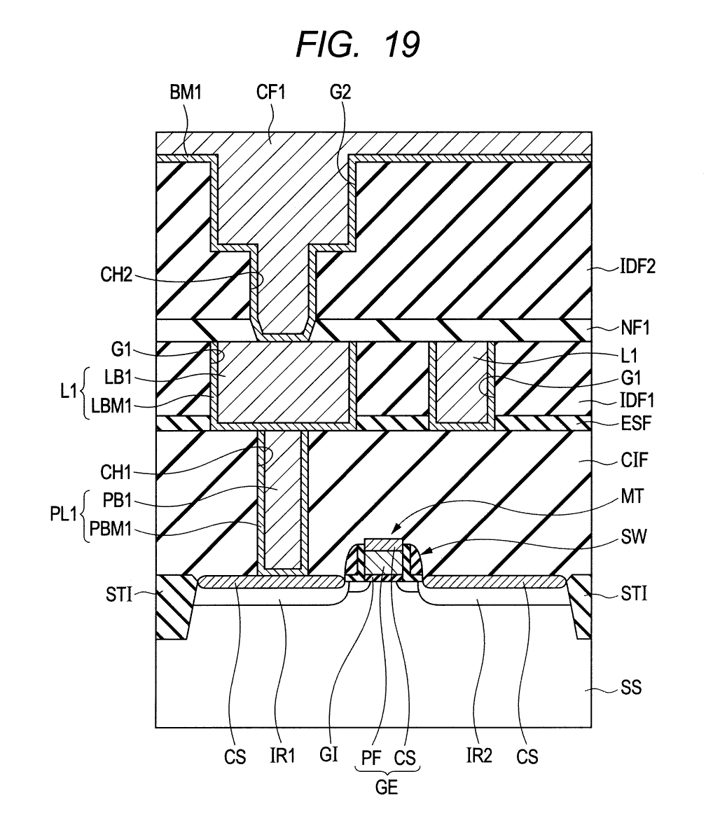

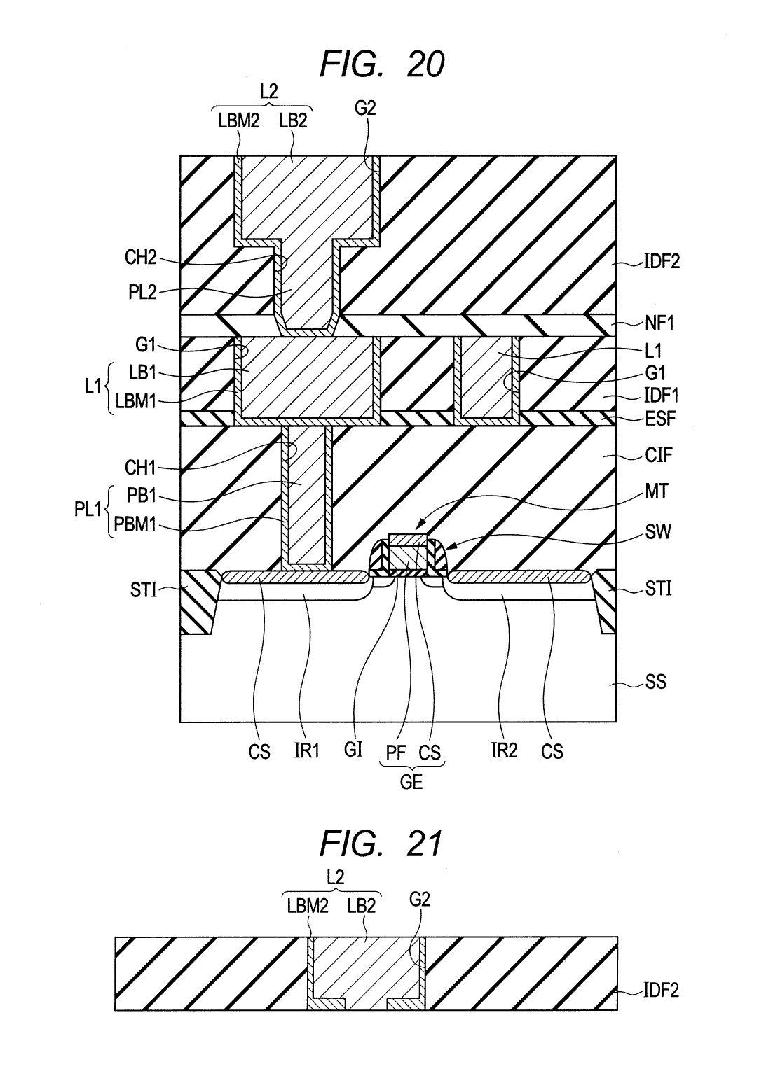

As illustrated in FIG. 20, the conductive film CF1 and the barrier metal BM1 on the interlayer insulating film IDF2 are removed using CMP, resulting in the formation of a wiring L2 including a barrier metal LBM2 formed on the inner surfaces of the contact hole CH2 and the trench portion G2 and a wiring body portion LB2 filled in the contact hole CH2 and the trench portion G2.

After formation of the wiring L2 in such a manner, the interlayer insulating film IDF2 is subjected to plasma treatment similar to that given to the interlayer insulating film IDF1 and the contact interlayer insulating film CIF.

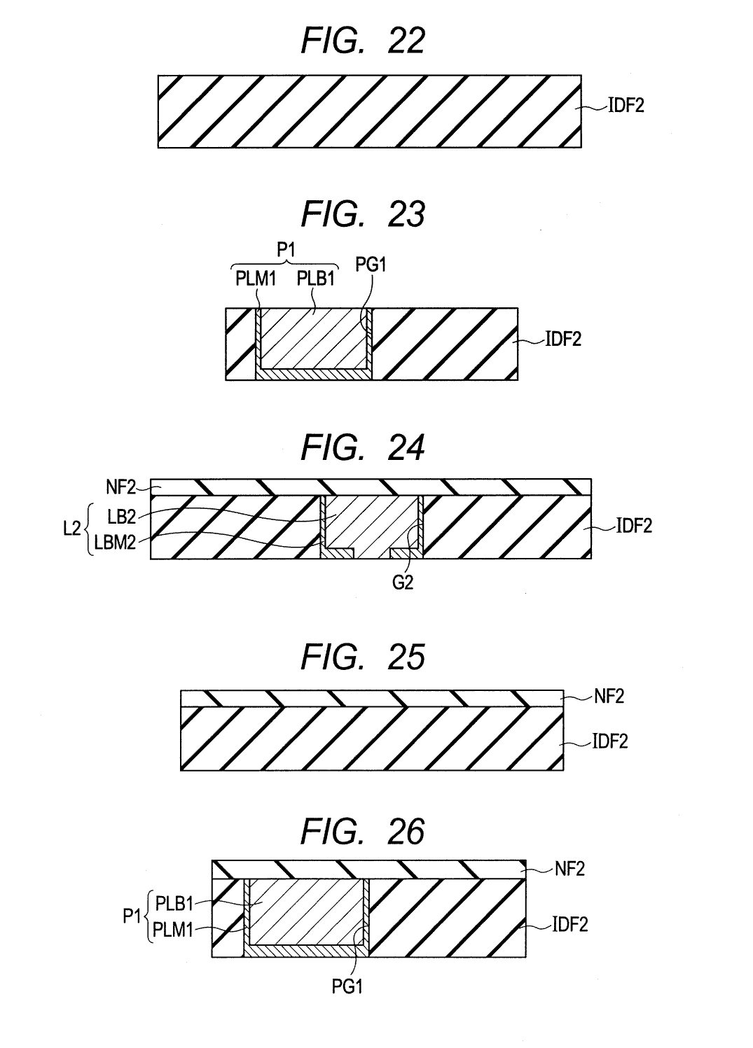

As described above, formation of the wiring layer LL1 of the MRAM 100 is completed. FIG. 21 is a cross-sectional view illustrating a portion of the MRAM 100 when the wiring L2 is formed and it is a cross-sectional view corresponding to the cross-section of FIG. 5. FIG. 22 is a cross-sectional view of the MRAM 100 when the wiring L2 is formed and it is a cross-section corresponding to the cross-section of FIG. 6. FIG. 23 is a cross-sectional view of the peripheral circuit 200 when the wiring L2 is formed and it is a cross-sectional view corresponding to the cross-section of FIG. 7.

FIGS. 24 to 26 are cross-sectional views illustrating the step after the manufacturing step illustrated in FIGS. 21 to 23.

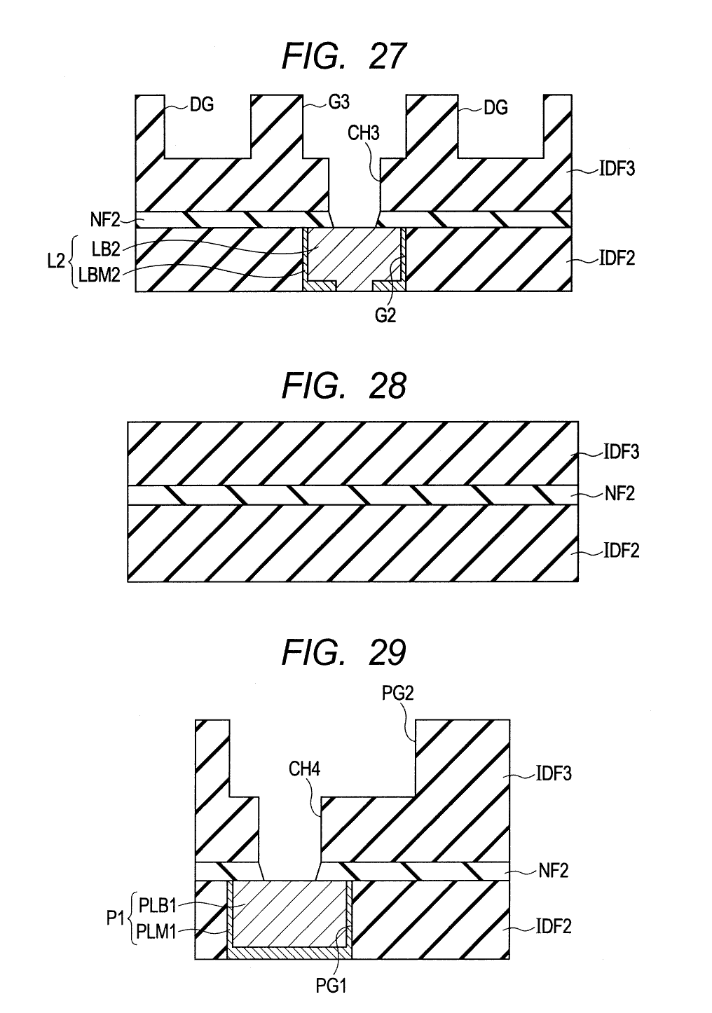

As illustrated in FIGS. 24 and 26, a diffusion preventive film NF2 made of a silicon carbonitride film (SiCN film) or a silicon carbide film (SiC film) is deposited on the top surface of the interlayer insulating film IDF2 by using CVD or the like. The film formation temperature of the diffusion preventive film NF2 is set at, for example, about 450° C. As illustrated in FIGS. 27 to 29, an interlayer insulating film IDF3 is then deposited by CVD or the like. Then, photolithography and etching are used to form a trench portion DG, a trench portion G3, a contact hole CH3, a contact hole CH4, and a trench portion PG2 in the interlayer insulating film IDF3.

Incidentally, as illustrated in FIG. 27, the trench portion DG, the contact hole CH3, and the trench portion G3 are formed in a portion of the interlayer insulating film IDF3 which will be the MRAM 100 and as illustrated in FIG. 29, the contact hole CH4 and the trench portion PG2 are formed in a portion of it which will be the peripheral circuit 200.

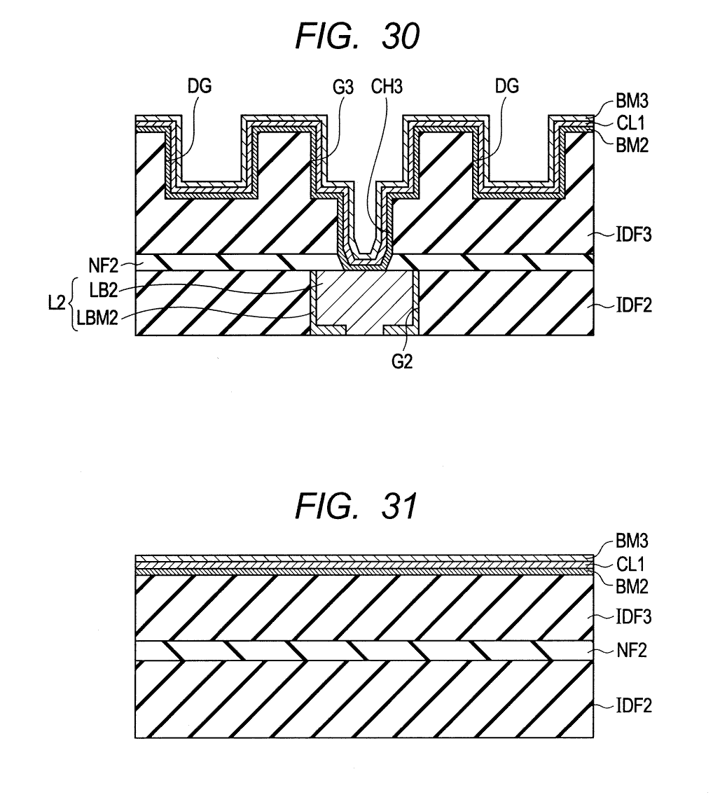

As illustrated in FIGS. 30 to 32, a barrier metal BM2, a clad layer CL1, and a barrier metal BM3 are stacked one after another.

The barrier metal BM2 and the barrier metal BM3 are each made of a metal material containing at least one element selected from tantalum (Ta), titanium (Ti), ruthenium (Ru), manganese (Mn), magnesium (Mg), and tungsten (W). More specifically, titanium or titanium nitride is employed.

The clad layer CL1 is made of a high magnetic permeability material and a metal material containing at least one element selected from cobalt (Co), nickel (Ni), and iron (Fe) is selected. More specifically, it is preferred to use, for the clad layer CL1, an alloy such as NiFe (nickel iron), NiFeMo, CoNbZr (cobalt niobium zirconium), CoFeNb, CoFeSiB, CoNbRu, CoNbZrMoCr, or CoZrCrMo, or an amorphous alloy.

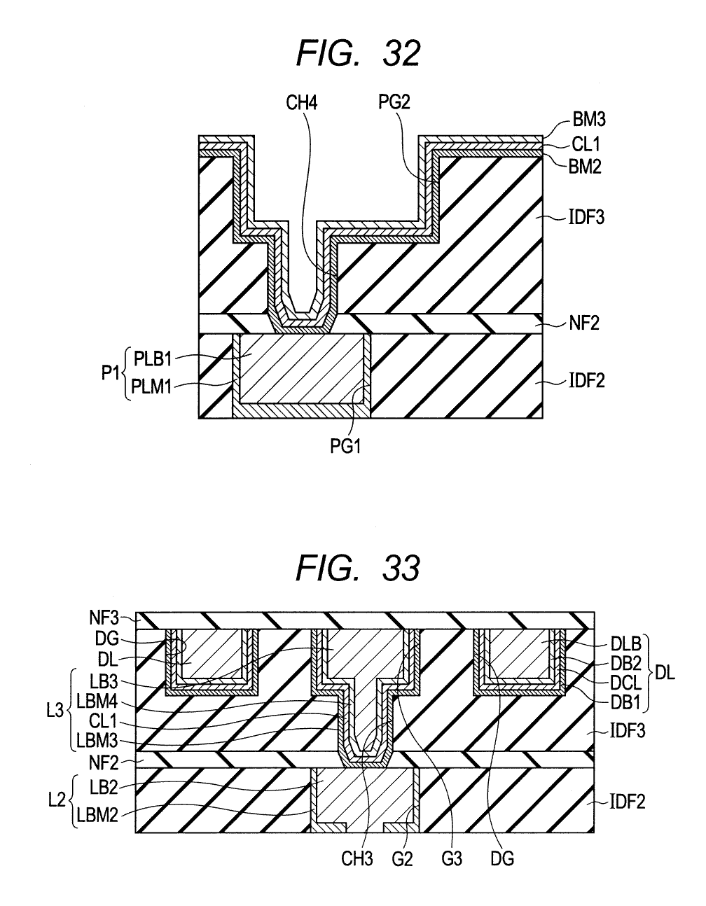

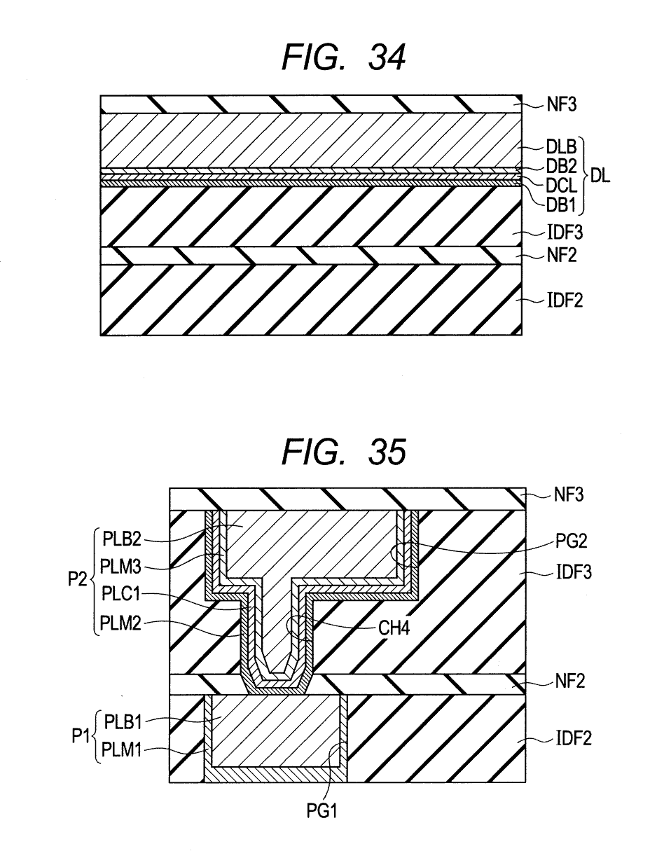

As illustrated in FIGS. 33 to 35, a metal material is applied by using sputtering or electroplating. The metal material is made of copper (embracing a metal material composed mainly of copper). More specifically, copper (Cu) or a copper alloy (an alloy between copper (Cu) and aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), In (indium), a lanthanoid metal, or an actinoid metal) is employed.

CMP or the like is then performed to remove the metal material, the barrier metal BM2, the clad layer CL1, and the barrier metal BM3 on the interlayer insulating film IDF3. As a result, the formation of a digit line DL, a wiring L3, and a peripheral circuit PL is completed.

The interlayer insulating film IDF3 having therein the digit line DL, the wiring L3, and the peripheral circuit P2 is then subjected to plasma treatment.

First the semiconductor substrate SS is loaded in a chamber and then, a mixed gas comprised of a nitrogen-containing molecule and a nitrogen-free inert molecule is introduced into the chamber. This plasma treatment is performed by introducing the mixed gas while setting the flow rate of the nitrogen-free inert molecule greater than that of the nitrogen-containing molecule and converting the mixed gas into plasma.

Then, an LT (low temperature)-SiN film is deposited on the top surface of the interlayer insulating film IDF3 by using CVD. The film formation temperature is set at, for example, 275° C. or less. Film formation at such a reduced temperature makes it possible to suppress formation of hillocks in the digit line DL, the wiring L3, and the peripheral wiring P2. In addition, the plasma treatment given to the interlayer insulating film IDF3 improves adhesion between the diffusion preventive film NF3 and the interlayer insulating film IDF3.

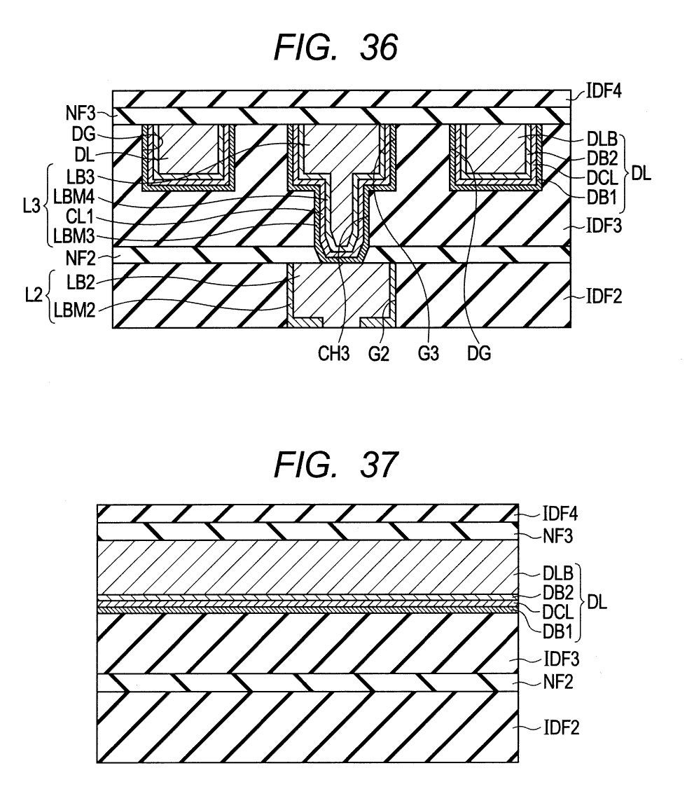

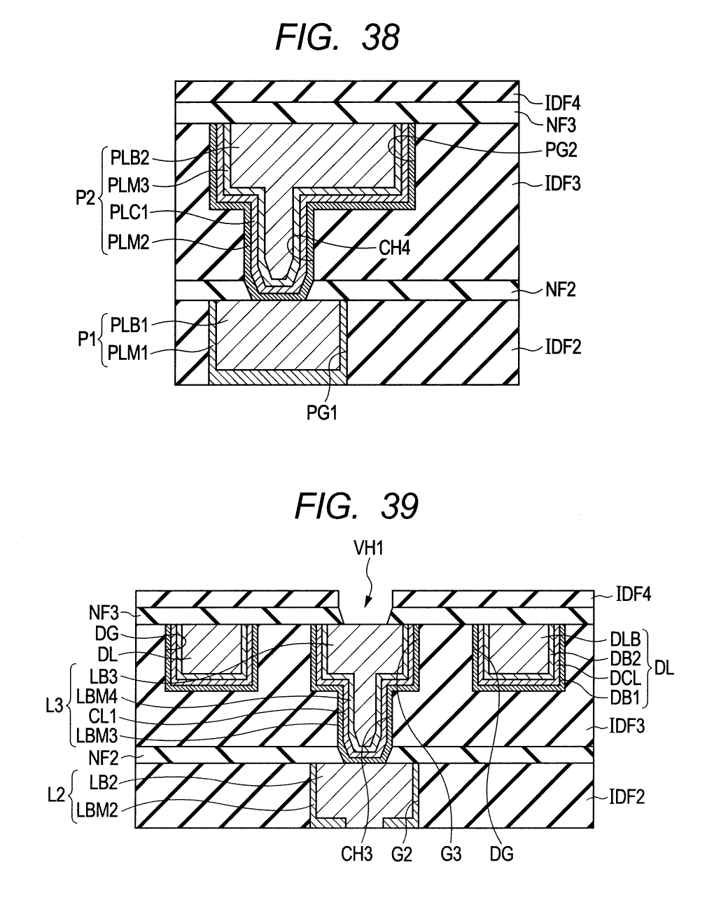

As illustrated in FIGS. 36 to 38, a TEOS oxide film or the like is then deposited on the top surface of the diffusion preventive film NF3 to obtain an interlayer insulating film IDF4.

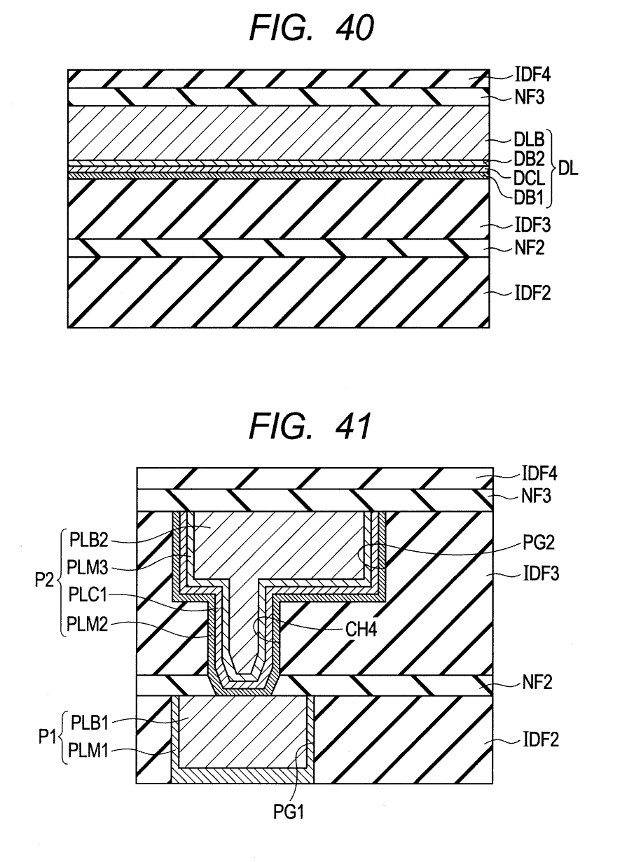

As illustrated in FIGS. 39 to 41, photolithography and etching are then performed to form a via hole VH1 in the interlayer insulating film IDF4 and the diffusion preventive film NF3. From this via hole, the top surface of the wiring L3 is exposed.

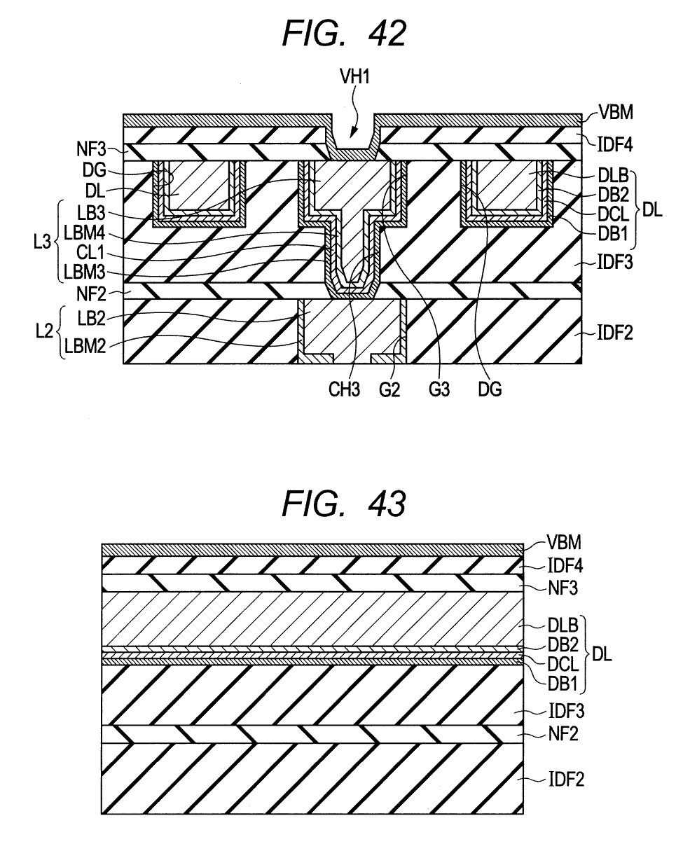

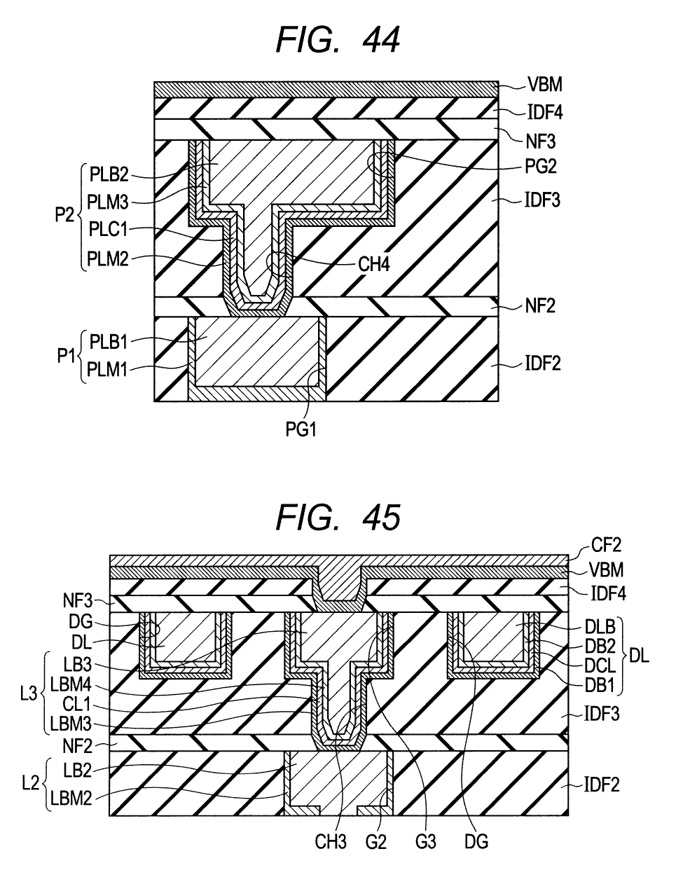

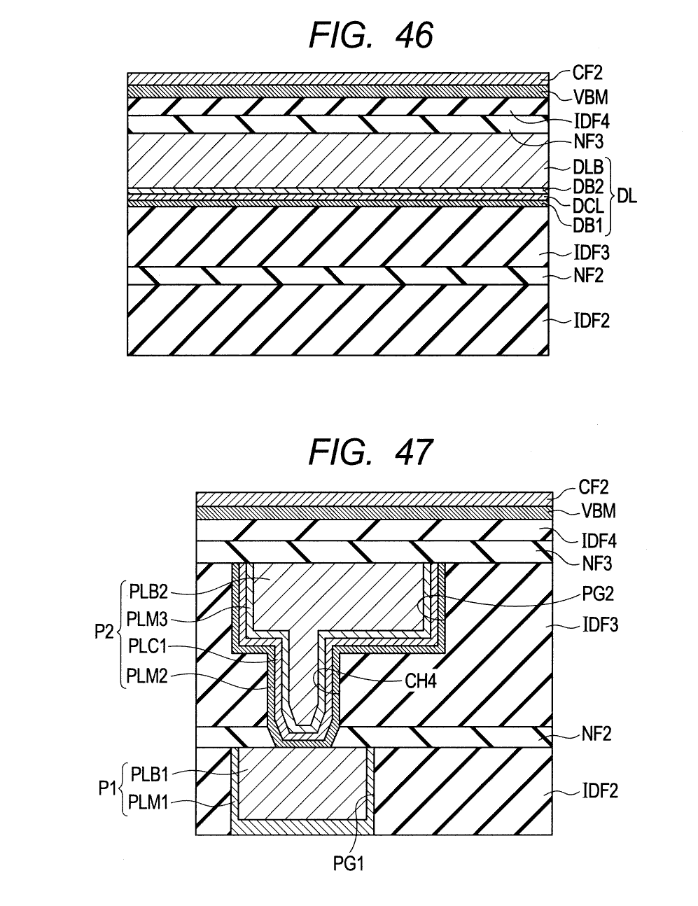

As illustrated in FIGS. 42 to 44, a barrier metal VBM is then formed by depositing, for example, a titanium/titanium nitride film on the top surface of the interlayer insulating film IDF4. Incidentally, as the barrier metal VBM, another material other than the titanium/titanium nitride film and containing at least one element selected from tantalum (Ta), titanium (Ti), ruthenium (Ru), manganese (Mn), magnesium (Mg), and tungsten (W) may be used. As illustrated in FIGS. 45 to 47, a conductive film CF2 is formed by depositing a metal material such as tungsten or copper on the barrier metal VBM.

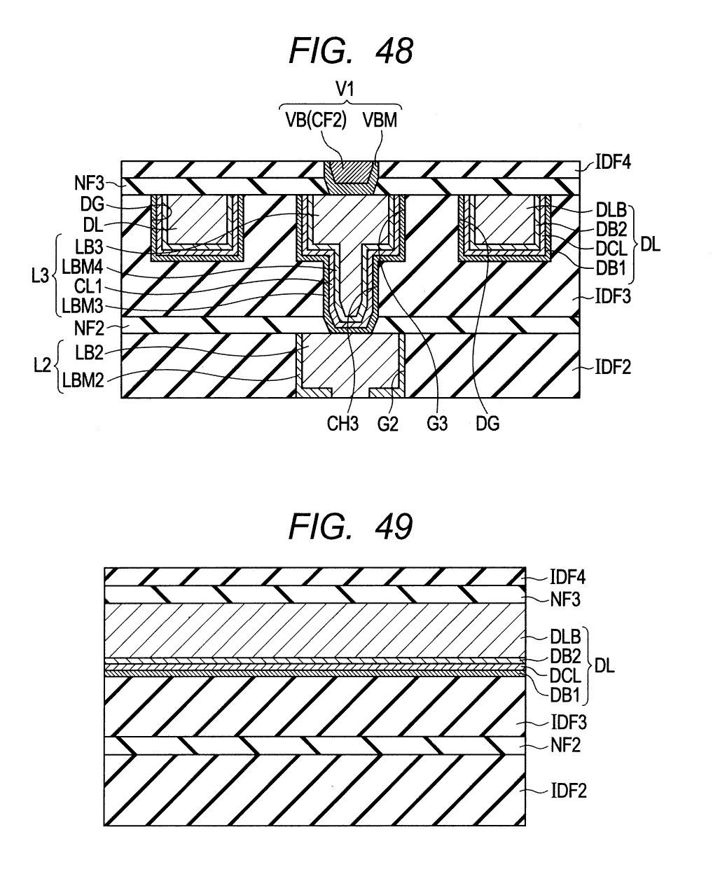

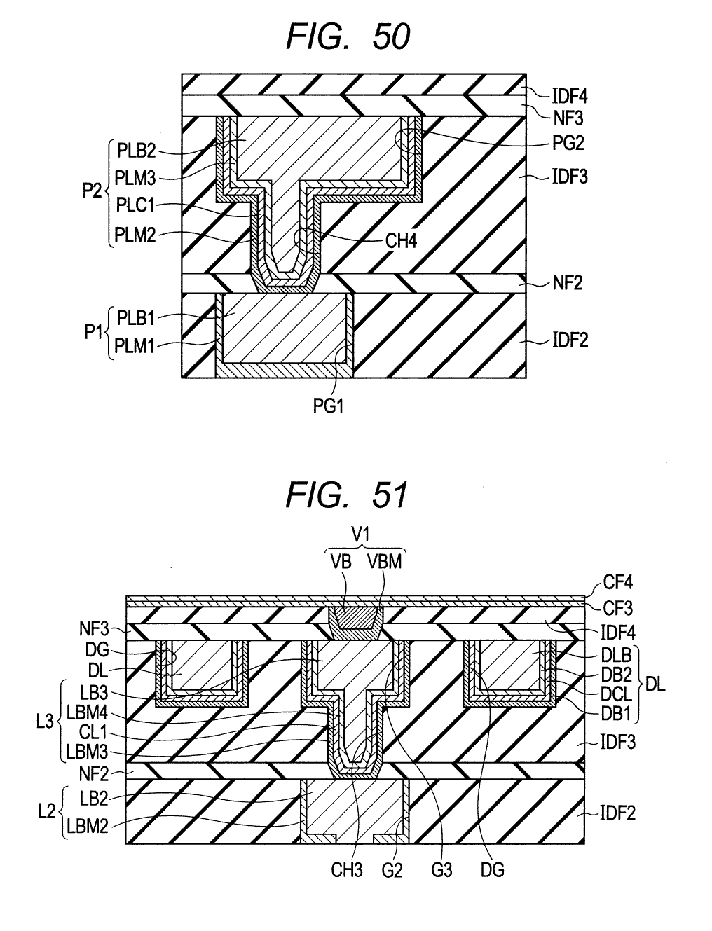

As illustrated in FIGS. 48 to 50, the barrier metal VBM and the conductive film CF2 are then subjected to CMP to planarize the barrier metal VBM and the conductive film CF2. As a result, the formation of a via plug V1 is completed.

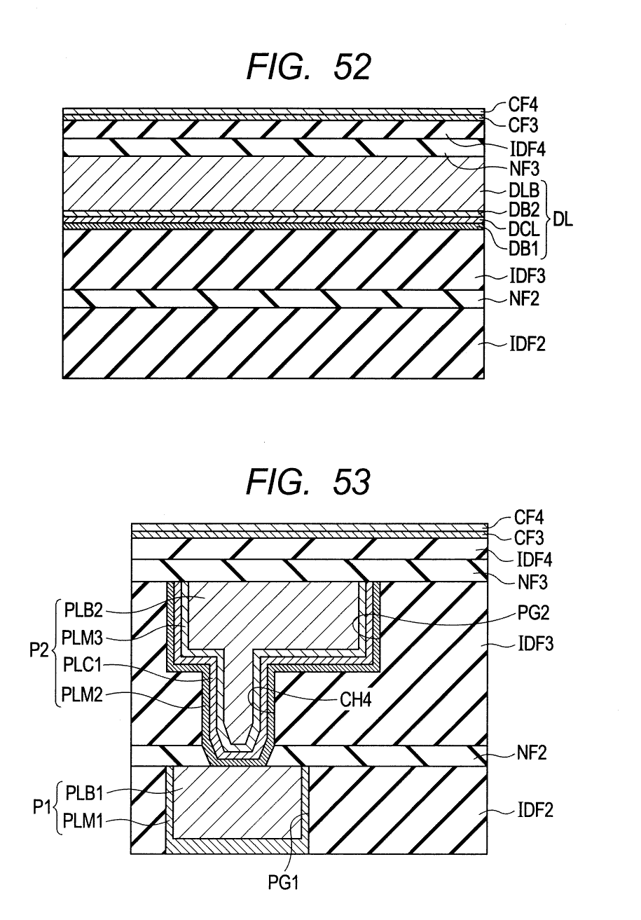

As illustrated in FIGS. 51 to 53, a conductive film CF3 is then formed on the upper end portion of the via plug V1 by using sputtering or the like. The conductive film CF3 is made of, for example, titanium (Ti). A conductive film CF4 is formed on the top surface of the conductive film CF3. The conductive film CF4 is formed of titanium nitride (TiN). In such a manner, a film stack structure obtained by stacking a titanium nitride (TiN) film on a titanium film is formed on the interlayer insulating film IDF4 and the via plug V1. Both the conductive film CF3 and the conductive film CF4 may be made of titanium nitride (TiN). When the conductive film CF3 formed of titanium is formed after removal of all of the via body VB and the barrier metal VBM provided on the interlayer insulating film IDF4, the conductive film CF3 and the conductive film CF4 formed on the conductive film CF3 can have improved film quality and uniformity.

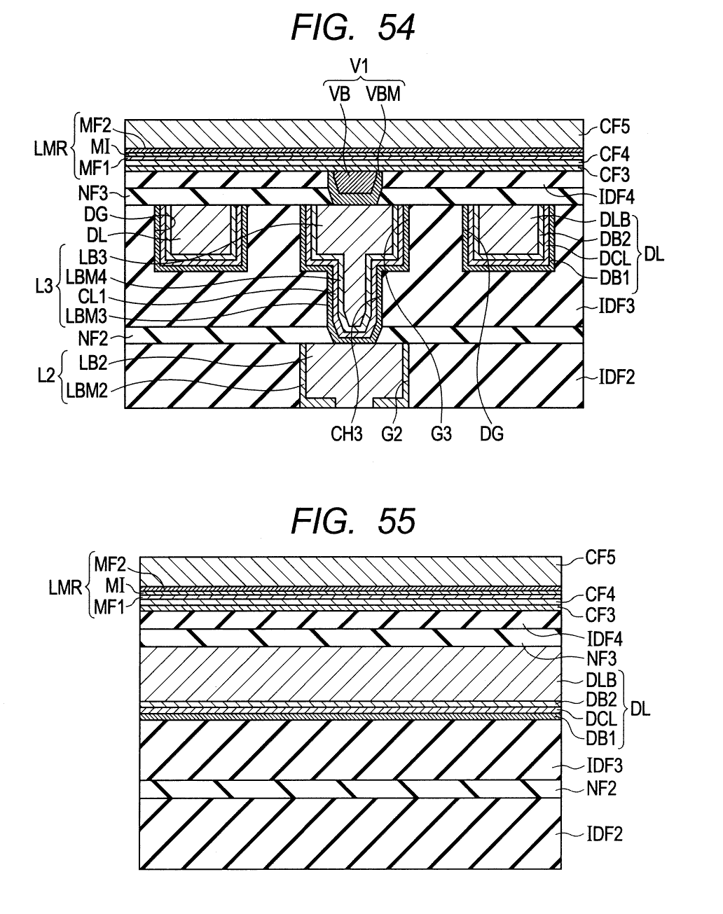

As illustrated in FIGS. 54 to 56, a fixed magnetization layer MF1, a tunnel insulating film MI, and a free magnetization layer MF2 are then stacked successively on the top surface of the conductive film CF4, by which a film stack LMR is formed on the top surface of the conductive film CF4. Then, a conductive film CF5 is formed on the top surface of the free magnetization layer MF2 of the film stack LMR. As the conductive film CF5, for example, a tantalum film or a ruthenium film is employed.

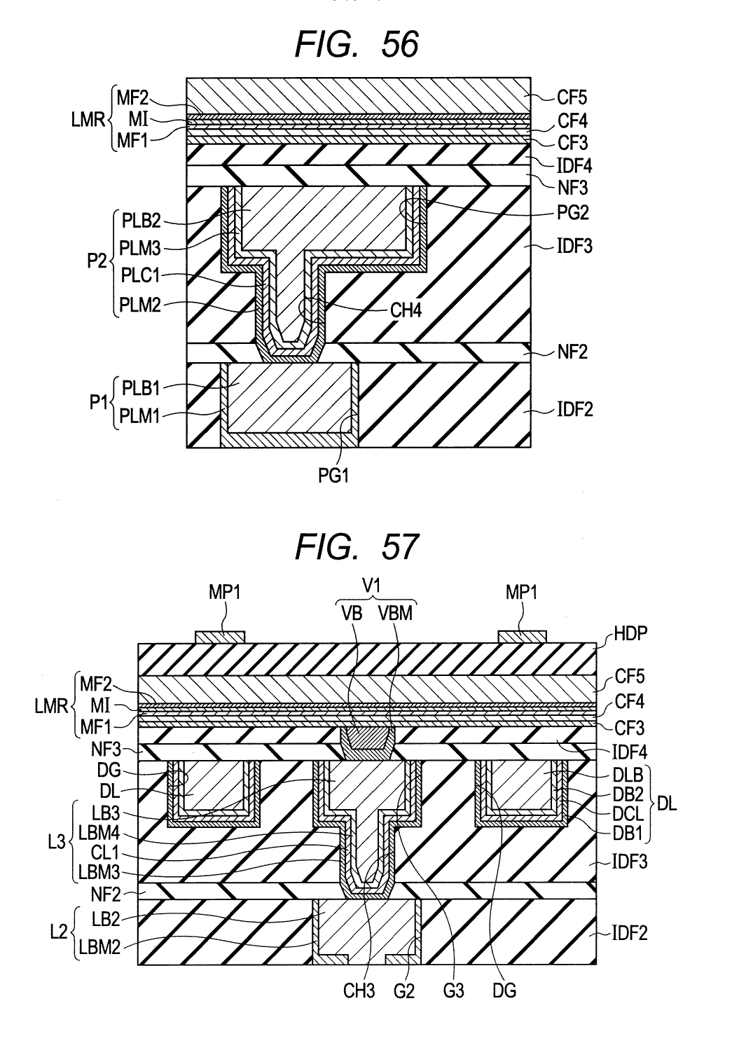

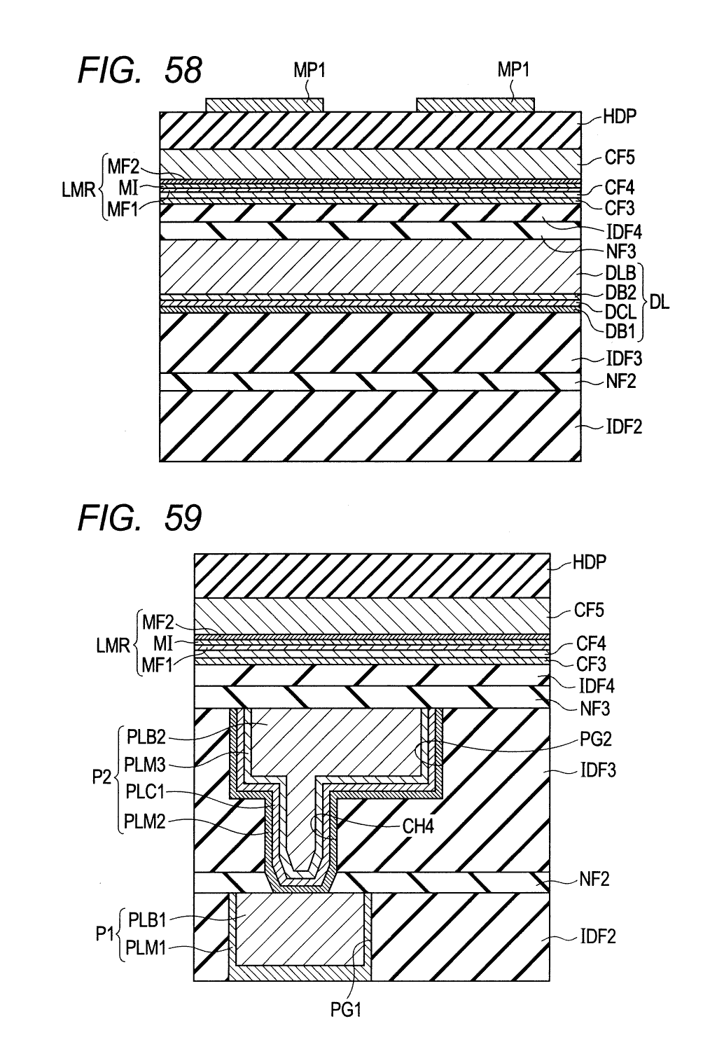

As illustrated in FIGS. 57 to 59, a silicon oxide film HDP is then deposited on the top surface of the conductive film CF5 by using CVD or the like. Then, a mask pattern MP1 is formed on the top surface of the silicon oxide film HDP.

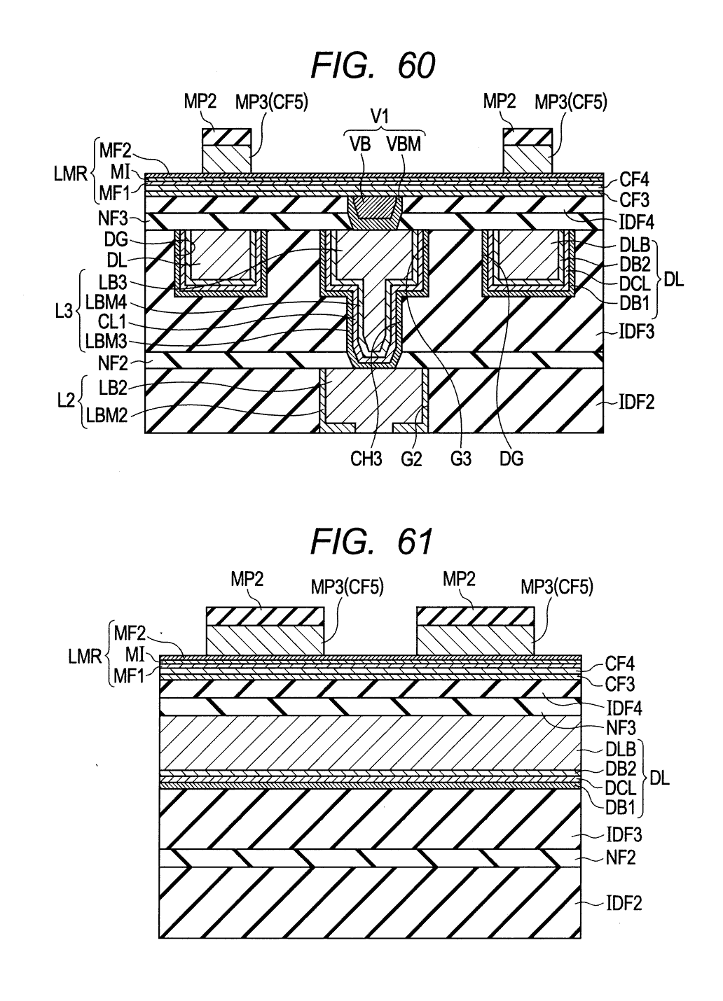

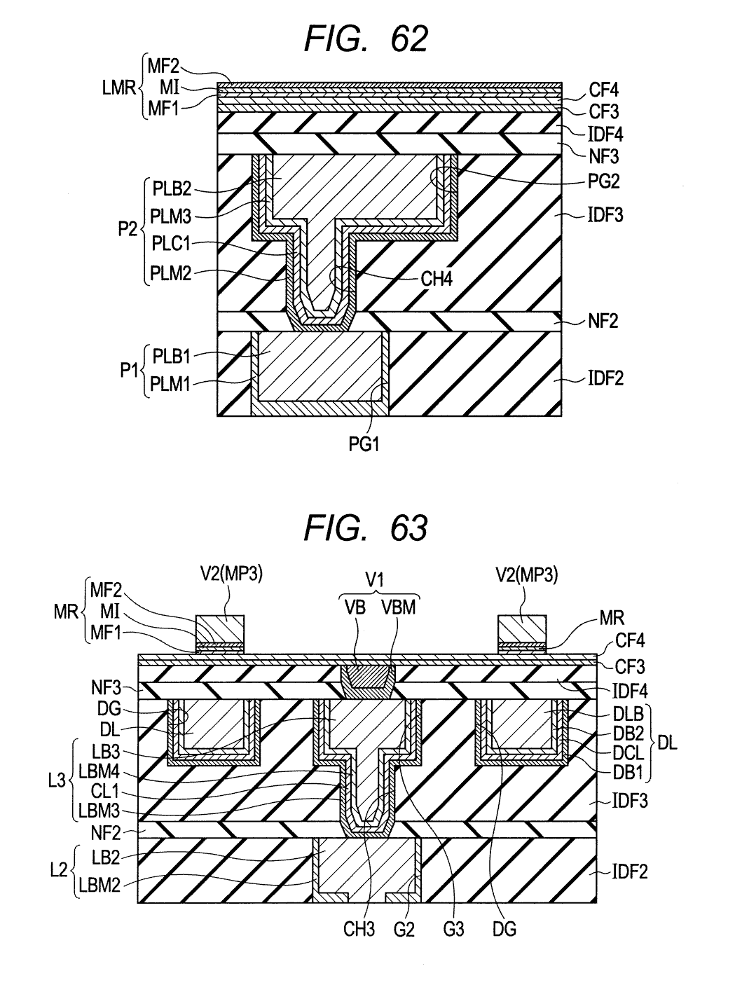

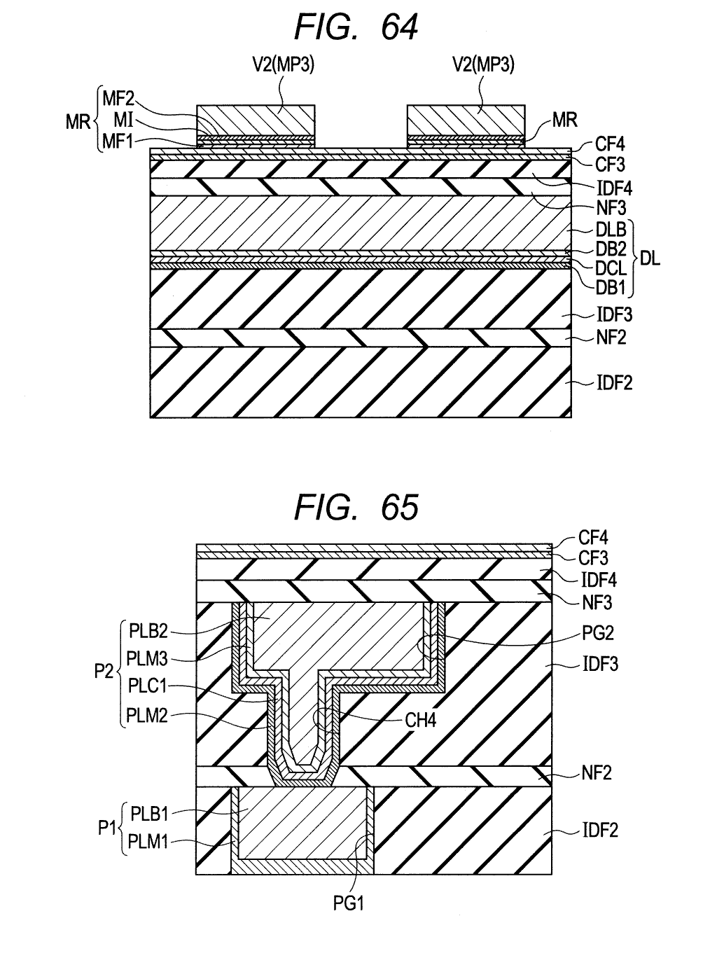

As illustrated in FIGS. 60 to 62, mask patterns MP2 and MP3 are then formed by etching the silicon oxide film HDP and the conductive film CF5. Plasma dry etching of the film stack LMR is then performed with the mask patterns MP2 and MP3. As illustrated in FIGS. 63 to 65, as a result, in a formation region of the MRAM 100 on the top surface of the conductive film CF4, a magnetic storage element MR is formed and at the same time, a via plug V2 is formed on the top surface of the magnetic storage element MR. As illustrated in FIG. 65, the film stack LMR and the mask pattern MP3 are removed completely from a region which will be a peripheral circuit 200. Ashing is then performed to remove the mask pattern MP2 remaining on the top surface of the via plug V2.

When plasma dry etching is performed, the semiconductor substrate SS is loaded in a chamber, in which the semiconductor substrate SS is exposed to a high temperature atmosphere. The conductive film CF4 is therefore exposed to a gas atmosphere of from about 100 to 300° C. Similarly, the conductive film CF4 is exposed to ashing plasma in the above ashing step.

The film stack structure of the conductive film CF3 and the conductive film CF4 is a two-layer structure in which titanium nitride (TiN) has been stacked on titanium nitride (TiN) or titanium (Ti). Since titanium nitride (TiN) is more resistant to oxidation and nitriding than tantalum (Ta) or tantalum nitride (TaN), the conductive film CF4 is prevented from expanding in the above etching step and ashing step.

Further, in the conductive film CF4 and the conductive film CF3 rightly below the conductive film CF4, titanium nitride (TiN) of the upper layer (conductive film CF4) is more resistant to oxidation and nitriding than titanium (Ti) of the lower layer (conductive film CF3) so that oxidation and nitriding of the lower layer (Ti) are prevented by covering the lower layer (Ti) with the upper layer (TiN). Incidentally, titanium (Ti) is a material which is more susceptible to oxidation and nitriding than tantalum (Ta) or tantalum nitride (TaN).

This structure makes it possible to prevent the conductive film CF4 and the conductive film CF3 from expanding in the above etching step and ashing step.

After completion of the etching step and the ashing step, the semiconductor substrate SS is discharged from the chamber and loaded in a next processing apparatus. In this transport procedure, the semiconductor substrate SS is cooled. As described above, expansion of the conductive film CF4 and the conductive film CF3 is suppressed so that even when the conductive film CF4 and the conductive film CF3 are cooled during the transport procedure, remaining of an internal stress in the conductive film CF4 and the conductive film CF3 can be prevented.

As a result, warp of the semiconductor substrate SS can be suppressed and peeling between the diffusion preventive film NF3 and the top surfaces of the wiring L3, the digit line DL, and the peripheral wiring P2 can be prevented.

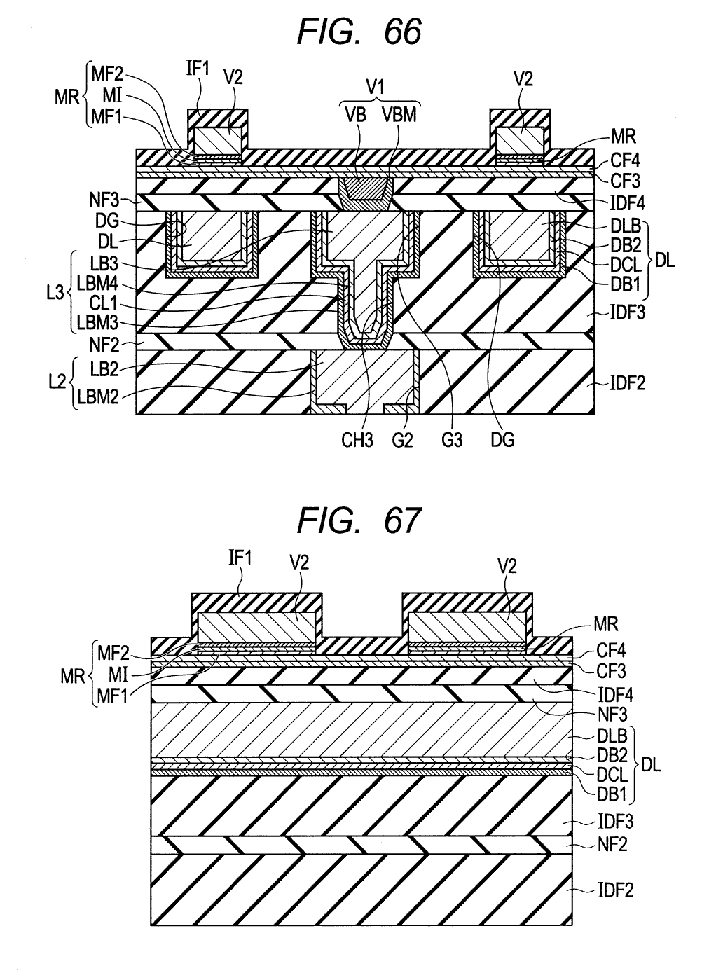

As illustrated in FIGS. 66 to FIG. 68, an insulating film IF1 made of LT (low temperature)-SiN is deposited using, for example, CVD.

The film formation temperature of the insulating film IF1 is set at 275° C. or less so that the film can be formed at a temperature not influencing on the magnetic properties of the magnetic storage element MR.

Further, formation of the insulating film IF1 at a low temperature makes it possible to inhibit formation of hillocks on the top surface of the digit line DL.

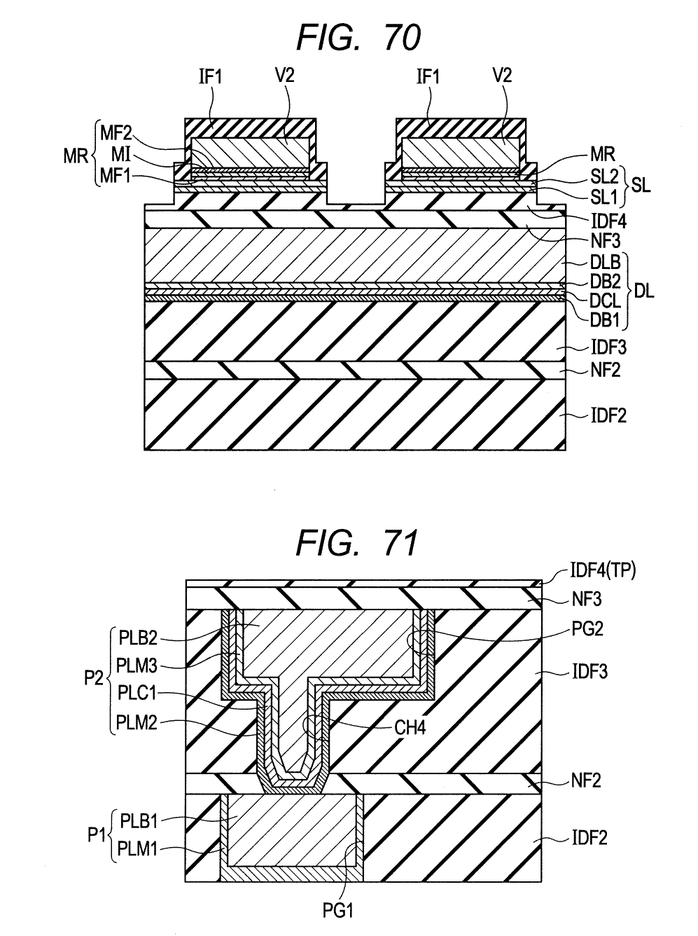

As illustrated in FIGS. 69 to 71, the insulating film IF1 is patterned. With the patterned insulating film IF1 as a mask, the conductive film CF4 is etched. As a result, a strap line SL is formed.

At this time, also the interlayer insulating film IDF4 is etched into a thick film portion SP and a thin film portion TP. The via plug V1 is formed in the thick film portion SP and the strap line SL is formed on the top surface of the thick film portion SP. A magnetic storage element MR is formed on the top surface of the strap line SL.

The thin film portion TP is formed in respective regions of the top surface of the diffusion preventive film NF3 which is located between the thick film portions SP and which will be a peripheral circuit 200.

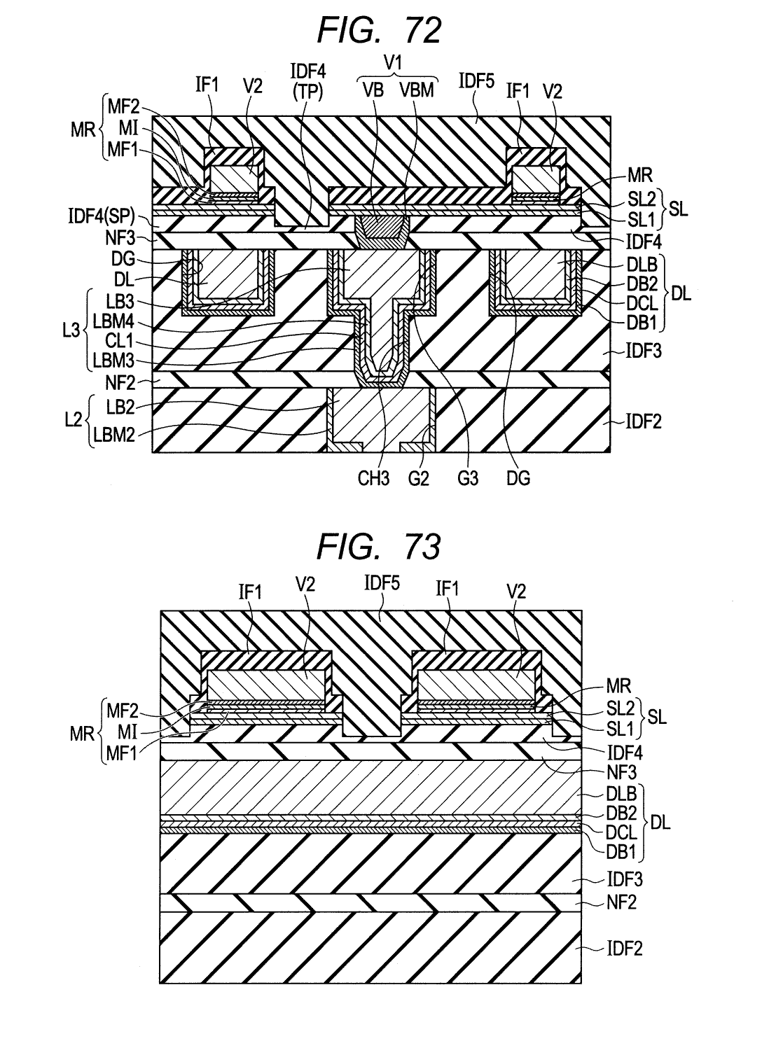

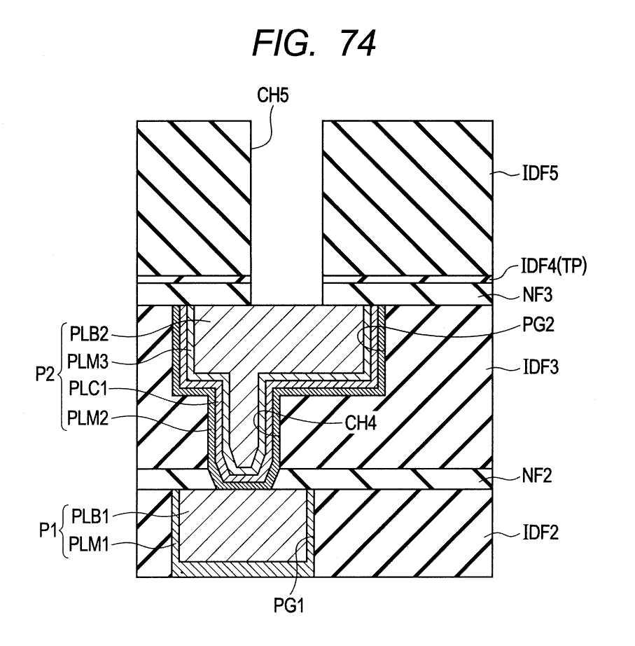

As illustrated in FIGS. 72 to 74, an interlayer insulating film IDF5 made of a silicon oxide film or the like is deposited using, for example, CVD to cover therewith the insulating film IF1. The interlayer insulating film IDF5 is then patterned to form therein a contact hole CH5. By this patterning, the top surface of the diffusion preventive film NF3 is exposed from the bottom surface of the contact hole CH5.

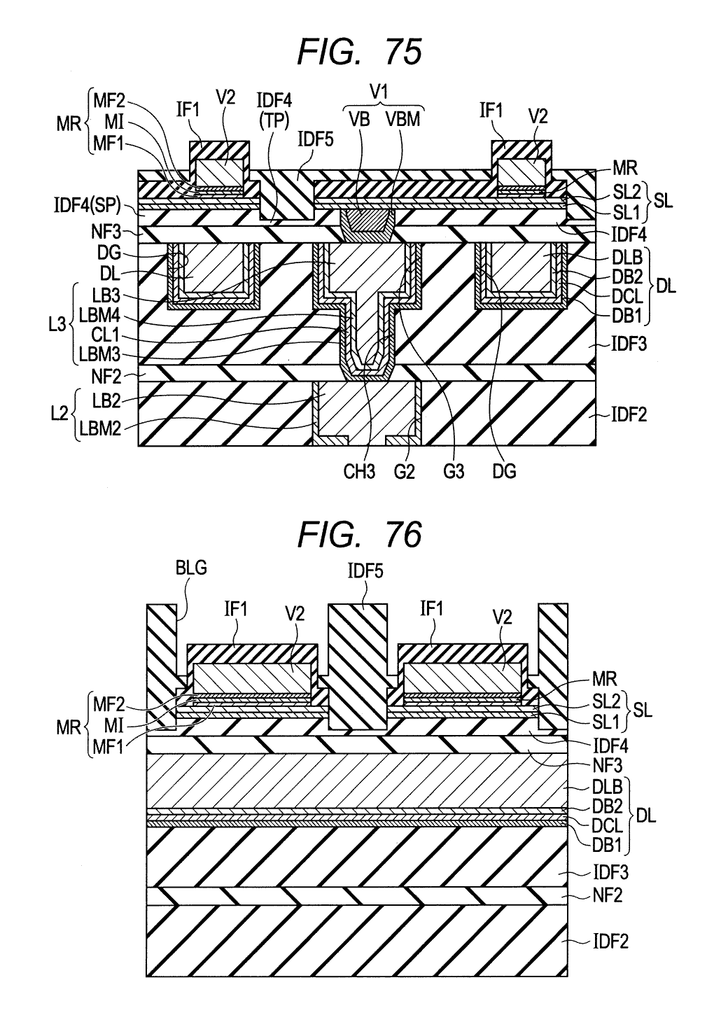

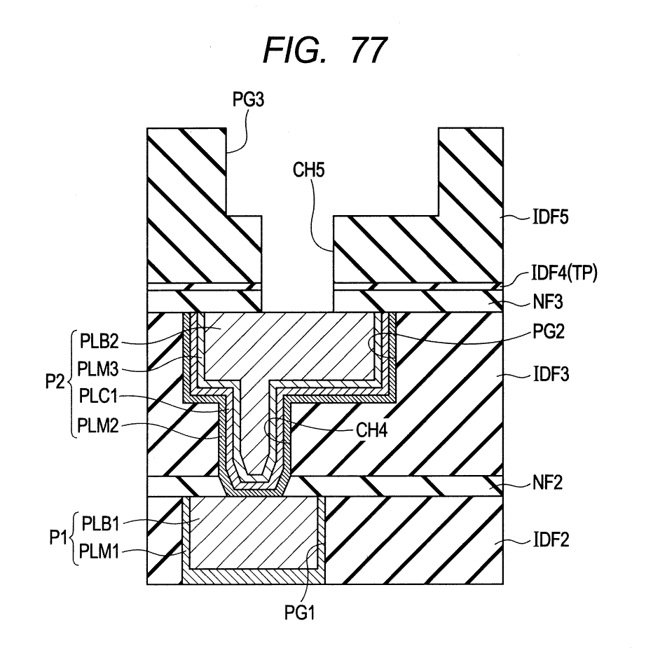

As illustrated in FIGS. 75 to 77, the interlayer insulating film IDF5 is patterned to form a trench portion BLG and a trench portion PG3. By this patterning, the insulating film IF1 is exposed in the trench portion BLG.

The insulating film IF1 exposed in the trench portion BLG and the diffusion preventive film NF3 exposed from the contact hole CH5 are etched. Since the insulating film IF1 and the contact hole CH5 are each made of a silicon nitride (SiN) film, the insulating film IF1 in the trench portion BLG and the diffusion preventive film NF3 located at the bottom of the contact hole CH5 can be removed in the same step.

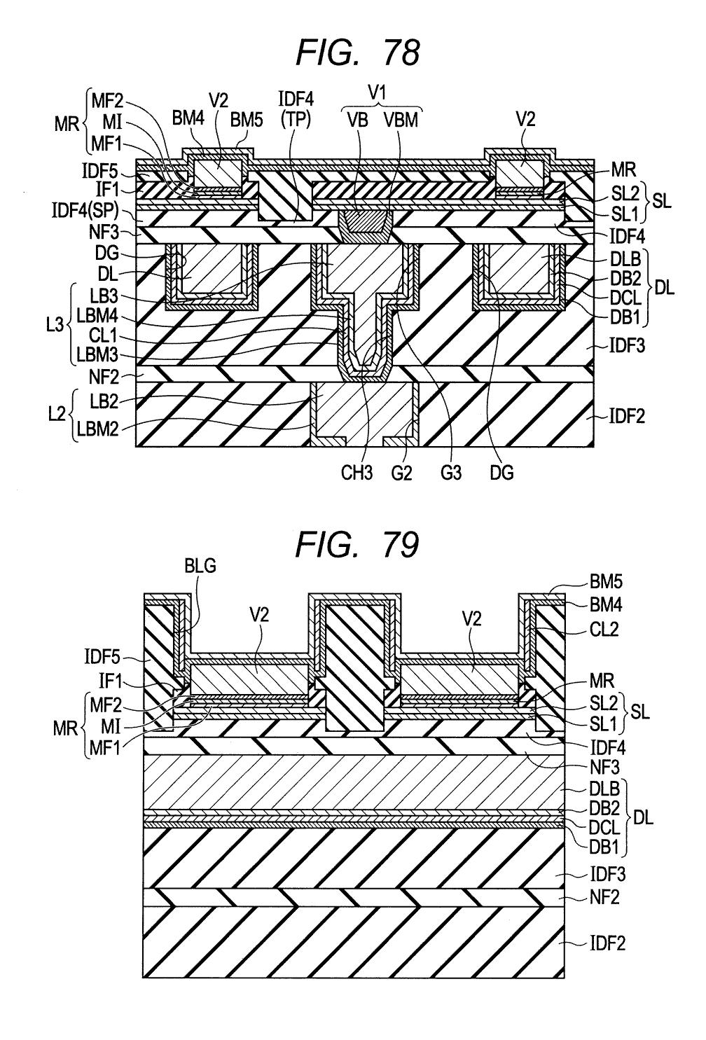

By this etching, the upper end portion of the via plug V2 and the top surface of the peripheral wiring P3 are exposed. As illustrated in FIGS. 78 to 80, a barrier metal BM4 and a clad layer CL2 are formed successively by using sputtering or the like.

Then the clad layer CL2 is etched to remove the clad layer CL2 formed on the bottoms of the trench portion BLG, the trench portion PG3, and the contact hole CH5, and on the top surface of the interlayer insulating film IDF5. As a result, the clad layer CL2 remains on the side surfaces of the trench portion BLG, the trench portion PG3, and the contact hole CH5. A barrier metal BM5 is then formed by sputtering.

Copper or a metal film composed mainly of copper is deposited on the barrier metal BM5 located on the top surface of the interlayer insulating film IDF5 by using electroplating, sputtering, or the like.

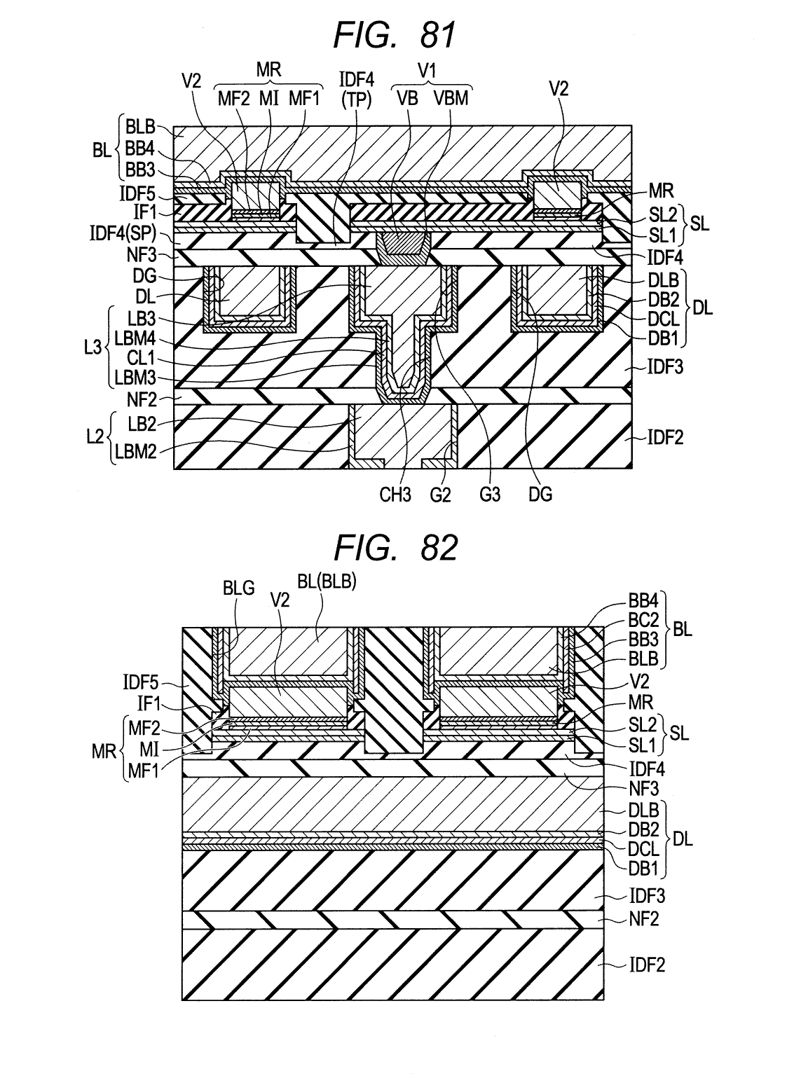

As illustrated in FIGS. 81 to 83, the metal film is planarized by using CMP to form a bit line body portion BLB filled in the trench portion BLG and a wiring body portion PLB3 filled in the contact hole CH5 and the trench portion PG3.

Then, the barrier metal BM5 and the barrier metal BM4 on the top surface of the interlayer insulating film IDF5 are removed using CMP to form a barrier metal BB3, a clad layer BC2, and a barrier metal BB4 in the trench portion BLG and form a barrier metal PLM4, a clad layer PLC2, and a barrier metal PLM5 on the inner peripheral surfaces of the trench portion PG3 and the contact hole CH5.

As a result, the bit line BL and the peripheral wiring P3 are formed and at the same time, a clad layer is formed on each side surface.

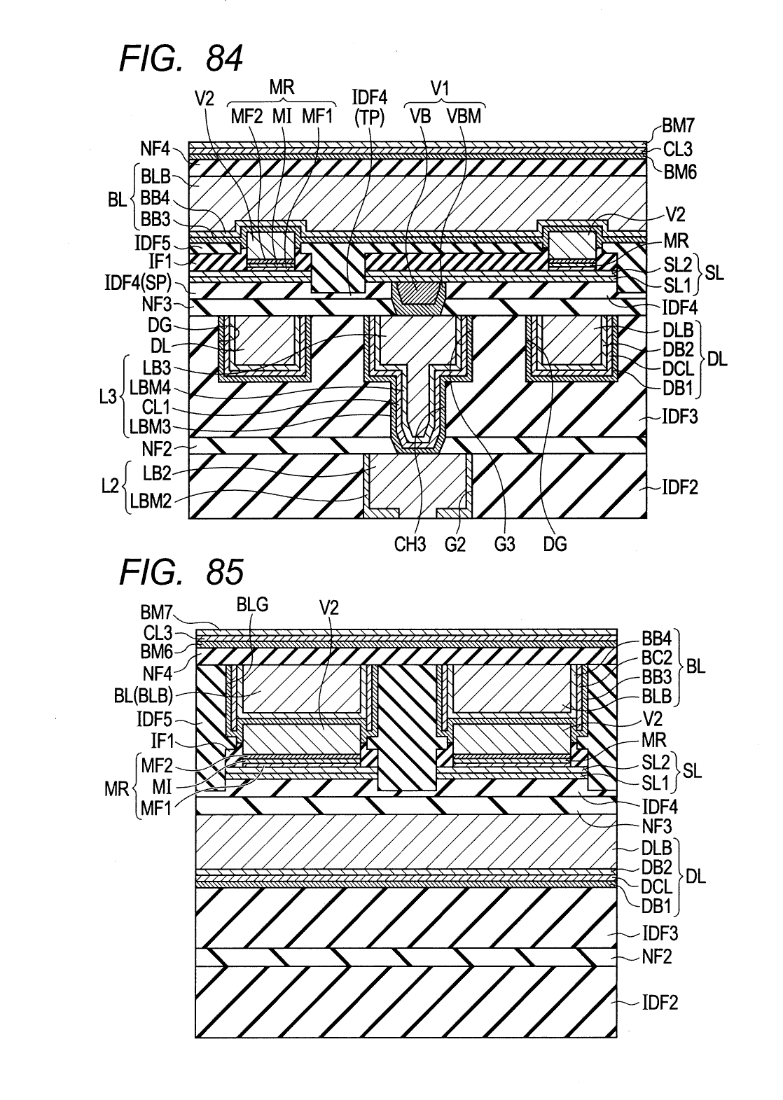

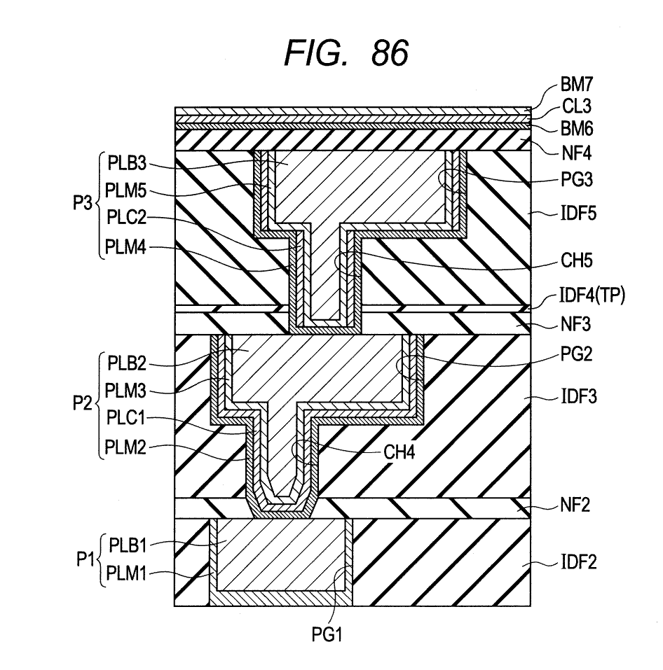

As illustrated in FIGS. 84 to 86, a diffusion preventive film NF4 such as an LT (low temperature)-SiN film is formed on the top surface of the interlayer insulating film IDF5 by using, for example, CVD.

The formation temperature of the diffusion preventive film NF4 can be set at, for example, 275° or less, making it possible to lessen an influence on the magnetization properties of the magnetic storage element MR which has already been formed.

Further, since the LT (low temperature)-SiN film is used and the diffusion preventive film NF4 can be formed at a reduced temperature, formation of hillocks in the bit line BL or peripheral wiring P3 can be inhibited.

After formation of the diffusion preventive film NF4, a barrier metal BM6, a clad layer CL3, and a barrier metal BM7 are stacked one after another by using sputtering or the like.

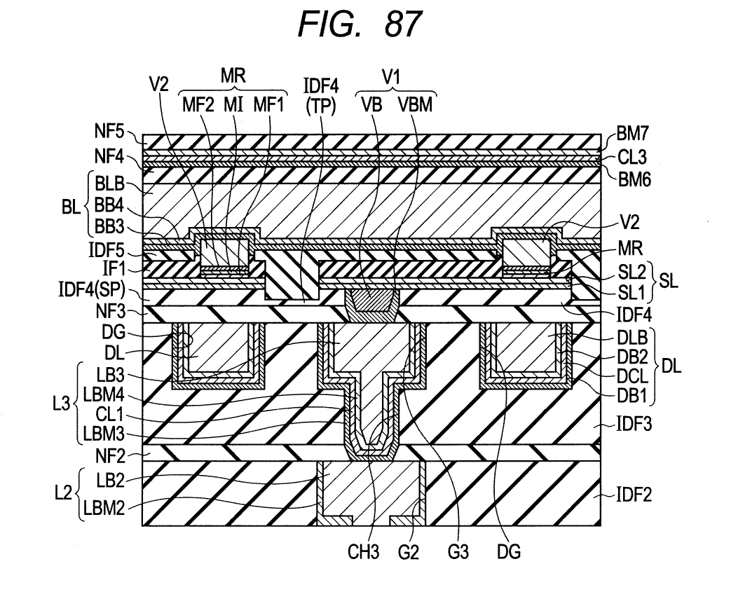

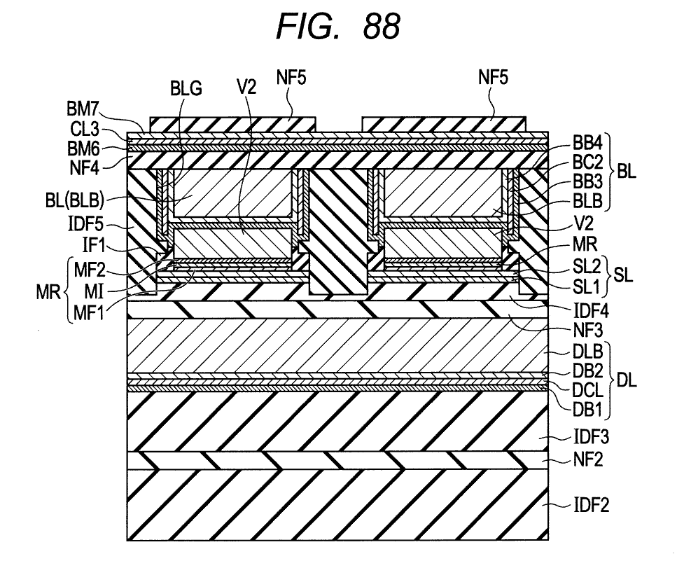

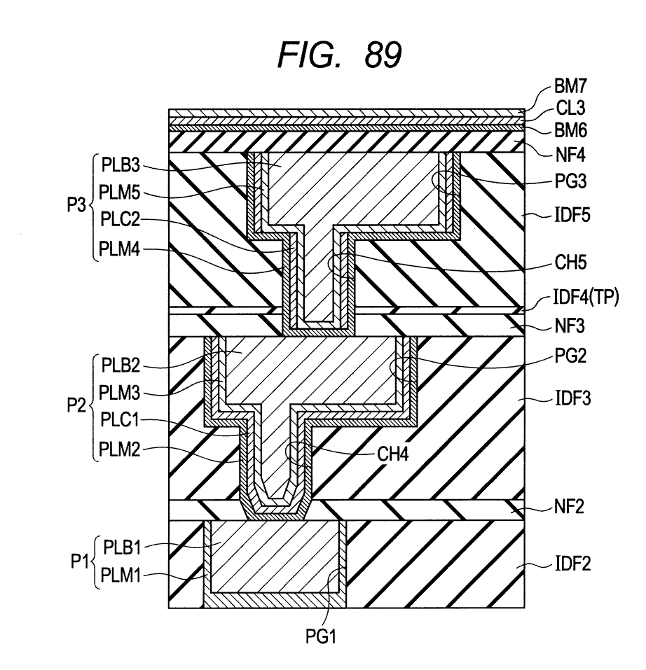

As illustrated in FIGS. 87 to 89, a diffusion preventive film NF5 made of an LT (low temperature)-SiN film is formed on the top surface of the barrier metal BM7. Incidentally, the formation temperature of the diffusion preventive film NF5 is also set at 275° C. or less so that formation of hillocks in the bit line BL can be inhibited. The resulting diffusion preventive film NF5 is then patterned.

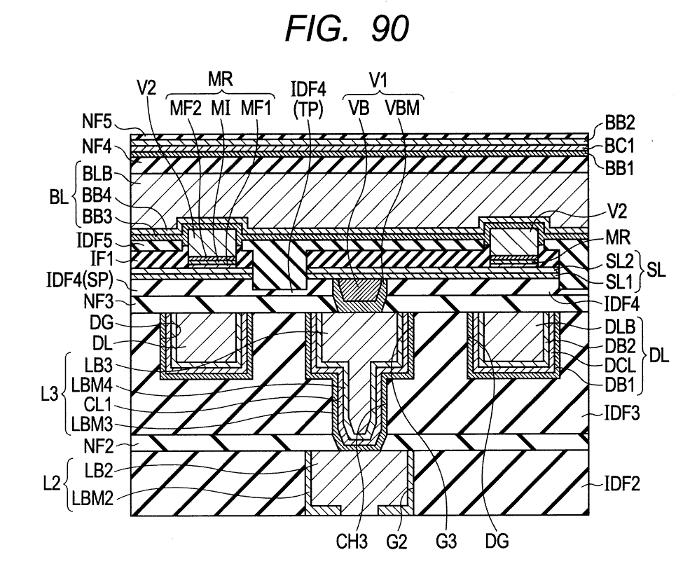

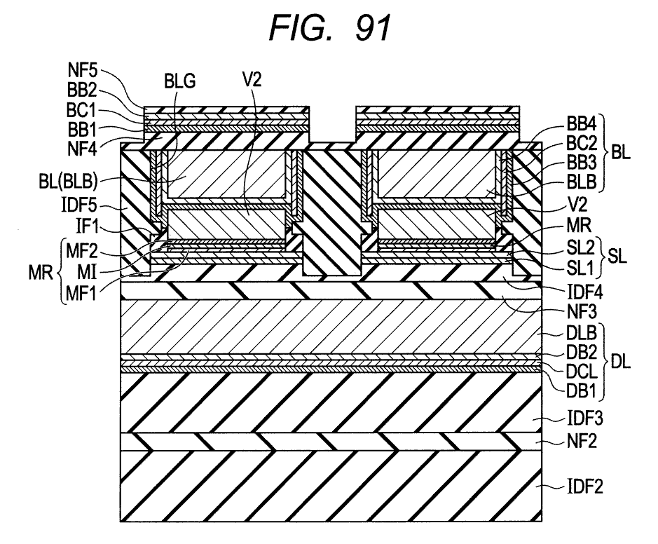

As illustrated in FIGS. 90 to 92, with the patterned diffusion preventive film NF5 as a mask, the barrier metal BM7, the clad layer CL3, and the barrier metal BM6 are patterned, by which a barrier metal BB1, a clad layer BC1, and a barrier metal BB2 located above the bit line BL are formed.

As illustrated in FIGS. 5 to 7, an upper-layer insulating film TI1 is formed on the top surface of the diffusion preventive film NF5 to cover the diffusion preventive film NF5. Also as the upper-layer insulating film TI1, an LT (low temperature)-SiN film is employed and it can be formed at a temperature as low as 275° C. or less. An influence on the magnetization properties of the magnetic storage element MR is therefore suppressed and moreover, formation of hillocks in the bit line BL and the peripheral wiring P3 is inhibited.

Upper-layer insulating films 112 and 113 are stacked one after another on the top surface of the upper-layer insulating film TI1. Incidentally, in a region which will be the peripheral circuit 200, an outer contact CT is formed by patterning the diffusion preventive film NF4 and the upper-layer insulating films TI1, TI2, and 113 and filling a metal film. In such a manner, the MRAM 100 and the peripheral circuit 200 according to the present embodiment can be obtained.

As described above, in the MRAM 100 and the peripheral circuit 200 of the semiconductor device according to the present embodiment, the diffusion preventive films NF1 and NF2 brought into contact with the top surface of the wirings (first wirings) L1 and L2 formed in the wiring layers LL1 and LL2 illustrated in FIG. 4 are made of a silicon carbonitride (SiCN) film or a silicon carbide film (SiC) film. On the other hand, the diffusion preventive film (first silicon nitride (SiN) film) NF3 brought into contact with the top surface of the digit line DL through which a rewrite current is caused to pass and the top surfaces of the wiring L3 and the peripheral wiring P2 formed in the same wiring layer LL3 as the digit line DL is made of an LT (low temperature)-SiN film. In the procedure of forming the diffusion preventive film NF3, formation of hillocks in the digit line DL or peripheral wiring P2 can therefore be inhibited and at the same time, diffusion of a copper element from the digit line DL or peripheral wiring P2 to therearound can be inhibited. Moreover, as illustrated in FIG. 5, since the clad layer (second metal film) DCL containing at least one element selected from cobalt (Co), nickel (Ni), and iron (Fe) covers the bottom surface and the side surface of the digit line DL, a rewrite current necessary for rewriting operation can be saved.

In particular, on the outer peripheral surface and the inner peripheral surface of the clad layer DCL, the barrier metals (first metal films) DB1 and DB2 containing at least one element selected from tantalum (Ta), titanium (Ti), ruthenium (Ru), manganese (Mn), magnesium (Mg), and tungsten (W) are formed so that diffusion of the metal element in the clad layer DCL or the copper element in the digit line DL can be inhibited, making it possible to suppress variations in the properties of the MOS transistor MT.

Further, the MRAM 100 is equipped further with a wiring (third wiring) L3 provided in the wiring layer (second wiring layer) LL3 and placed with a space from the digit line DL, a strap line (first strap line) SL provided in the wiring layer (third wiring layer) LL4 and coupled to the upper portion of the wiring L3, and an interlayer insulating film (interlayer insulating film) IDF4 formed on the diffusion preventive film (first silicon nitride (SiN) film) NF3.

Since the strap line SL is made of a metal material containing titanium (Ti), oxidation and nitriding of the strap line SL can be prevented during the manufacturing procedure of the MRAM 100.

In the present embodiment, the strap line SL is formed of a first metal film SL1 made of titanium (Ti) and a second metal film SL2 located on the first metal film SL1 and made of titanium nitride (TiN). Thus, since the strap line SL is made of such a film stack, oxidation and nitriding of the strap line SL can be prevented. Incidentally, the strap line SL may be made of only the second metal film SL2.

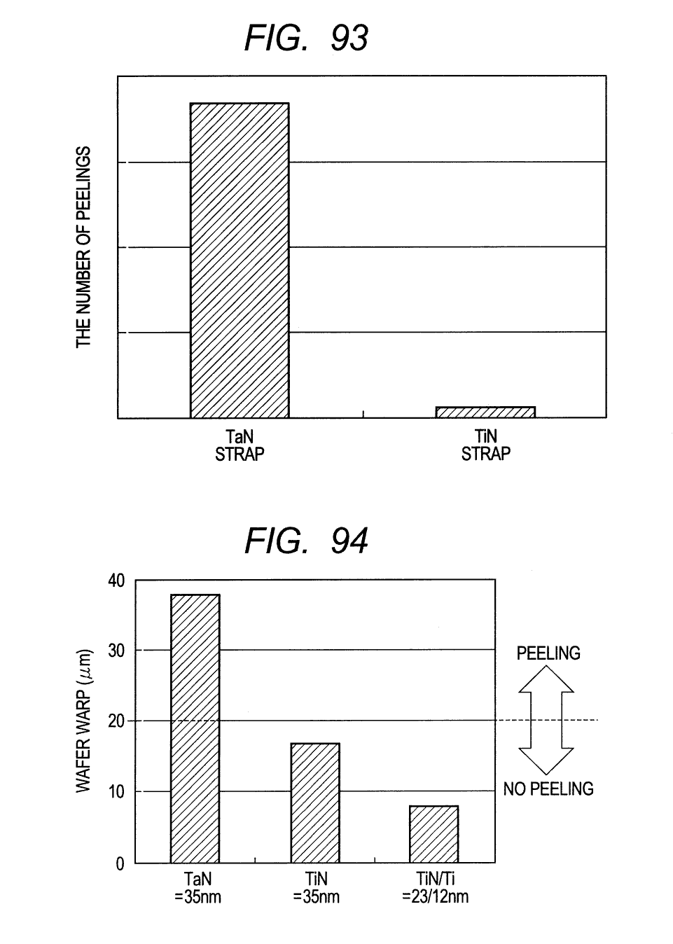

FIG. 93 is a graph, in the MRAM 100 of FIG. 5 in which the strap line SL has been formed while using different metals, showing the number (proportion) of peelings which have occurred between the digit line DL, the peripheral wiring P2, or the like and the diffusion preventive film NF3 during the manufacturing procedure of the MRAM 100.

In the graph of FIG. 93, the term “TaN strap” means an MRAM 100 having a strap line SL made of tantalum nitride (TaN), while the term “TiN strap” means an MRAM 100 having a strap line SL made of titanium nitride (TiN).

This graph shows the number (proportion) of peelings which have occurred between the digit line DL or the peripheral wiring P3 and the diffusion preventive film NF3 in each MRAM 100 when after etching of the film stack LMR to form the magnetic storage element MR and ashing, the wafer is cooled at room temperature.

As shown in this graph of FIG. 93, the proportion of peelings is by far smaller when the strap line SL is made of titanium nitride (TiN) than when the strap line SL is made of tantalum nitride (TaN).

This is because titanium nitride (TiN) is more resistant to oxidation and nitriding than tantalum nitride (TaN) so that the strap line SL made of titanium nitride can be inhibited from expanding in the etching or ashing step of the film stack LMR.

FIG. 94 is a graph showing a difference in the warp of the semiconductor substrate SS caused by cooling after patterning of the magnetic storage element MR when various strap lines SL are employed.

In the graph of FIG. 94, the term “TaN=35 nm” means an MRAM 100 having a strap line SL formed of a 35-nm thick tantalum nitride (TaN) film, while the term “TiN=35 nm” means an MRAM 100 having a strap line SL formed of a 35-nm thick titanium nitride (TiN) film. The term “TiN/Ti=23/12 nm” means an MRAM 100 having, as a strap line SL, a film stack of a 12-nm thick titanium (Ti) film and a 23-nm thick titanium nitride film (TiN) film formed on the titanium (Ti) film.

This graph shows the measurement results of wafer warp of the above three MRAMs 100 which has occurred when after etching of the film stack LMR to form the magnetic storage element MR and asking, the wafer is cooled.

Incidentally, the above three MRAMs 100 have a substantially similar configuration to each other except the strap line SL.

In any of the MRAMs 100, when the warp of the wafer (the semiconductor substrate SS) is 20 μm or greater, peeling occurs between the strap line SL or peripheral wiring P3 and the diffusion preventive film NF3.

As can be under stood from the graph, in the MRAM 100 having a strap line SL made of tantalum nitride (TaN), the warp of the wafer is about 38 μm; the warp of the wafer is about 18 μm when the strap line SL is made of titanium nitride (TiN); and in the MRAM 100 having a strap line SL made of a film stack of titanium (Ti) and titanium nitride (TiN), the warp of the wafer is about 8 μm.

It has been found that the MRAM 100 having a strap line SL formed of a film stack of titanium (Ti) and titanium nitride (TiN) shows the smallest wafer warp and the MRAM 100 having a strap line SL made of titanium nitride (TiN) shows the next smallest wafer warp.

It has also been found that the MRAM 100 having a strap line SL made of a film stack of titanium (Ti) and titanium nitride (TiN) and the MRAM 100 having a strap line SL made of titanium nitride (TiN) each shows a wafer warp smaller than 20 μm.

Accordingly, this suggests that the strap line SL made of titanium nitride (TiN) or a film stack of titanium (Ti) and titanium nitride (TiN) can greatly reduce the probability of peeling between the digit line DL or peripheral wiring P3 and the diffusion preventive film NF3.

Referring to FIGS. 93 and 94, the advantages attributable to the digit line DL of the MRAM 100 according to the present embodiment have been described. Further, the following advantages are available in the present embodiment.

The MRAM 100 of the semiconductor device according to the present embodiment has an insulating film (second silicon nitride (SiN) film) IF1 which is formed on the strap line SL, covers at least the side surface of the magnetic storage element MR, and is made of an LT (low temperature)-SiN film. By using, as an insulating film formed on the magnetic storage element MR, an LT (low temperature)-SiN film which can be formed at a low temperature, it is possible to inhibit variations in the magnetic properties of the magnetic storage element MR and at the same time, inhibit formation of hillocks in the digit line DL.

The MRAM 100 of the semiconductor device according to the present embodiment further has a bit line BL which is formed in the wiring layer LL4, formed on the magnetic storage element MR, and coupled to the upper end portion of the magnetic storage element MR, and a diffusion preventive film (third silicon nitride (SiN) film) NF4 which is brought into contact with the top surface of the bit line BL and is made of an LT (low temperature)-SiN film. Thus, by using an LT (low temperature)-SiN film which can be formed at a low temperature as an insulating film to be formed on the bit line BL, formation of hillocks in the bit line BL can be inhibited during the manufacturing procedure. In particular, the formation temperature of a silicon carbonitride (SiCN) film or a silicon carbide film (SiC) is about 450° C., while that of a silicon nitride (SiN) film can be suppressed to 275° C. or less. This makes it possible to prevent hillocks and to inhibit variations in the magnetization properties of the magnetic storage element MR. On the other hand, a silicon carbonitride film or a silicon carbide film has a lower dielectric constant than a silicon nitride film so that use of it can increase the operation speed of the device.

### Second Embodiment

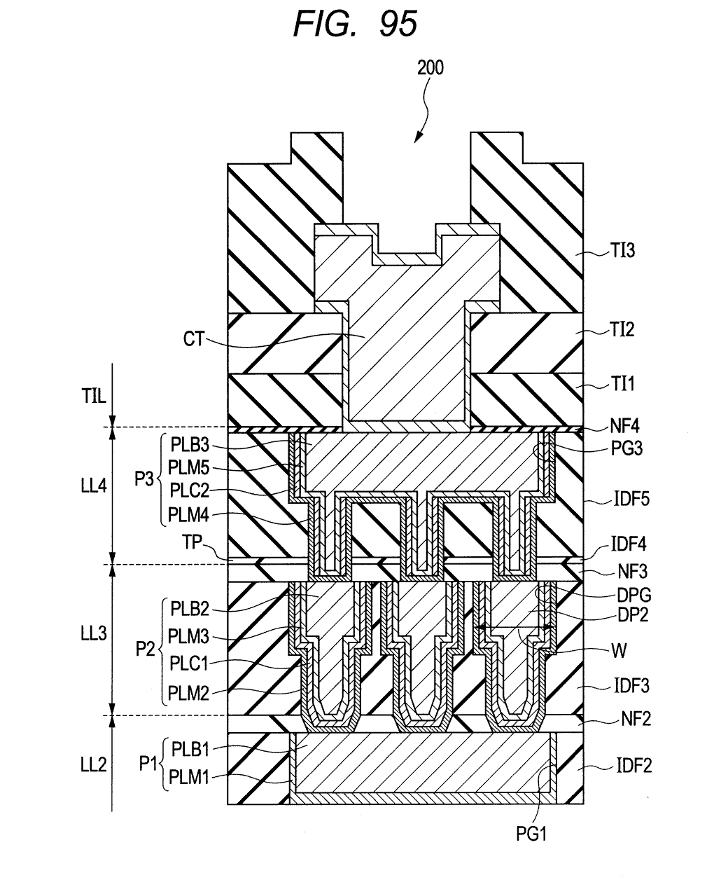

Referring to FIGS. 95 to 100, a semiconductor device having an MRAM 100 and a peripheral circuit 200 will be described. Configurations shown in FIGS. 95 to 100 similar to or corresponding to the configurations shown in FIGS. 1 to 92 are identified by like reference numerals and a description on them may be omitted.

FIG. 95 is a cross-sectional view of the peripheral circuit 200 of a semiconductor device according to Second Embodiment of the present invention. In the example shown in FIG. 95, a peripheral wiring P2 has a plurality of split wirings DP2. The split wirings DP2 are placed with a space and they are each coupled to a peripheral wiring P3 and a peripheral wiring P1. The width W of the peripheral split wiring DP2 can be made smaller by configuring the peripheral wiring P2 from a plurality of split wirings DP2. For example, the maximum width of the split wiring DP2 is made smaller than the maximum width of the digit line DL, the wiring L1, the wiring L2, the wiring L3, the peripheral wiring P1, or the peripheral wiring P3. In the semiconductor device according to Second Embodiment and the semiconductor device according to First Embodiment, the thickness of the wiring layer LL1 or the wiring layer LL2 and the thickness of the wiring layer LL3 are substantially the same.

In particular, the maximum width of the split wiring DP2 is smaller than the maximum width of each of the wiring L1, the wiring L2, and the peripheral wiring P1 formed in the wiring layer LL1 and the wiring layer LL2 (first wiring layer).

The peripheral wiring P2 is likely to cause peeling at the interface with the diffusion preventive film NF3 when an internal stress occurs in the first metal film SL1 and the second metal film SL2 during the manufacturing procedure of the semiconductor device. In particular, it has been found as a result of intensive efforts that there is a certain relationship between the width of the peripheral wiring P2 (width in the cross-section perpendicular to the extending direction of the peripheral wiring P2) and a probability of peeling. When the wiring has a width greater than 4 μm, peeling occurs. Details will be described later.

The wiring L1, the wiring L2, and the peripheral wiring P1 located in the wiring layer LL1 and the wiring layer LL2 are more distant from the first metal film SL1 and the second metal film SL2 than the peripheral wiring P2.

Even if the first metal film SL1 and the second metal film SL2 shrink due to cooling after expansion caused by oxidation or nitriding during the manufacturing procedure, there does not easily occur peeling between the wiring L1 and the diffusion preventive film NF1 or between the wiring L2 and the diffusion preventive film NF2.

It is therefore possible to inhibit occurrence of peeling between the split wiring DP2 and the diffusion preventive film NF3 by configuring the peripheral wiring P2 from a plurality of split wirings DP2 and making the width of each of the split wirings DP2 smaller than the width of the wiring formed in the wiring layer LL1 and the wiring layer LL2.

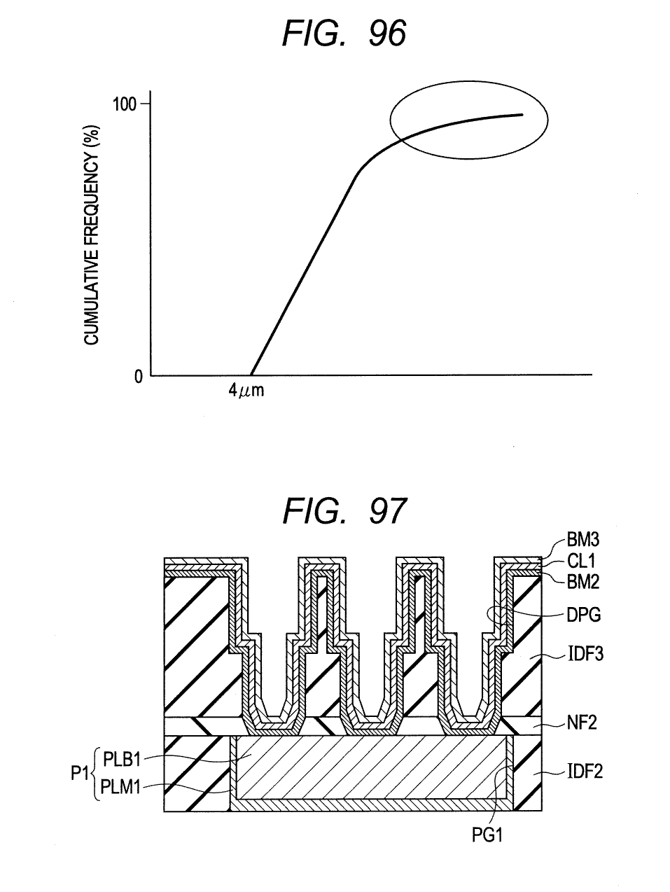

FIG. 96 is a graph showing the mutual relationship between the width of the peripheral wiring P2 and peeling that occurs between the peripheral wiring and the diffusion preventive film NF3. FIG. 96 shows the cumulative frequency at a portion, in the MRAM 100 and the peripheral circuit 200, where peeling occurs. The width of the wiring at which peeling has occurred between the wiring and the diffusion preventive film NF3 is plotted along the abscissa. FIG. 96 shows that no peeling occurs when the wiring width is 4 μm or less. This suggests that the maximum width of the split wiring DP2 is set at 4 μm or less. Because of the same reason, the maximum width of each of the digit line DL and the wiring L3 is set at preferably 4 μm or less.

In the graph of FIG. 96, peeling frequency decreases in a region enclosed with a solid line because there are not many portions, in the MRAM 100 and the peripheral circuit 200, where the width of the wiring becomes 20 μm or greater. In the example shown in FIG. 95, the width of each of the split wirings DP2 is made smaller by configuring the peripheral wiring P2 from a plurality of split wirings DP2. Alternatively, the maximum width of the peripheral wiring P2 shown in FIG. 7 may be made smaller than the maximum width of the wiring L1, wiring L2, or the peripheral wiring P1 formed in the wiring layer LL1 and the wiring layer LL2 (first wiring layer). In this case, the maximum width of the peripheral wiring P2 is made smaller than 4 μm.

Referring to FIGS. 97 to 100, a manufacturing method of the semiconductor device according to Second Embodiment will next be described.

FIG. 97 is a cross-sectional view showing one of the manufacturing steps of the semiconductor device according to Second Embodiment and it is a cross-sectional view showing a step corresponding to that of FIG. 32. As illustrated in FIG. 97, a plurality of trench portions DPG are formed in the interlayer insulating film IDF3. Then, a barrier metal BM2, a clad layer CL1, and a barrier metal BM3 are stacked one after another.

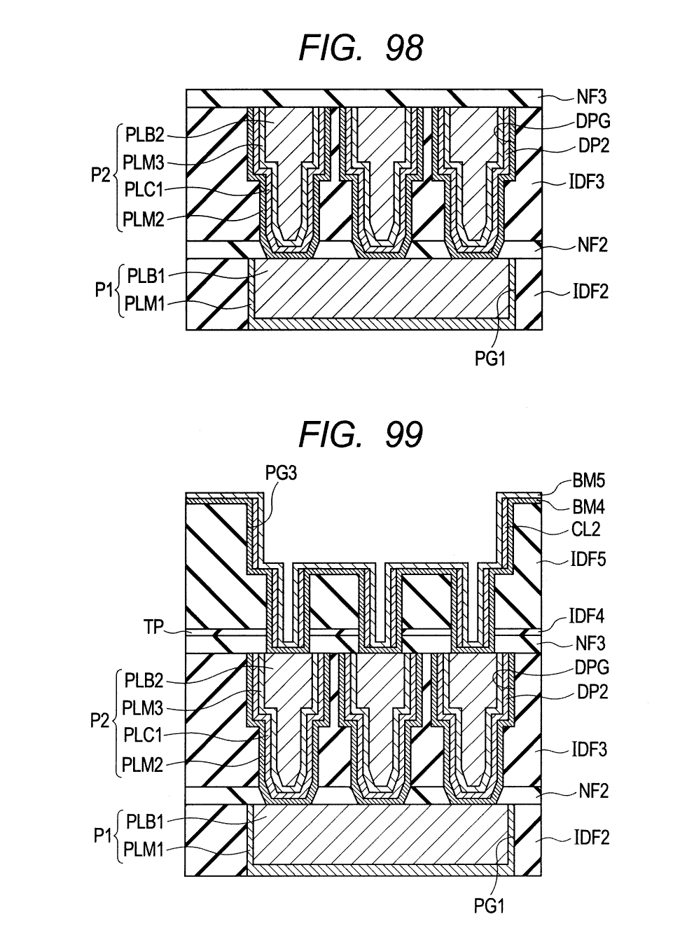

As illustrated in FIG. 98, copper (embracing a metal composed mainly of copper) is then deposited using electroplating or sputtering. Copper is thus filled in each of the trench portions DPG. Then, CMP is performed to planarize the copper film and at the same time, remove the copper film on the interlayer insulating film IDF4. Further, the barrier metal BM2, the clad layer CL1, and the barrier metal BM3 on the interlayer insulating film IDF4 are removed. Then, a silicon nitride (SiN) film is formed as a diffusion preventive film NF3. The step shown in FIG. 97 corresponds to that shown above in FIG. 35.

After the manufacturing step shown in FIG. 98, substantially similar treatments to those performed in the manufacturing steps of First Embodiment are performed.

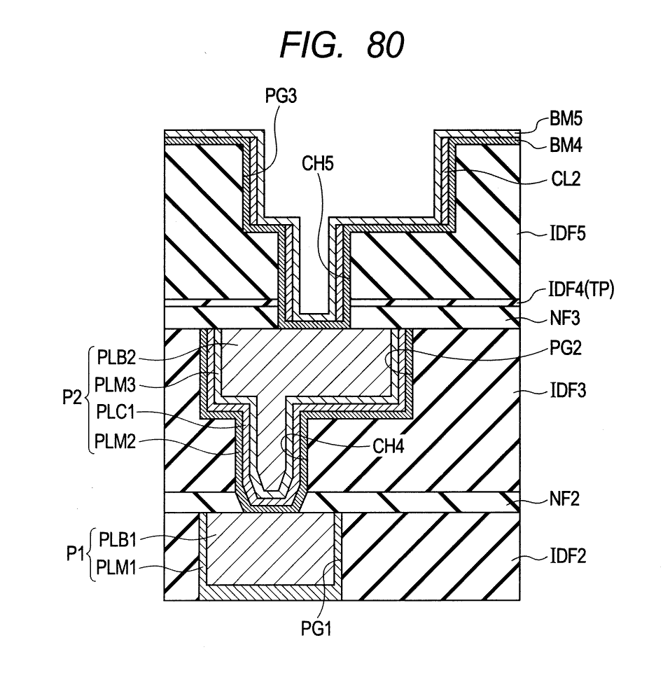

As illustrated in FIG. 99, a trench portion PG3 is formed on the top surface of the interlayer insulating film IDF5. Then, a barrier metal BM4 and a clad layer CL2 are stacked one after another. The clad layer CL2 is etched to remove the clad layer CL2 on the bottom surface of the trench portion PG2 and on the top surface of the interlayer insulating film IDF5. Then, a barrier metal BM5 is deposited. Incidentally, the step shown in FIG. 99 corresponds to the step shown above in FIG. 80.

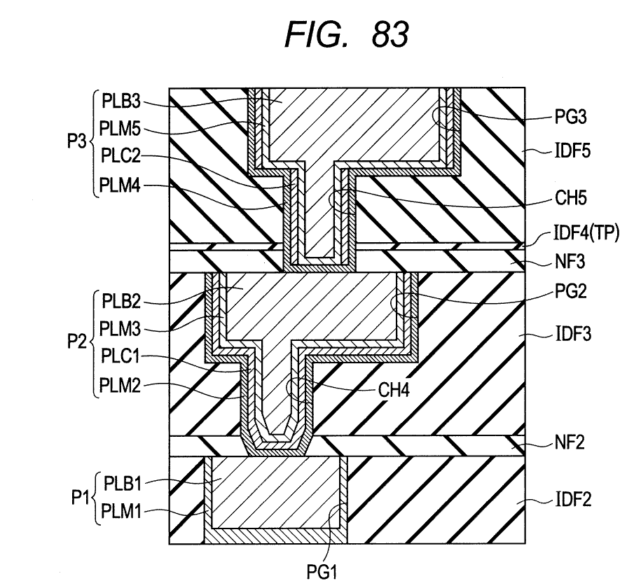

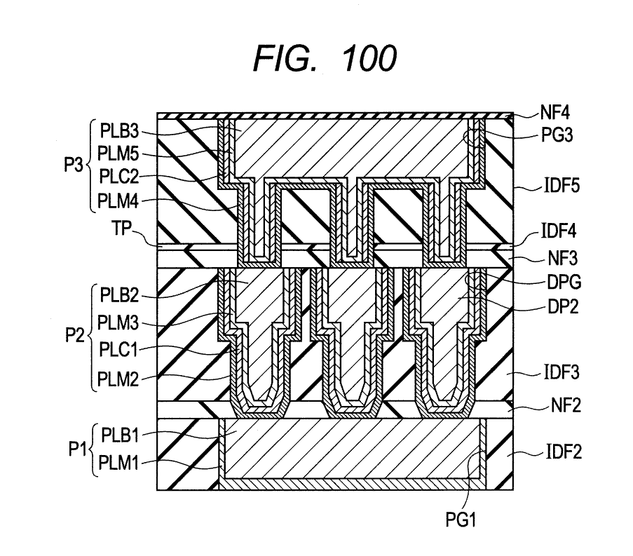

As illustrated in FIG. 100, copper is formed on the interlayer insulating film IDF5 by using sputtering or electroplating. Copper is thus filled in the trench portion PG3. Then, the copper, the barrier metal BM4, and the barrier metal BM5 on the interlayer insulating film IDF5 are removed. A diffusion preventive film NF4 made of silicon nitride (SiN) is then formed. Incidentally, the step shown in FIG. 100 corresponds to the step shown above in FIG. 83.

Substantially similar treatments to those described above in First Embodiment are then performed to manufacture the semiconductor device of Second Embodiment.

According to the manufacturing method of the semiconductor device according to Second Embodiment, since the peripheral wiring P2 is formed of a plurality of split wirings DP2 having a small width, it is possible to inhibit peeling between the split wiring DP2 and the diffusion preventive film NF3 even if the wafer warps as a result of patterning of the film stack LMR.

### Third Embodiment

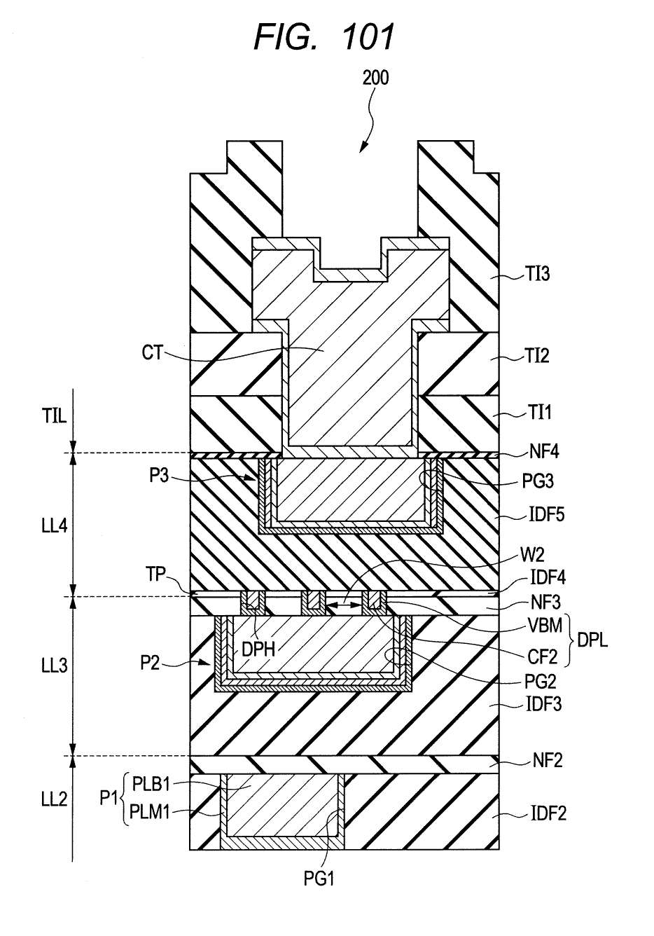

Referring to FIGS. 101 to 110, a manufacturing method of a semiconductor device according to Third Embodiment of the present invention will be described. Configurations shown in FIGS. 101 to 110 which are similar to or corresponding to the configurations shown in FIGS. 1 to 100 are identified by like reference numerals and a description on them may be omitted.

FIG. 101 is a cross-sectional view, in a peripheral circuit 200, of the semiconductor device according to Third Embodiment. In FIG. 101, the position of the cross-section is different from that shown above in FIG. 7.

As illustrated in FIG. 101, a plurality of dummy plugs DPL are formed on the top surface of the peripheral wiring P2. The dummy plugs DPL are located so that a width W2 between any adjacent two is made smaller than 4 μm. Incidentally, in the example shown in FIG. 101, three dummy plugs DPL are formed, but the number is not limited to 3 but it is needless to say that it can be changed as needed.

The dummy plug DPL is formed in a hole portion DPH penetrating through the diffusion preventive film NF3 and the interlayer insulating film IDF4. The dummy plug DPL is formed of a barrier metal VBM formed on the inner peripheral surface and bottom of the hole portion DPH and a conductive film CF2 formed on the barrier metal VBM and filled in the hole portion DPH.

In the example shown in FIG. 101, the upper end portion of the dummy plug DPL is brought into contact with the interlayer insulating film IDF5. Due to the plurality of dummy plugs DPL on the top surface of the peripheral wiring P2, adhesion between the diffusion preventive film NF3 and the peripheral wiring P2 is enhanced.

This makes it possible to prevent peeling between the diffusion preventive film NF3 and the peripheral wiring P3 which will otherwise occur during the manufacture of the peripheral circuit 200 as shown in FIG. 101.

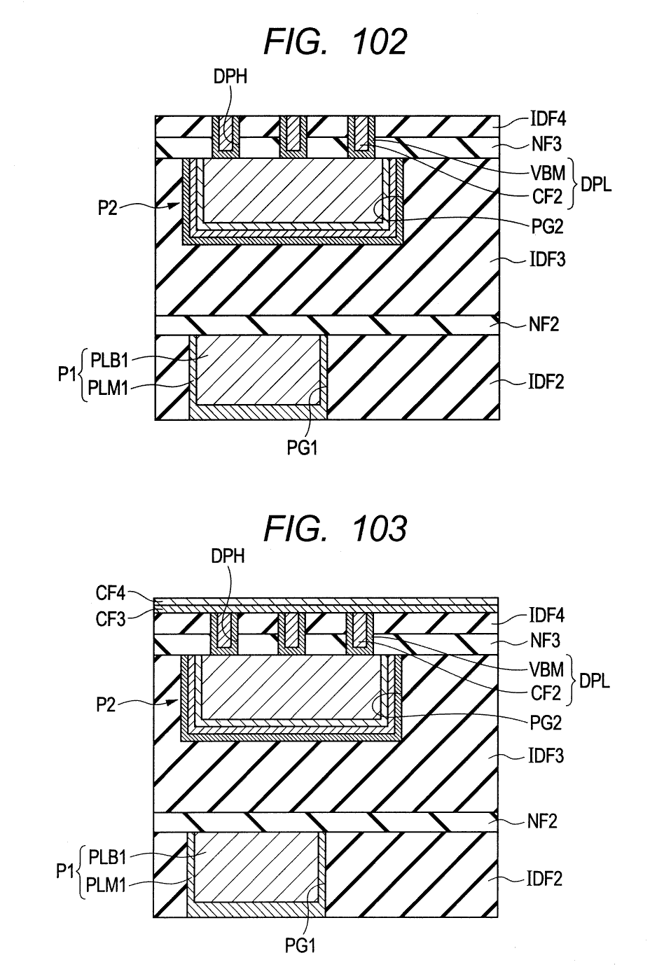

A manufacturing method of the semiconductor device according to Third Embodiment will next be described referring to FIGS. 102 to 110.

FIG. 102 is a cross-sectional view showing one of the manufacturing steps of the peripheral circuit 200 of the semiconductor device according to Third Embodiment.

The manufacturing step shown in FIG. 102 corresponds to, among the manufacturing steps of First Embodiment, that shown in FIG. 50.

As illustrated in FIG. 102, a hole portion DPH is formed in the diffusion preventive film NF3 and the interlayer insulating film IDF4, followed by the formation of a barrier metal VBM. After formation of the barrier metal VBM, a metal film such as copper is deposited using sputtering or the like to fill the hole portion DPH with the metal film. The metal film thus deposited is planarized using CMP or the like, by which the metal film such as copper on the interlayer insulating film I DF4 is removed.

As illustrated in FIG. 103, a conductive film CF3 is then formed on the top surface of the interlayer insulating film IDF4, followed by the formation of a conductive film CF4 on the top surface of the conductive film CF3. The manufacturing step shown in FIG. 103 corresponds to the manufacturing step illustrated in FIG. 53 of First Embodiment. As illustrated in FIG. 104, a fixed magnetization layer MF1, a tunnel insulating film MI, a free magnetization layer MF2, a conductive film CF5, and a silicon oxide film HDP are stacked one after another. The manufacturing step illustrated in FIG. 104 corresponds to that illustrated in FIG. 59 of First Embodiment.

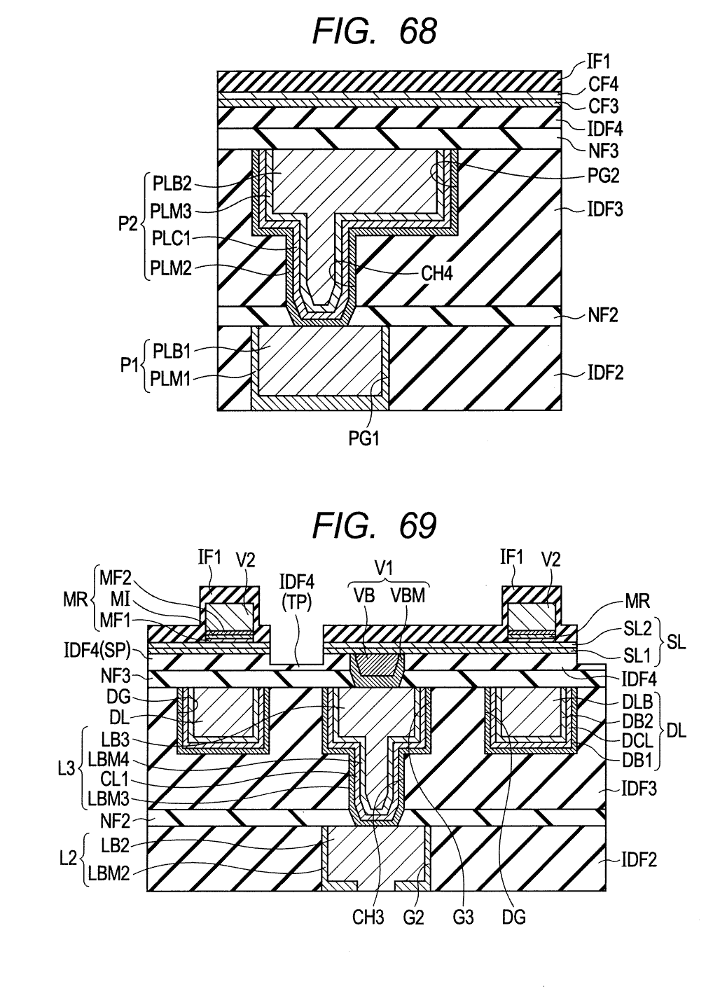

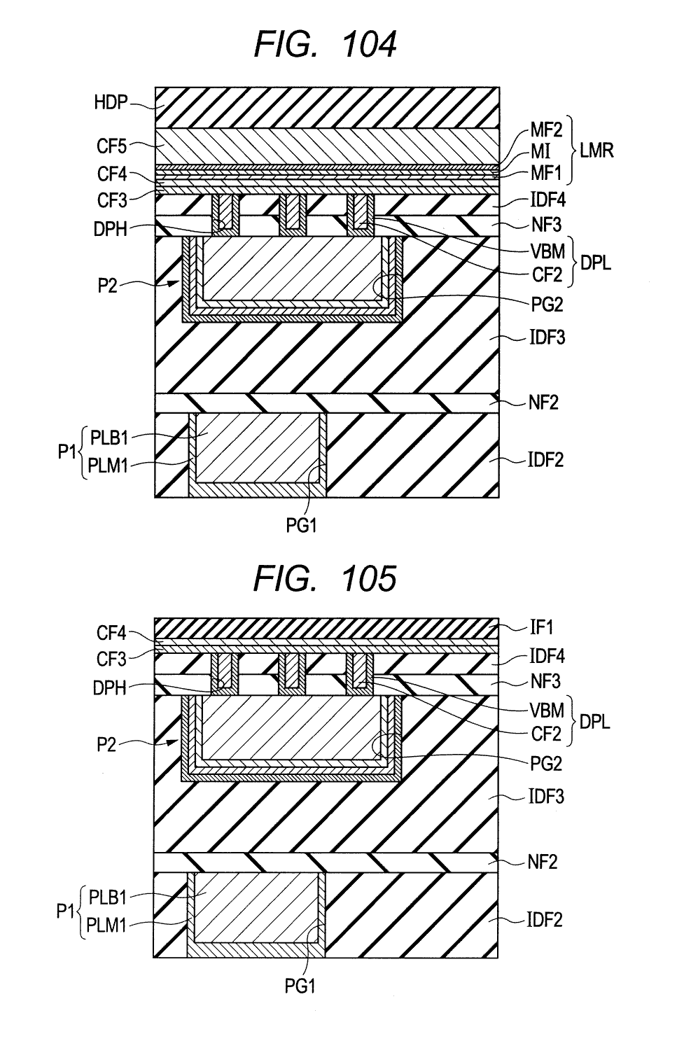

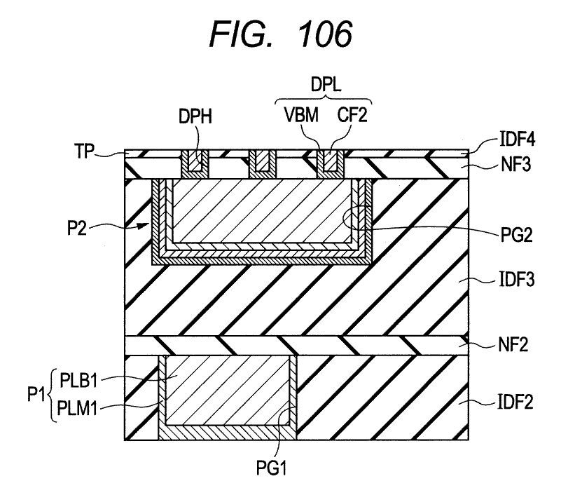

As illustrated in FIG. 105, the silicon oxide film HDP, the conductive film CF5, and the film stack LMR formed on the top surface of the conductive film CF4 are removed successively from a region of the peripheral circuit 200 of Third Embodiment. Then, an insulating film IF1 is formed on the top surface of the conductive film CF4. The step illustrated in FIG. 105 corresponds to the step shown above in FIG. 68. As illustrated in FIG. 106, the insulating film IF1, the conductive film CF4, and the conductive film CF3 on the interlayer insulating film IDF4 are removed successively. Further, the interlayer insulating film IDF4 is thinned by etching. As a result, dummy plugs DPL are formed on the top surface of the peripheral wiring P2.

Then, manufacturing steps similar to those of First Embodiment are performed to obtain the peripheral circuit 200 illustrated in FIG. 101.

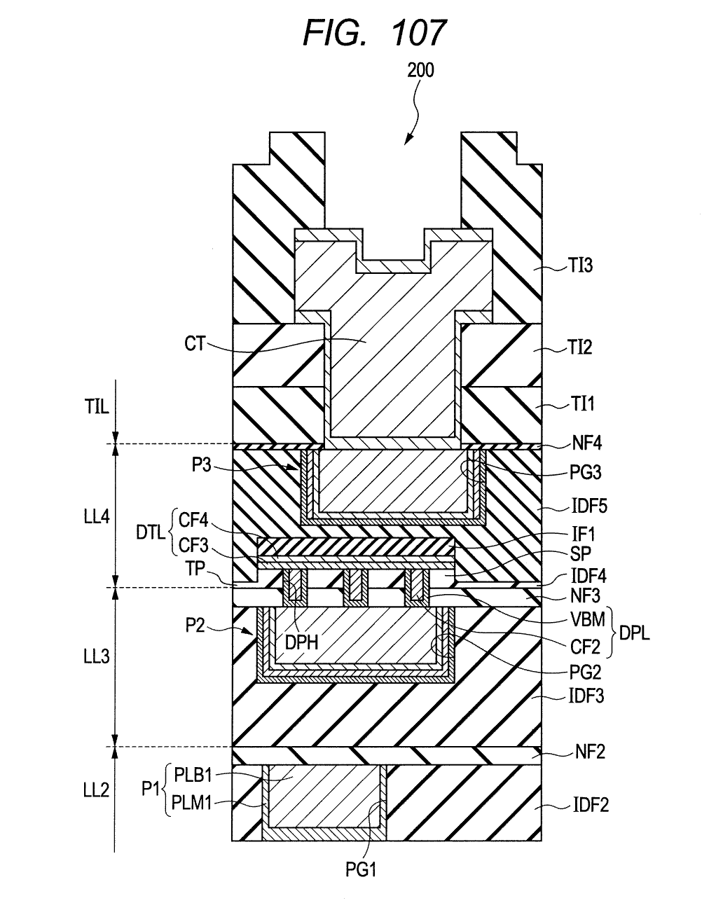

FIG. 107 is a cross-sectional view showing a modification example of the peripheral circuit 200. In the example shown in FIG. 107, the dummy plugs DPL are formed in a hole portion DPH penetrating through the thick film portion SP of the interlayer insulating film IDF4 and the diffusion preventive film NF3.

The upper end portion of the dummy plug DPL is coupled to a dummy upper-layer wiring DTL. This dummy upper-layer wiring DTL is made of a film stack of a conductive film CF3 and a conductive film CF4. The conductive film CF3 and the conductive film CF4 of the dummy upper-layer wiring DTL are formed in the same layer as the first metal film SL1 and the second metal film SL2 of the strap line SL illustrated in FIG. 5, but the dummy upper-layer wiring DTL is not electrically coupled to the strap line SL and the magnetic storage element MR. Thus, the upper end portion of the dummy plug DPL may be coupled to a conductive film (metal film).

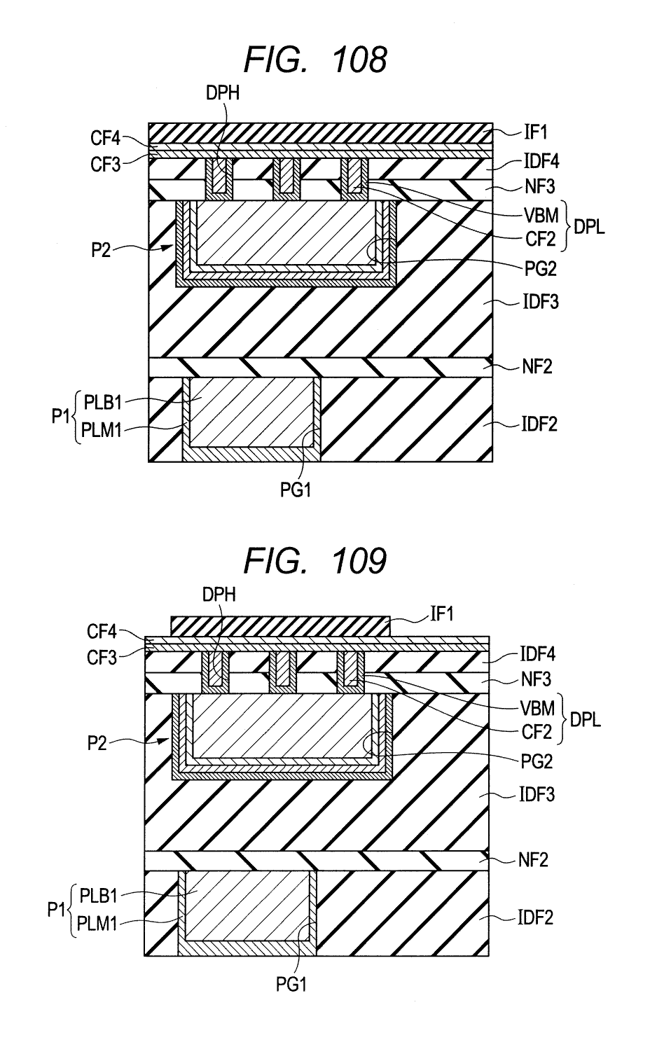

FIG. 108 is a cross-sectional view illustrating one of the manufacturing steps of the peripheral circuit 200 shown in FIG. 107. The step shown in FIG. 108 corresponds to the manufacturing step of First Embodiment illustrated in FIG. 68. As shown in FIG. 108, an insulating film IF1 made of silicon nitride (SiN) is formed on the top surface of the conductive film CF4.

As illustrated in FIG. 109, the insulating film IF1 is then patterned to leave a portion of the insulating film IF1 which is located above the dummy plugs DPL.

As illustrated in FIG. 110, with the patterned insulating film IF1 as a mask, the conductive film CF4 and the conductive film CF3 are then patterned. As a result, the conductive film CF4 and the conductive film CF3 coupled to the upper portion of the dummy plugs DPL remain.

Manufacturing steps substantially similar to those of the semiconductor device according to First Embodiment are then performed to obtain a semiconductor device having the peripheral circuit 200 illustrated in FIG. 107.

### Fourth Embodiment

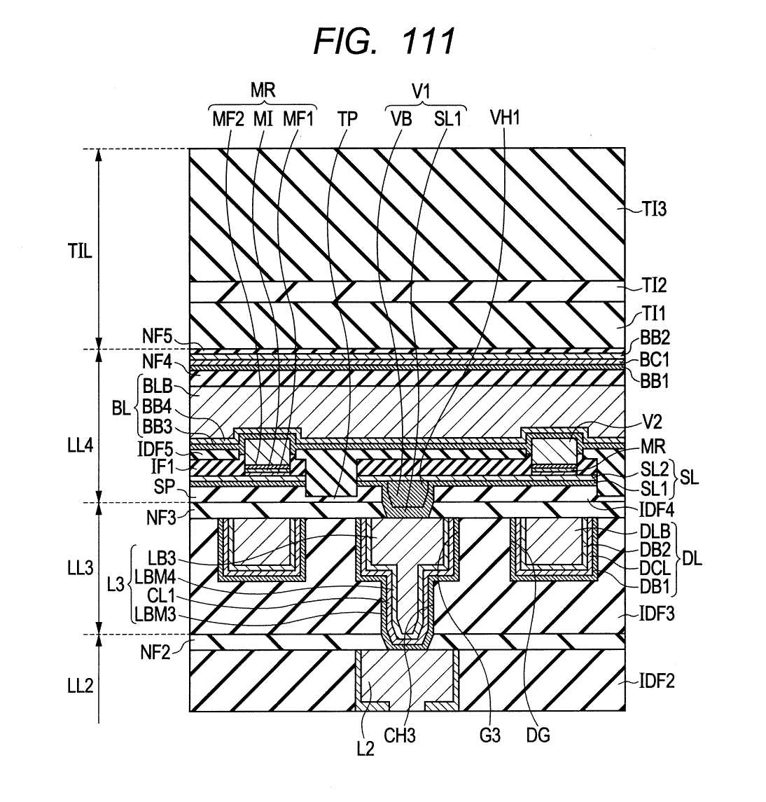

Referring to FIGS. 111 to 121, a semiconductor device of Fourth Embodiment will be described. Incidentally, among the configurations shown in FIGS. 111 to 120, those similar to or corresponding to the configurations shown in FIGS. 1 to 110 are identified with a like reference numeral and the description on them is omitted. FIG. 111 is a cross-sectional view of an MRAM 100 loaded on the semiconductor device according to Fourth Embodiment. As illustrated in FIG. 111, the MRAM 100 according to Fourth Embodiment is also equipped with, in the wiring layer LL4 thereof, a via plug V1 formed in the diffusion preventive film NF3 and the interlayer insulating film IDF4, a strap line SL coupled to the via plug V1, and a magnetic storage element MR formed on the top surface of the strap line SL.

The via plug V1 is formed in a via hole VH1 penetrating through the diffusion preventive film NF3 and the interlayer insulating film IDF4. The via plug V1 is equipped with a first metal film SL1 formed on the inner peripheral surface of the via hole VH1 and on the top surface of the interlayer insulating film IDF4 and a via body VB formed on the first metal film SL1 and filled in the via hole VH1.

The strap line SL is equipped with the first metal film SL1 and a second metal film SL2 formed on the top surface of the first metal film SL1. Thus, the first metal film SL1 configures a portion of the via plug V1 and at the same time, configures a portion of the strap line SL. Also in Fourth Embodiment, the first metal film SL1 is made of a titanium (Ti) film and the second metal film SL2 is made of a titanium nitride (TiN) film.

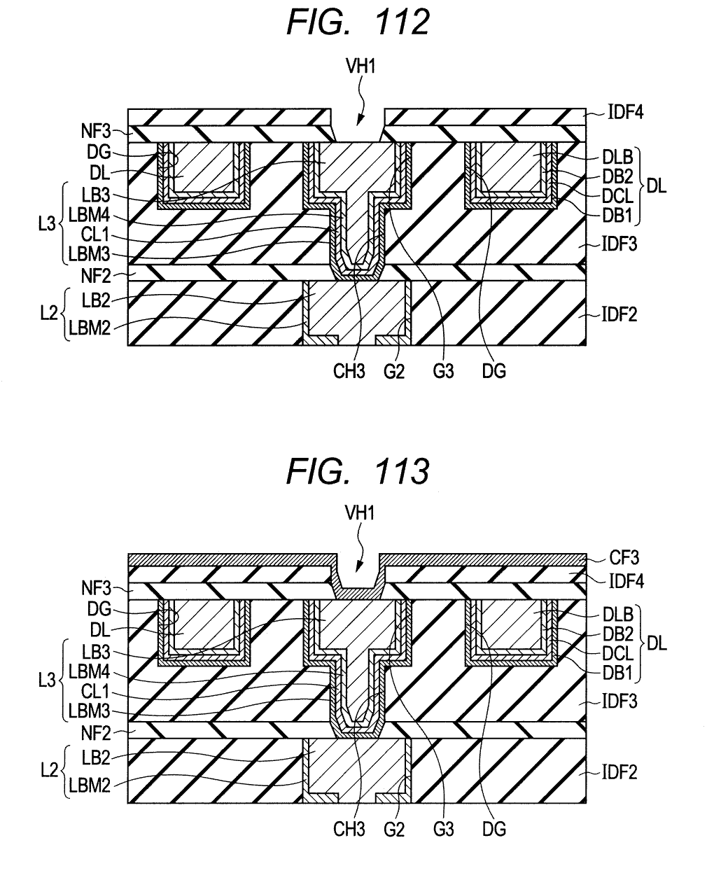

Since the first metal film SL1 configures both the via plug V1 and the strap line SL, the manufacturing steps of the semiconductor device can be simplified. Referring to FIGS. 112 to 120, the manufacturing method of the semiconductor device according to Fourth Embodiment will next be described.

FIG. 112 is a cross-sectional view illustrating one of the manufacturing steps of the MRAM 100 according to Fourth Embodiment. The step illustrated in FIG. 112 corresponds to the manufacturing step illustrated in FIG. 39. As illustrated in FIG. 112, photolithography and etching are performed to form a via hole VH1 in the interlayer insulating film IDF4.

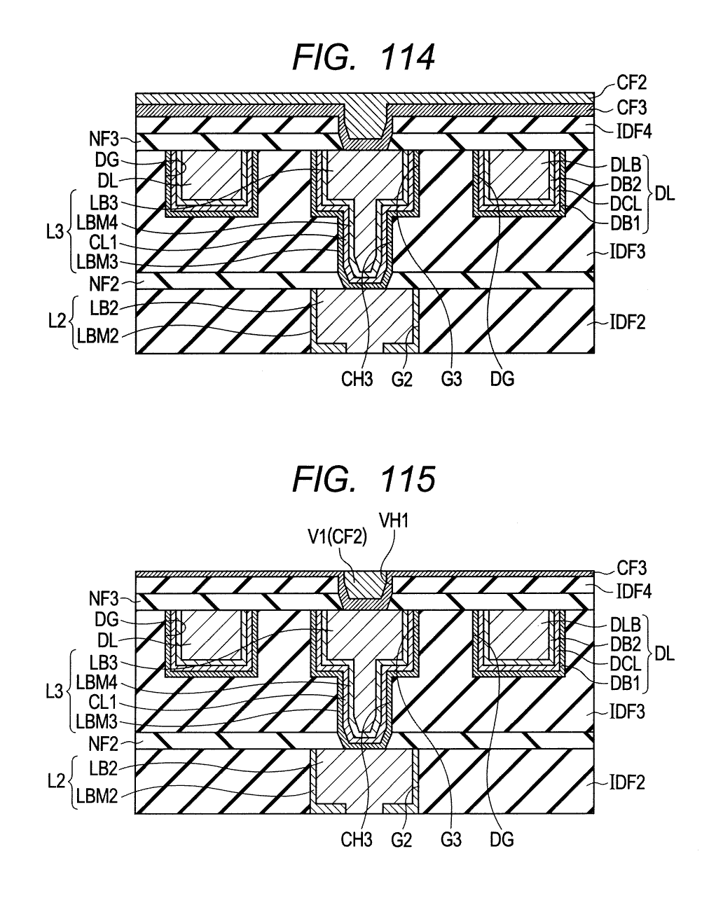

As illustrated in FIG. 113, a conductive film CF3 is formed using sputtering so as to cover therewith the top surface of the interlayer insulating film IDF4 and the inner peripheral surface of the via hole VH1. Incidentally, titanium (Ti) is employed as the conductive film CF3. As illustrated in FIG. 114, a conductive film CF2 is formed using sputtering on the top surface of the conductive film CF3. As the conductive film CF2, a metal material such as tungsten or copper is employed.

As illustrated in FIG. 115, the conductive film CF2 and the conductive film CF3 are subjected to CMP. By this treatment, the top surface of the conductive film CF3 is exposed and the conductive film CF3 remains on the top surface of the interlayer insulating film IDF4. The conductive film CF2 remains in the via hole VH1.

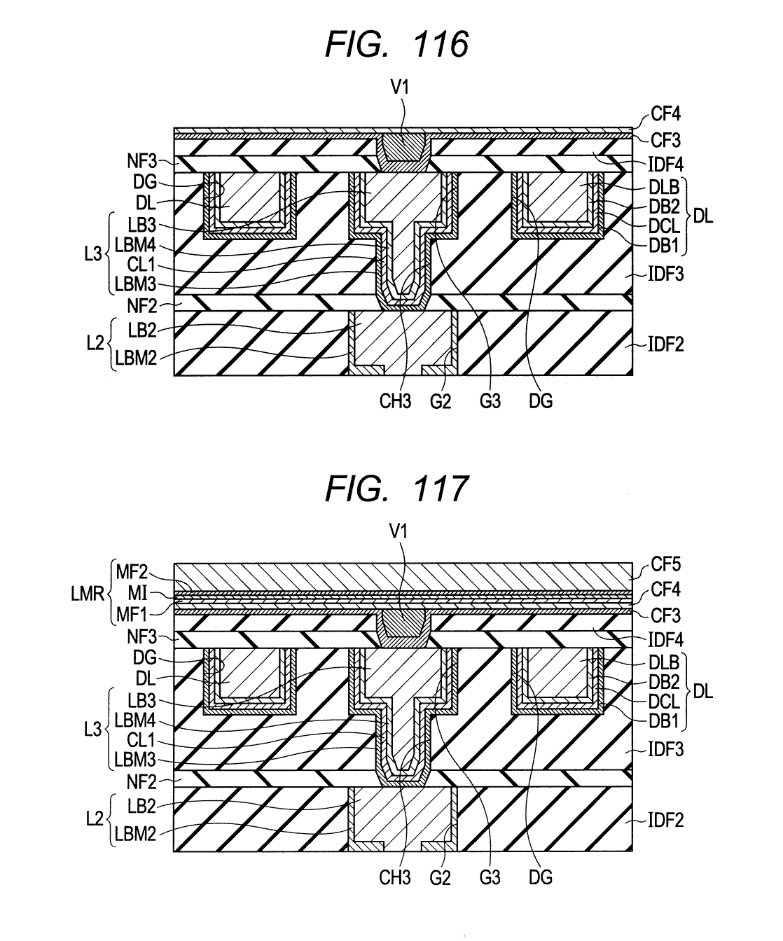

As illustrated in FIG. 116, a conductive film CF4 is then formed on the top surface of the conductive film CF2. As the conductive film CF4, titanium nitride (TiN) is employed. As illustrated in FIG. 117, a film stack LMR and a conductive film CF5 are then formed on the top surface of the conductive film CF3.

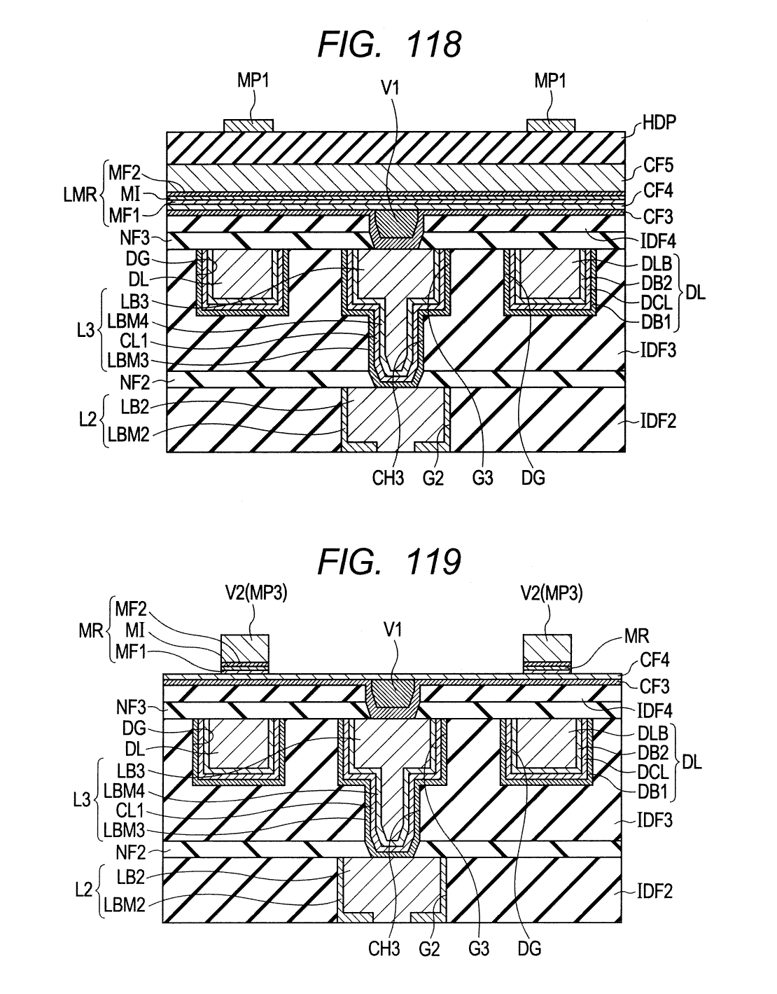

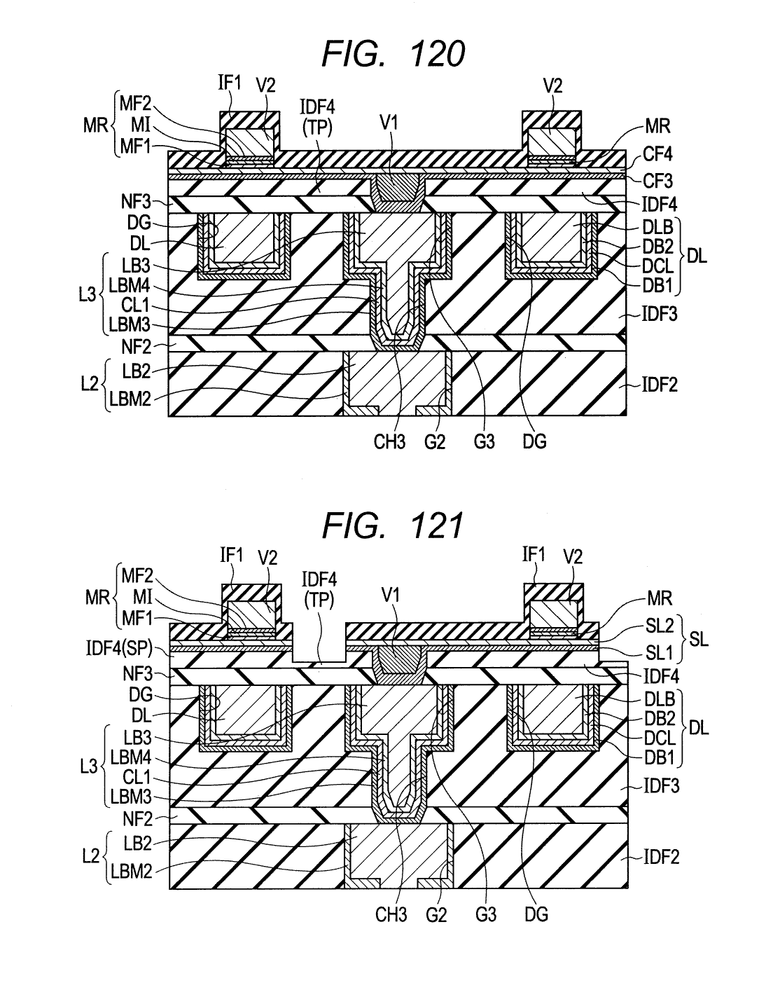

As illustrated in FIG. 118, a silicon oxide film HDP and a mask pattern MP1 are then formed on the top surface of the conductive film CF5. As illustrated in FIG. 119, the conductive film CF5 is then patterned to form a via plug V1 and a magnetic storage element MR. As illustrated in FIG. 120, an insulating film IF1 made of LT (low temperature)-SiN is formed, for example, by using CVD. Then, the insulating film IF1 is patterned into a mask. With the mask made of this insulating film IF1, the conductive film CF4 and the conductive film CF3 are patterned as illustrated in FIG. 121 to form a strap line SL.

Thus, the first metal film SL1 configuring a portion of the strap line SL has been formed in advance when a via plug V1 is formed and this enables simplification of manufacturing steps. After manufacturing steps similar to those described in First Embodiment, the semiconductor device according to Fourth Embodiment can be manufactured.

Thus, embodiments of the invention have been described, but it should be understood that the embodiments disclosed herein are not limiting but exemplary only. The scope of the invention is indicated by the claims and any element identical or equivalent to the claims or any change or modification within the claims is embraced in the present invention. Further, the numbers, values, and the like are all exemplary and they are not limited to the above-described ranges.

The invention can be applied to a semiconductor device and a manufacturing method thereof. In particular, it can be applied preferably to a semiconductor device including a magnetic storage element and a manufacturing method of the device.

What is claimed is:

1. A semiconductor device comprising:
a semiconductor substrate having a main surface;
a first wiring layer formed over the main surface of the semiconductor substrate and having a first copper wiring;
a second wiring layer formed over the first wiring layer and having a second copper wiring;
a third wiring layer formed over the second wiring layer and having a magnetic storage element;
an insulating film brought into contact with the top surface of the first copper wiring and comprised of a silicon carbide (SiC) film or a silicon carbonitride (SiCN) film; and
a first silicon nitride (SiCN) film brought into contact with the top surface of the second copper wiring,
wherein a rewrite current of the magnetic storage element is caused to pass through the second copper wiring,
wherein the second copper wiring has a wiring body comprised of copper and a stacked metal film covering therewith the bottom surface and the side surface of the wiring body, and
wherein the stacked metal film is a film stack of a first metal film containing at least one element selected from tantalum (Ta), titanium (Ti), ruthenium (Ru), manganese (Mn), magnesium (Mg), and tungsten (W) and a second metal film containing at least one element selected from cobalt (Co), nickel (Ni), and iron (Fe).

2. The semiconductor device according to claim 1, further comprising:
a third copper wiring provided in the second wiring layer;
a first plug provided in the third wiring layer and coupled to an upper portion of the third copper wiring;
a first strap line coupling the upper portion of the first plug to the magnetic storage element; and
a first interlayer insulating film formed over the first silicon nitride (SiN) film,
wherein the first silicon nitride (SiN) film is brought into contact with the top surface of the third copper wiring,
wherein the first plug penetrates through the first silicon nitride (SiN) film and the first interlayer insulating film, and
wherein the first strap line is formed over the first interlayer insulating film.

3. The semiconductor device according to claim 2,
wherein the first strap line is comprised of a titanium nitride (TiN) film or a film stack of a titanium (Ti) film and a titanium nitride (TiN) film formed thereover.

4. The semiconductor device according to claim 2,
wherein the first wiring layer and the second wiring layer have the same thickness, and
wherein the maximum width of the second copper wiring and the third copper wiring provided in the second wiring layer is smaller than the maximum width of the first copper wiring provided in the first wiring layer.

5. The semiconductor device according to claim 2, further comprising:
a fourth copper wiring formed in the second wiring layer and having a top surface to which the first silicon nitride (SiN) film is brought into contact; and
a second plug formed in the first silicon nitride (SiN) film and the first interlayer insulating film, coupled to the upper portion of the fourth copper wiring, and not electrically coupled to the magnetic storage element.

6. The semiconductor device according to claim 5, further comprising a second strap line coupled to the second plug, formed over the first interlayer insulating film and at the same time, provided in the third wiring layer, and not coupled to the first strap line.

7. The semiconductor device according to claim 5, further comprising a second interlayer insulating film brought into contact with the upper end portion of the second plug.

8. The semiconductor device according to claim 2, further comprising a second silicon nitride (SiN) film covering therewith the top surface of the magnetic storage element and the first strap line.

9. The semiconductor device according to claim 8,
wherein the third wiring layer has:
a fifth copper wiring formed over the magnetic storage element and coupled to the magnetic storage element; and
a third silicon nitride (SiN) film formed over the fifth copper wiring and brought into contact with the top surface of the fifth copper wiring.

10. The semiconductor device according to claim 9,
wherein a formation temperature of the insulating film is higher than that of the first silicon nitride (SiN) film, the second silicon nitride (SiN) film, and the third silicon nitride (SiN) film.

11. A semiconductor device comprising:
a substrate having a main surface;
a first wiring layer formed over the main surface of the semiconductor substrate and having a first copper wiring;
a second wiring layer formed over the first wiring layer and having a second copper wiring; and
a third wiring layer formed over the second wiring layer and having a magnetic storage element,
wherein the first wiring layer is brought into contact with the top surface of the first copper wiring and has an insulating film comprised of a silicon carbide (SiC) film or a silicon carbonitride (SiCN) film,
wherein the second wiring layer has a first silicon nitride (SiN) film brought into contact with the top surface of the second copper wiring and a third copper wiring provided with a space from the second copper wiring, and
wherein the third wiring layer has a first plug coupled to the upper portion of the third copper wiring and a first strap line coupling the upper portion of the first plug to the bottom portion of the magnetic storage element.

12. The semiconductor device according to claim 11, further comprising a first interlayer insulating film formed over the first silicon nitride (SiN) film and provided in the third wiring layer,
wherein the first silicon nitride (SiN) film extends from the upper portion of the second copper wiring to the upper portion of the third copper wiring and is brought into contact with the top surface of the third copper wiring,
wherein the first interlayer insulating film extends from a portion on the second copper wiring to a portion on the third copper wiring, each of the top surface of the first silicon nitride (SiN) film,
wherein the first plug is formed in the first silicon nitride (SiN) film and the first interlayer insulating film,
wherein the second copper wiring has a wiring body comprised of copper and a stacked metal film covering therewith the bottom surface and side surface of the wiring body, and
wherein the stacked metal film is a film stack of a first metal film containing at least one element selected from tantalum (Ta), titanium (Ti), ruthenium (Ru), manganese (Mn), magnesium (Mg), and tungsten (W) and a second metal film containing at least one element selected from cobalt (Co), nickel (Ni), and iron (Fe).

13. The semiconductor device according to claim 11,
wherein the first strap line is comprised of a titanium nitride (TiN) film or a film stack of a titanium (Ti) film and a titanium nitride (TiN) film formed thereover.

14. The semiconductor device according to claim 11,
wherein the first wiring layer and the second wiring layer have the same thickness, and
wherein the maximum width of the second copper wiring provided in the second wiring layer is smaller than the maximum width of the first copper wiring provided in the first wiring layer.

15. The semiconductor device according to claim 11, further comprising:
a first interlayer insulating film formed over the first silicon nitride (SiN) film and provided in the third wiring layer;
a fourth copper layer formed in the second wiring layer and having a top surface to which the first silicon nitride (SiN) film is brought into contact; and
a second plug formed in the first silicon nitride (SiN) film and the first interlayer insulating film, coupled to the upper portion of the fourth copper wiring, and not electrically coupled to the magnetic storage element.

16. The semiconductor device according to claim 15, further comprising a second strap line coupled to the second plug, formed over the first interlayer insulating film and at the same time, provided in the third wiring layer, and not coupled to the first strap line.

17. The semiconductor device according to claim 15, further comprising a second interlayer insulating film brought into contact with the upper end portion of the second plug.

18. The semiconductor device according to claim 11, further comprising a second silicon nitride (SiN) film covering therewith the top surfaces of the magnetic storage element and the first strap line.

19. The semiconductor device according to claim 18,
wherein the third wiring layer has:
a fifth copper wiring formed over the magnetic storage element and coupled to the magnetic storage element; and
a third silicon nitride (SiN) film formed over the fifth copper wiring and brought into contact with the top surface of the fifth copper wiring.

20. The semiconductor device according to claim 19,
wherein a formation temperature of the insulating film is higher than that of the first silicon nitride (SiN) film, the second silicon nitride (SiN) film, and the third silicon nitride (SiN) film.

21. A manufacturing method of a semiconductor device comprising the steps of:
preparing a semiconductor substrate having a main surface;
forming first wiring layers over the main surface;
forming a second wiring layer over the top layer of the first wiring layers; and
forming a third wiring layer having a magnetic storage element over the second wiring layer,
wherein the step of forming first wiring layers comprises the steps of:
forming a first insulating film;
forming a first copper wiring in the first insulating film; and
forming an insulating film brought into contact with the top surface of the first copper wiring and comprised of a silicon carbide (SiC) film or a silicon carbonitride (SiCN) film,
wherein the step of forming a second wiring layer comprises the steps:
forming a second insulating film over the first wiring layer;
forming a second copper wiring in the second insulating film; and
forming, over the second copper wiring, a first silicon nitride (SiN) brought into contact with the top surface of the second copper wiring, and
wherein the step of forming a second copper wiring comprises the steps:
forming a first trench portion in the second insulating film;
forming, over the side surface and the bottom surface of the first trench portion, a film stack of a first metal film containing at least one element selected from tantalum (Ta), titanium (Ti), ruthenium (Ru), manganese (Mn), magnesium (Mg), and tungsten (W) and a second metal film containing at least one element selected from cobalt (Co), nickel (Ni), and iron (Fe); and
forming a wiring body comprised of copper in the first trench portion having the film stack.

22. The manufacturing method of a semiconductor device according to claim 21,
wherein the step of forming the second wiring layer comprises a step of forming a third copper wiring with a space from the second copper wiring,
wherein the first silicon nitride (SiN) film is brought into contact with the top surface of the second copper wiring and the top surface of the third copper wiring, and
wherein the step of forming the third wiring layer comprises the steps of:
forming a first interlayer insulating film over the first silicon nitride (SiN) film;
forming a first plug penetrating through the first interlayer insulating film and the first silicon nitride (SiN) film and coupled to the upper portion of the third copper wiring;
forming, over the first interlayer insulating film, a first strap line coupled to the upper portion of the first plug; and
forming the magnetic storage element over the top surface of the first strap line.

23. The manufacturing method of a semiconductor device according to claim 22,
wherein the step of forming the first strap line comprises the steps of:
forming a titanium (Ti) film; and
forming a titanium nitride (TiN) film over the titanium (Ti) film.

24. The manufacturing method of a semiconductor device according to claim 22,
wherein the maximum width of the second copper wiring and the third copper wiring is set smaller than the maximum width of the first copper layer.

25. The manufacturing method of a semiconductor device according to claim 22,
wherein the step of forming the second wiring layer comprises a step of forming a fourth copper wiring,
wherein the first silicon nitride (SiN) film is brought into contact with the top surfaces of the first copper wiring, the second copper wiring, and the fourth copper wiring;
wherein the step of forming the third wiring layer comprises the step of forming a second plug penetrating through the first interlayer insulating film and the first silicon nitride (SiN) film and reaching the top surface of the fourth copper wiring, and
wherein the step of forming the magnetic storage element comprises the step of forming the magnetic storage element so as not to be electrically coupled to the second plug.

26. The manufacturing method of a semiconductor device according to claim 25,
wherein the step of forming the third wiring layer comprises the step of forming, over the first interlayer insulating film, a second strap line not coupled to the first strap line and coupled to the upper end portion of the second plug.

27. The manufacturing method of a semiconductor device according to claim 25,
wherein the step of forming the third wiring layer comprises the step of forming, over the first interlayer insulating film, a second interlayer insulating film to be brought into contact with the upper end portion of the second plug.

28. The manufacturing method of a semiconductor device according to claim 22,
wherein the first silicon nitride (SiN) film is brought into contact with the top surface of the third copper wiring,
wherein the step of forming the third wiring layer comprises the step of forming a second silicon nitride (SiN) film so as to cover therewith the magnetic storage element and the first strap line.

29. The manufacturing method of a semiconductor device according to claim 28,
wherein the step of forming the third wiring layer comprises the steps of:
forming a fifth copper wiring located on the magnetic storage element and coupled to the magnetic storage element; and
forming a third silicon nitride (SiN) film located on the fifth copper wiring and brought into contact with the top surface of the fifth copper wiring.

30. The manufacturing method of a semiconductor device according to claim 29,
wherein a formation temperature of the insulating film is higher than that of the first silicon nitride (SiN) film, the second silicon nitride (SiN) film, and the third silicon nitride (SiN) film.

31. A manufacturing method of a semiconductor device comprising the following steps of:
preparing a semiconductor substrate having a main surface;
forming a first wiring layer over the main surface;
forming a second wiring layer over the first wiring layer; and
forming a third wiring layer having therein a magnetic storage element over the second wiring layer,
wherein the step of forming the first wiring layer comprises the steps of:
forming a first insulating film;
forming a first copper wiring in the first insulating film; and
forming an insulating film comprised of a silicon carbide (SiC) film or a silicon carbonitride (SiCN) film so as to be brought into contact with the top surface of the first copper wiring,
wherein the step of forming the second wiring layer comprises the steps of:
forming a second insulating film;
forming a second copper wiring and a third copper wiring in the second insulating film; and
forming a first silicon nitride (SiN) film to be brought into contact with the top surface of the second copper wiring, and
wherein the step of forming the third wiring layer comprises the steps of:
forming a first plug to be coupled to the upper portion of the third copper wiring; and
forming a first strap line coupling the upper portion of the first plug to the bottom portion of the magnetic storage element.

32. The manufacturing method of a semiconductor device according to claim 31,
wherein the first silicon nitride (SiN) film extends from the upper portion of the second copper wiring to the upper portion of the third copper wiring,
wherein the step of forming the third wiring layer comprises the step of forming a first interlayer insulating film over the first silicon nitride (SiN) film,
wherein the step of forming the first plug comprises the steps of:
forming a hole portion penetrating through the first silicon nitride (SiN) film and the first interlayer insulating film; and
forming a metal material in the hole portion, and
wherein the step of forming the second copper wiring comprises the steps of:
forming a first trench portion in the second insulating film;
forming, over the side surface and the bottom surface of the first trench portion, a film stack of a first metal film containing at least one element selected from tantalum (Ta), titanium (Ti), ruthenium (Ru), manganese (Mn), magnesium (Mg), and tungsten (W) and a second metal film containing at least one element selected from cobalt (Co), nickel (Ni), and iron (Fe); and
filling copper on the film stack to form a wiring body.

33. The manufacturing method of a semiconductor device according to claim 31,
wherein the step of forming the first strap comprises the steps of:
forming a titanium (Ti) film; and
forming a titanium nitride (TiN) film over the titanium (Ti) film.

34. The manufacturing method of a semiconductor device according to claim 31,
wherein the maximum width of the second copper wiring and the third copper wiring is set smaller than the maximum width of the first copper wiring.

35. The manufacturing method of a semiconductor device according to claim 32,
wherein the step of forming the second wiring layer comprises the step of forming a fourth copper wiring,
wherein the first silicon nitride (SiN) film is brought into contact with the top surface of the fourth copper wiring,
the step of forming the third copper wiring comprises the step of forming a second plug penetrating through the first interlayer insulating film and the first silicon nitride (SiN) film and reaching the top surface of the fourth copper wiring, and
wherein the step of forming the magnetic storage element comprises the step of forming the magnetic storage element so as not to be electrically coupled to the second plug.

36. The manufacturing method of a semiconductor device according to claim 35,
wherein the step of forming the third wiring layer comprises the step of forming, over the first interlayer insulating film, a second strap line not coupled to the first strap line but coupled to the upper end portion of the second plug.

37. The manufacturing method of a semiconductor device according to claim 35,
wherein the step of forming the third wiring layer comprises the step of forming, over the first interlayer insulating film, a second interlayer insulating film to be brought into contact with the upper end portion of the second plug.

38. The manufacturing method of a semiconductor device according to claim 31,
wherein the step of forming the third wiring layer comprises the step of forming a second silicon nitride (SiN) film so as to cover therewith the magnetic storage element and the first strap line.

39. The manufacturing method of a semiconductor device according to claim 38,
wherein the step of forming the third wiring layer comprises the steps of:
forming a fifth copper wiring located on the magnetic storage element and coupled to the magnetic storage element; and
forming a third silicon nitride (SiN) film located on the fifth copper wiring and brought into contact with the top surface of the fifth copper wiring.

40. The manufacturing method of a semiconductor device according to claim 39,
wherein a formation temperature of the insulating film is higher than that of the first silicon nitride (SiN) film, the second silicon nitride (SiN) film, and the third silicon nitride (SiN) film.
